(19) United States
(12) Patent Application Publication
(10) Pub. No.: US 2023/0395497 A1
(43) Pub. Date: Dec. 7, 2023

(54) SEMICONDUCTOR STORAGE DEVICE

(71) Applicant: Kioxia Corporation, Tokyo (JP)

(72) Inventors: Hiroyuki YAMASAKI, Aichi Nagoya (JP); Masayoshi TAGAMI, Kuwana Mie (JP)

(21) Appl. No.: 18/176,431

(22) Filed: Feb. 28, 2023

(30) Foreign Application Priority Data
Jun. 2, 2022 (JP) 2022-090273

(51) Int. Cl. H01L 23/528; H01L 23/522; H10B 80/00; H01L 25/18; H10B 41/20; H10B 43/20; H10B 41/10; H10B 43/10

(52) U.S. Cl. CPC H01L 23/5283; H01L 23/5226; H10B 80/00; H10B 43/10; H10B 41/20; H10B 43/20; H10B 41/10; H01L 25/18

(57) ABSTRACT

According to one embodiment, a semiconductor storage device includes a first chip, a second chip, and a third chip. In the third chip, a first conductive film is above a first stacked body. The first conductive film extends across the first stacked body when viewed from a stacking direction. A first plug extends in the stacking direction and connects the first conductive film and a second conductive film. The first electrode is connected to the second conductive film. In the second chip, a third conductive film is above a second stacked body. A second plug extends in the stacking direction and connects the third conductive film and the fourth conductive film. The second electrode is connected to the fourth conductive film. The first chip has a first wiring structure therein. The first wiring structure is connected to the second electrode.

### CROSS-REFERENCE TO RELATED APPLICATION(S)

This application is based upon and claims the benefit of priority from Japanese Patent Application No. 2022-090273, filed Jun. 2, 2022, the entire contents of which are incorporated herein by reference.

### FIELD

Embodiments described herein relate generally to a semiconductor storage device.

### BACKGROUND

A semiconductor storage device may include a plurality of chips bonded to each other. It is desirable to appropriately connect conductive films between a plurality of chips in the semiconductor storage device.

### BRIEF DESCRIPTION OF THE DRAWINGS

FIG. 1 is a block diagram showing a configuration of a semiconductor storage device according to a first embodiment.

FIG. 2 is a circuit diagram showing the configuration of memory blocks in a first embodiment.

FIG. 3 is a plan view showing the configuration of a semiconductor storage device according to a first embodiment.

FIG. 4 is a cross-sectional view showing the configuration of a semiconductor storage device according to a first embodiment.

FIGS. 5A and 5B are cross-sectional views showing the configuration of a memory cell according to a first embodiment.

FIG. 6 is a cross-sectional view showing the configuration of a semiconductor storage device according to a first embodiment.

FIGS. 7A to 7D are cross-sectional views showing aspects of a manufacturing method of a semiconductor storage device according to a first embodiment.

FIGS. 8A to 8C are cross-sectional views showing aspects of a manufacturing method of a semiconductor storage device according to a first embodiment.

FIGS. 9A to 9E are cross-sectional view showing aspects of a manufacturing method of a semiconductor storage device according to a first embodiment.

FIGS. 10A and 10B are cross-sectional views showing aspects of a manufacturing method of a semiconductor storage device according to a first embodiment.

FIGS. 11A and 11B are cross-sectional views showing aspects of a manufacturing method of a semiconductor storage device according to a first embodiment.

FIGS. 12A to 12D are cross-sectional views showing aspects of a manufacturing method of a semiconductor storage device according to a first embodiment.

FIG. 13 is a cross-sectional view showing aspects of a manufacturing method of a semiconductor storage device according to a first embodiment.

FIG. 14 is a cross-sectional view showing the configuration of a semiconductor storage device according to a first modification of a first embodiment.

FIG. 15 is a cross-sectional view showing the configuration of a semiconductor storage device according to a second modification of a first embodiment.

FIG. 16 is a cross-sectional view showing the configuration of a semiconductor storage device according to a third modification of a first embodiment.

FIG. 17 is a cross-sectional view showing the configuration of a semiconductor storage device according to a fourth modification of a first embodiment.

FIG. 18 is a cross-sectional view showing the configuration of a semiconductor storage device according to a fifth modification of a first embodiment.

FIG. 19 is a plan view showing the configuration of a semiconductor storage device according to a second embodiment.

FIG. 20 is a cross-sectional view showing the configuration of a semiconductor storage device according to a second embodiment.

FIG. 21 is a cross-sectional view showing the configuration of a semiconductor storage device according to a second embodiment.

FIG. 22 is a cross-sectional view showing the configuration of a semiconductor storage device according to a first modification of a second embodiment.

FIG. 23 is a cross-sectional view showing the configuration of a semiconductor storage device according to a second modification of a second embodiment.

FIG. 24 is a cross-sectional view showing the configuration of a semiconductor storage device according to a third modification of a second embodiment.

FIG. 25 is a cross-sectional view showing the configuration of a semiconductor storage device according to a fourth modification of a second embodiment.

FIG. 26 is a cross-sectional view showing the configuration of a semiconductor storage device according to a fifth modification of a second embodiment.

FIG. 27 is a cross-sectional view showing the configuration of a semiconductor storage device according to a sixth example of a second embodiment.

FIG. 28 is a cross-sectional view showing the configuration of a semiconductor storage device according to a seventh modification of a second embodiment.

FIG. 29 is a cross-sectional view showing the configuration of a semiconductor storage device according to a third embodiment.

FIG. 30 is a cross-sectional view showing the configuration of a semiconductor storage device according to a first modification of a third embodiment.

FIG. 31 is a cross-sectional view showing the configuration of a semiconductor storage device according to a second modification of a third embodiment.

### DETAILED DESCRIPTION

Embodiments provide a semiconductor storage device suitable for appropriately connecting conductive films between a plurality of chips.

In general, according to one embodiment, a semiconductor storage device includes a first chip, a second chip, and a third chip. The second chip is bonded to the first chip. The third chip is bonded to the second chip on a side opposite the first chip. The third chip includes a first stacked body, a plurality of first semiconductor films, a first conductive film, a second conductive film, a first plug, and a first electrode. In the first stacked body, a plurality of first conductive layers are stacked via a first insulating layer one on the other in a stacking direction. The plurality of first semiconductor films each extend in the stacking direction in the first stacked body. The first conductive film is disposed above the first stacked body. The first conductive film extends across the first stacked body when viewed from the stacking direction. The second conductive film is spaced apart from the first stacked body in a planar direction intersecting the stacking direction at a position along the stacking direction that is closer to the second chip than is the first conductive film. The first plug is disposed between the first conductive film and the second conductive film. The first plug extends in the stacking direction and connects the first conductive film and the second conductive film. The first electrode is disposed at the bonding surface (bonding interface) of the second chip and the third chip. The first electrode is connected to the second conductive film. The second chip includes a second stacked body, a plurality of second semiconductor films, a third conductive film, a fourth conductive film, a second plug, and a second electrode. In the second stacked body, a plurality of second conductive layers are stacked via a second insulating layer. The plurality of second semiconductor films each extend in the stacking direction in the second stacked body. The third conductive film is disposed above the second stacked body. The fourth conductive film is spaced apart from the second stacked body in the planar direction at a position along the stacking direction that is closer to the first chip than is the third conductive film. The second plug is disposed between the third conductive film and the fourth conductive film. The second plug extends in the stacking direction and connects the third conductive film and the fourth conductive film. The second electrode is disposed at the bonding surface (bonding interface) of the first chip and the second chip. The second electrode is connected to the fourth conductive film. The first chip has a first wiring structure therein. The first wiring structure is connected to the second electrode.

Semiconductor storage devices according to certain example embodiments will be described below with reference to the accompanying drawings. It is noted that the present disclosure is not limited by these embodiments.

### First Embodiment

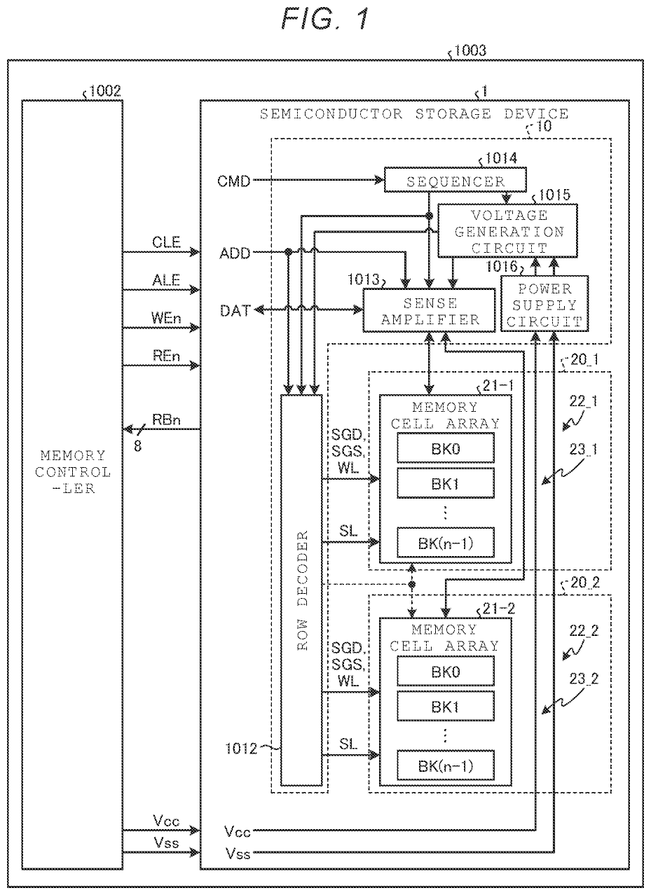

A semiconductor storage device according to the first embodiment includes a plurality of chips bonded to each other, and is implemented to appropriately connect conductive films between the different chips. For example, the semiconductor storage device 1 may be configured as shown in FIG. 1. FIG. 1 is a block diagram showing the configuration of the semiconductor storage device 1.

The semiconductor storage device 1 includes a plurality of chips 10, 20_1, and 20_2. The chips 20_1 and 20_2 include memory cell arrays 21_1 and 21_2, and are also called array chips. The chip 10 includes a circuit for controlling the memory cell arrays 21_1 and 21_2, and is also called a circuit chip.

It is noted that the chips 20_1 and 20_2 can be referred to as a chip 20 when they are not required to be distinguished from each other. The memory cell arrays 21_1 and 21_2 are referred to as a memory cell array 21 when they are not distinguished from each other. FIG. 1 illustrates a configuration in which the semiconductor storage device 1 includes two chips (array chips) 20_1 and 20_2, the semiconductor storage device 1 may include three or more array chips.

The semiconductor storage device 1 may be a nonvolatile memory that stores data in a nonvolatile manner, and may be applied to a memory system 1003 such as a memory card, a Solid State Drive (SSD), or the like. The memory system 1003 has a semiconductor storage device 1 and a memory controller 1002.

The semiconductor storage device 1 receives from the memory controller 1002, a power Vss, a power Vcc, a command latch enable signal CLE, an address latch enable signal ALE, a write enable signal WEn, a read enable signal REn, a ready/busy signal RBn, input/output signals I/O, and the like. The semiconductor storage device 1 is controlled by the memory controller 1002 through these signals.

The input/output signal I/O can include a command CMD, address information ADD, and a data signal DAT. The power Vss has a reference voltage (for example, ground voltage). The power Vcc has a predetermined voltage (for example, a power supply voltage). The command latch enable signal CLE indicates that the input/output signal I/O is the command CMD. The address latch enable signal ALE indicates that the input/output signal I/O is the address information ADD. The write enable signal WEn may be used in enabling write operations. The read enable signal REn may be used in enabling read operations. The ready/busy signal RBn indicates that the semiconductor storage device 1 is in a ready state or a busy state.

The chip 20_1 has power lines 22_1 and 23_1. The chip 20_2 has power lines 22_2 and 23_2. The power Vss is transmitted to the chip 10 via the power lines 22_2 and 22_1. The power Vcc is transmitted to the chip 10 via the power lines 23_2 and 23_1.

The chip 20_1 further includes a memory cell array 21_1. In the memory cell array 21_1, a plurality of memory cell transistors (hereinafter, simply referred to as memory cells) are located three-dimensionally. A chip 10_2 further includes a memory cell array 21_2. In the memory cell array 21_2, a plurality of memory cells are located three-dimensionally. Each memory cell array 21 includes a plurality of blocks BK.

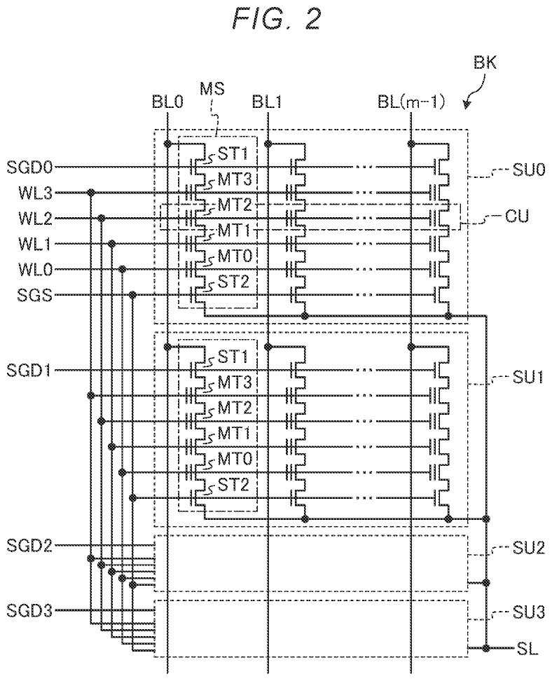

Each block BK corresponds to a set (group) of a plurality of memory cell transistors commonly connected (connected in common) to the word lines WL, and may be configured as shown in FIG. 2. FIG. 2 is a circuit diagram showing the configuration of a block BK.

Each block BK includes, for example, four string units SU0 to SU3. Each string unit SU includes a plurality of memory strings MS. The plurality of memory strings MS correspond to a plurality of bit lines BL0 to BL(m−1) (m is any integer equal to or greater than 2). Each memory string MS is connected to a corresponding bit line BL. Each memory string MS includes memory cell transistors MT0 to MT3 (hereinafter, referred to as memory cells) and select transistors ST1 and ST2.

In each memory string MS, the drain of the select transistor ST1 is connected to the bit line BL. The memory cell transistors MT0 to MT3 are connected in series between the source of the select transistor ST1 and the drain of the select transistor ST2. The source of the select transistor ST2 is connected to a source line SL.

The gate of the select transistor ST1 of each memory string MS provided in the string unit SU is commonly connected to a select gate line SGD. The gate of the select transistor ST2 of each memory string MS provided in the block BK is commonly connected to a select gate line SGS. The gates of the memory cell transistors MT of each memory string MS provided in the block BK are commonly connected to the word line WL.

A set of memory cells MC connected to the same word line WL in same string unit SU is called a cell unit CU. For example, when the memory cell MC stores p-bit data (p is an integer equal to or greater than 1), the storage capacity of the cell unit CU is defined as p page data.

Each bit line BL is connected to the drain of the select transistor ST1 of a corresponding memory string MS of each string unit SU of the block BK. The source line SL is commonly connected to the source of the select transistor ST2 of each memory string MS provided in the block BK, and is shared among the string units SU of the block BK. The source line SL may be shared between blocks BK.

The chip 10 (circuit chip) shown in FIG. 1 includes a row decoder 1012, a sense amplifier 1013, a sequencer 1014, a voltage generation circuit 1015, and a power circuit 1016.

The power circuit 1016 supplies powers Vss and Vcc received through the power lines 22 and 23 to each part. The power circuit 1016 supplies powers Vss and Vcc to the voltage generation circuit 1015.

The sequencer 1014 comprehensively controls each unit according to a command CMD. For example, the sequencer 1014 controls a write operation in accordance with a write command CMD. In controlling the write operation, the sequencer 1014 writes the data DAT to the addressed memory cell MC in the memory cell array 21 and returns a write completion notification to the memory controller 1002. The sequencer 1014 controls a read operation in accordance with a read command CMD. In controlling the read operation, the sequencer 1014 reads the data DAT from the addressed memory cell MC in the memory cell array 21 and returns the read data DAT to the memory controller 1002.

The voltage generation circuit 1015 uses the powers Vss and Vcc to generate voltages according to the control of the sequencer 1014, and supplies the generated voltages to the row decoder 1012 and the sense amplifier 1013.

The row decoder 1012 decodes the address information ADD, selects a word line WL corresponding to a memory cell to be written/read in the memory cell array 21 according to the decoding result, and supplies a voltage to the selected word line WL.

The sense amplifier 1013 decodes the address information ADD, and selects the bit line BL corresponding to the memory cell to be written/read in the memory cell array 21 according to the decoding result. The sense amplifier 1013 supplies a voltage to the selected bit line BL in the write process. The sense amplifier 1013 supplies the voltage of the selected bit line BL and senses the voltage of the selected bit line BL in the read process.

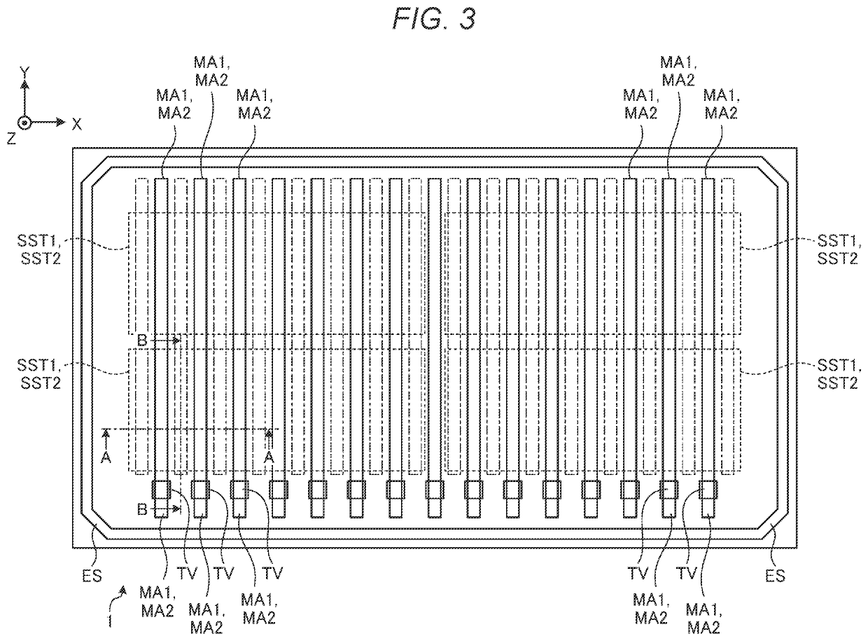

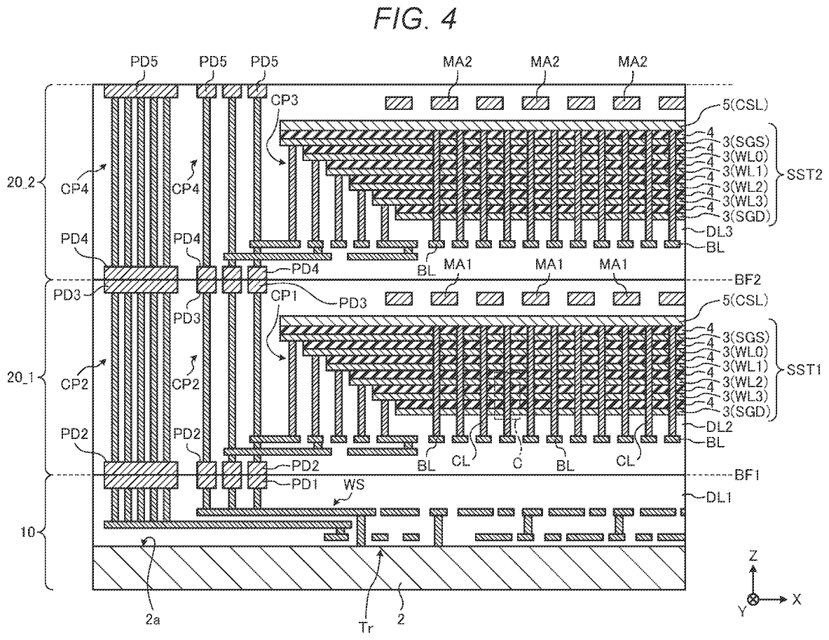

The power lines 22 and 23 shown in FIG. 1 may be implemented by wiring MA1 and MA2 as shown in FIGS. 3 and 4, for example. In the following description, the direction perpendicular to the surface of a substrate 2 is defined as the Z direction, and the two directions perpendicular to each other in the plane perpendicular to the Z direction are defined as the X direction and the Y direction. FIG. 3 is an XY plan view showing the configuration of the semiconductor storage device 1. FIG. 4 is an XZ cross-sectional view showing the configuration of the semiconductor storage device 1. FIG. 4 illustrates a cross section taken along line A-A of FIG. 3.

The semiconductor storage device 1 has a substantially rectangular shape in the XY plane view, and the longitudinal direction is, for example, the X direction. The semiconductor storage device 1 may include the stacked chips 10, 20_1, and 20_2.

FIG. 3 illustrates a schematic layout configuration of each of the chips 10, 20_1, and 20_2. A plurality of stacked bodies SST1 are disposed in the chip 20_1. The plurality of stacked bodies SST1 may be located two-dimensionally in the XY direction. Each stacked body SST1 has a substantially rectangular shape in the XY plane view, and the longitudinal direction is, for example, the X direction. Each stacked body SST1 functions as a part of the memory cell array 21_1. A plurality of wirings MA1 are disposed on the +Z side of the stacked body SST1. The plurality of wirings MA1 are located in the X direction. Each wiring MA1 extends in the Y direction. Each wiring MA1 extends in the Y direction across the stacked body SST1 when viewed from the Z direction. Each wiring MA1 functions as power lines 22 and 23, and the width and thickness may be set according to the amount of power to be transmitted and the length of the power lines 22 and 23.

Similarly, in the chip 20_2, a plurality of stacked bodies SST2 are disposed. The plurality of stacked bodies SST2 may be two-dimensionally located in the XY direction. Each stacked body SST2 has a substantially rectangular shape in the XY plane view, and the longitudinal direction is, for example, the X direction. Each stacked body SST2 functions as a part of the memory cell array 21_2. A plurality of wirings MA2 are disposed on the +Z side of the stacked body SST2. The plurality of wirings MA2 are located in the X direction. Each wiring MA2 extends in the Y direction. Each wiring MA2 extends in the Y direction across the stacked body SST2 when viewed from the Z direction. Each wiring MA2 functions as power lines 22 and 23, and the width and thickness may be set according to the amount of power to be transmitted and the length. Each wiring MA2 is mostly covered with an insulating film DL3, but the vicinity of the −Y-side end is partially exposed through an opening TV. Thus, wires or the like for wire bonding mounting may be bonded to each wiring MA2 through the opening TV.

An edge seal ES is provided as a structure shared by the chips 10, 20_1 and 20_2. The edge seal ES surrounds the plurality of stacked bodies SST1 and SST2 from the outside in the XY direction when viewed from the Z direction. Thus, the edge seal ES protects the memory cell arrays 21_1 and 21_2 and the circuits for controlling the memory cell arrays 21_1 and 21_2 (the row decoder 1012, the sense amplifier 1013, the sequencer 1014, the voltage generation circuit 1015, the power circuit 1016, or the like) from external electrostatic noise and the like.

It is noted that for simplification, the illustration of the interior configuration of the edge seal ES in the chip 10 is omitted.

As shown in FIG. 4, the chip 20_1 is disposed on the +Z side of the chip 10. The chip 20_2 is disposed on the +Z side of the chip 20_1. A chip 30 is disposed on the +Z side of the chip 20_2. That is, the chips 20_1 and 20_2 are stacked in order on the +Z side of the chip 10. The structure in which the chips 20_1 and 20_2 are bonded in order to the +Z side of the chip 10 is also called a multi-stack array, in which the memory cell arrays 21_1 and 21_2 are stacked in order.

The number of chips 20 (array chips) stacked in the multi-stack array is not limited to two, and may be three or more in other examples.

The chip 20_1 is bonded to the +Z-side surface of the chip 10. The chip 20_1 may be bonded by direct bonding. The chip 10 has an insulating film (for example, an oxide film) DL1 and an electrode PD1 on the +Z side. The chip 20_1 has an insulating film (for example, an oxide film) DL2 and an electrode PD2 on the −Z side. At the bonding surface BF1 between the chips 10 and 20_1, the insulating film DL1 of the chip 10 and the insulating film DL2 of the chip 20_1 are bonded together, and the electrode PD1 of the chip 10 and the electrode PD2 of the chip 20_1 are bonded together.

The chip 20_2 is bonded to the +Z-side surface of the chip 20_1. The chip 20_2 is bonded to the chip 20_1 on a side opposite to the chip 10. The chip 20_2 may be bonded by direct bonding. The chip 20_1 has an insulating film (for example, an oxide film) DL2 and an electrode PD3 on the +Z side. The chip 20_2 has an insulating film (for example, an oxide film) DL3 and an electrode PD4 on the −Z side. At the bonding surface BF2 between the chips 20_1 and 20_2, the insulating film DL2 of the chip 20_1 and the insulating film DL3 of the chip 20_2 are bonded together, and the electrode PD3 of the chip 20_1 and the electrode PD4 of the chip 20_2 are bonded together.

The chip 10 has a substrate 2, a transistor Tr, an electrode PD1, a wiring structure WS, and an insulating film DL1. The substrate 2 is disposed on the −Z side of the chip 10, and extends in a plate shape in the XY direction. The substrate 2 may be a semiconductor substrate, and may be made of a material based on a semiconductor (for example, silicon). The substrate 2 has a surface 2a on the +Z side. The transistor Tr functions as a circuit element of a circuit for controlling the memory cell array 21 (the row decoder 1012, the sense amplifier 1013, the sequencer 1014, the voltage generation circuit 1015, the power circuit 1016, or the like). The transistor Tr includes a gate electrode disposed as a conductive film on the surface 2a of the substrate 2, source electrode/drain electrode disposed as semiconductor regions near the surface 2a in the substrate 2, or the like. The electrode PD1 is disposed such that its surface is exposed to the bonding surface BF1 of the chips 10 and 20_1, as described above. The wiring structure WS extends mainly in the Z direction, and connects the gate electrode, source electrode/drain electrode, or the like of the transistor Tr to the electrode PD1.

The chip 20_1 has a stacked body SST1, a conductive layer 5, a plurality of columns CL, a plurality of plugs CP1, a plurality of plugs CP2, a plurality of conductive films BL, a plurality of wirings MA1, an electrode PD2, an electrode PD3, and an insulating film DL2. In the stacked body SST1, a plurality of conductive layers 3 are stacked in the Z direction with insulating layers 4 interposed therebetween. The plurality of conductive layers 3 function as a select gate line SGD, a word line WL3, a word line WL2, a word line WL1, a word line WL0, and a select gate line SGS in order from the −Z side to the +Z side.

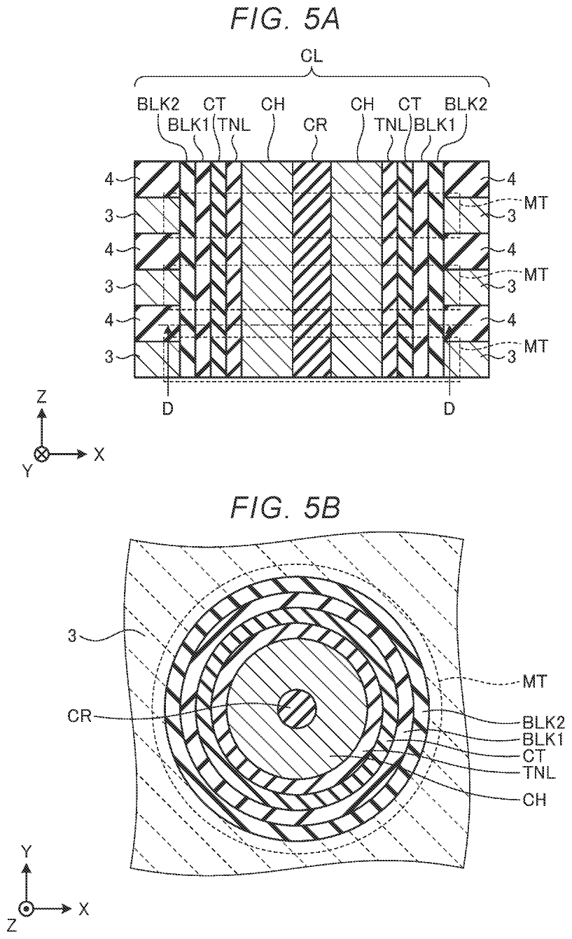

Each conductive layer 3 extends in a plate shape in the XY direction. Each column CL extends in the Z direction through the plurality of conductive layers 3. Each column CL may pass through the stacked body SST1 in the Z direction. Each column CL extends in a columnar shape in the Z direction. Each column CL includes a semiconductor film CH (see FIG. 5A) that functions as a channel region. The semiconductor film CH extends in a columnar shape (for example, in a columnar shape or a cylindrical shape) having an axis along the Z direction. A plurality of memory cells MC are formed at a plurality of intersection positions where the plurality of conductive layers 3 and the plurality of columns CL intersect, that is, at a plurality of intersection positions where the plurality of conductive layers 3 and the plurality of semiconductor films CH intersect.

Each column CL includes, as shown in FIGS. 5A and 5B, an insulating film CR, a semiconductor film CH, an insulating film TNL, a charge storage film CT, an insulating film BLK1, and an insulating film BLK2. FIG. 5A is an XZ cross-sectional view showing the configuration of the memory cell MT, and is an enlarged cross-sectional view of the C portion of FIG. 4. FIG. 5B is an XY cross-sectional view showing the configuration of the memory cell MT, and shows a cross section taken along line D-D in FIG. 5A. The insulating film CR extends in the Z direction, and forms a columnar shape having an axis along the Z direction. The insulating film CR may be made of an insulating material such as silicon oxide. The semiconductor film CH extends in the Z direction so as to cover the insulating film CR from the outside in the XY direction, and has a cylindrical shape having an axis along the Z direction. The semiconductor film CH may be formed of a semiconductor such as polysilicon. The insulating film TNL extends in the Z direction so as to cover the semiconductor film CH from the outside in the XY direction, and has a cylindrical shape having an axis along the Z direction. The insulating film TNL may be made of an insulating material such as silicon oxide. The charge storage film CT extends in the Z direction so as to cover the insulating film TNL from the outside in the XY direction, and has a cylindrical shape having an axis along the Z direction. The charge storage film CT may be made of an insulating material such as silicon nitride. The insulating film BLK1 extends in the Z direction so as to cover the charge storage film CT from the outside in the XY direction, and has a cylindrical shape having an axis along the Z direction. The insulating film BLK1 may be made of an insulating material such as silicon oxide. The insulating film BLK2 extends in the Z direction so as to cover the insulating film BLK1 from the outside in the XY direction, and has a cylindrical shape having an axis along the Z direction. The insulating film BLK2 may be made of an insulating material such as aluminum oxide. The portions surrounded by dotted lines in FIGS. 5A and 5B function as memory cells MT.

The tip of the semiconductor film CH in the column CL reaches the conductive layer 5 as shown in FIG. 4. The semiconductor film CH is connected to the conductive layer 5 at the +Z-side end, and is connected to the conductive film BL at the −Z-side end via a plug. The conductive film BL functions as a bit line BL (see FIG. 2). The conductive layer 5 may be formed of a semiconductor (for example, polysilicon) having conductivity. The conductive layer 5 functions as a cell source portion CSL in the source line SL (see FIG. 2). The semiconductor film CH functions as a channel region in the memory string MS (see FIG. 2).

Each of the conductive layers 3 may have the same width in the Y direction. The widths in the X direction of the plurality of conductive layers 3 increase stepwise from the −Z side to the +Z side. The plurality of conductive layers 3 are configured such that the ends in the X direction are positioned gradually more outward, from the −Z side to the +Z side. Thus, a staircase structure in which the select gate line SGD, a plurality of word lines WL, and the select gate line SGS are drawn in a stair-like manner from the −Z side to the +Z side is formed at the plug connection portion in a memory cell array 11_1.

The plurality of plugs CP1 correspond to the plurality of conductive layers 3. Each plug CP1 is disposed between the electrode PD2 and the corresponding conductive layer 3 in the Z direction, the −Z-side end is electrically connected to the electrode PD2, the plug CP1 extends in the Z direction, and the +Z-side end is electrically connected to the corresponding conductive layer 3. Thus, the plug CP1 electrically connects the electrode PD2 and the corresponding conductive layer 3.

The plurality of plugs CP2 correspond to the plurality of electrodes PD2, and correspond to the plurality of electrodes PD3. Each plug CP2 is disposed between the corresponding electrode PD2 and the corresponding electrode PD3 in the Z direction, the −Z-side end is electrically connected to the electrode PD2, the plug CP2 extends in the Z direction, and the +Z-side end is electrically connected to the corresponding electrode PD3. Thus, the plug CP2 electrically connects the corresponding electrode PD2 and the corresponding electrode PD3.

A plurality of conductive films BL are disposed on the −Z side of the stacked body SST1. The plurality of conductive films BL are located in the X direction with each other. Each conductive film BL extends in the Y direction. The plurality of conductive films BL correspond to the plurality of columns CL. Each conductive film BL is electrically connected to the −Z-side end of the corresponding column CL and functions as a bit line BL. The conductive film BL is electrically connected to the electrode PD2. Thus, the bit line BL can be connected to the transistor Tr of the chip 10 via the electrode PD2, the electrode PD1, and the wiring structure WS.

A plurality of wirings MA1 are disposed on the +Z side of the stacked body SST1. The plurality of wirings MA1 are located in the X direction. Each wiring MA1 extends in the Y direction. Each wiring MA1 extends in the Y direction across the stacked body SST1 when viewed from the Z direction. Each wiring MA1 functions as power lines 22 and 23, and the width and thickness may be set according to the amount of power to be transmitted and the necessary length. A detailed configuration of the wiring MA1 will be described later.

The electrode PD2 is disposed such that its surface is exposed to the bonding surface BF1 of the chips 10 and 20_1. The electrode PD3 is disposed such that its surface is exposed to the bonding surface BF2 of the chips 20_1 and 20_2.

The chip 20_2 has the stacked body SST2, a conductive layer 5, a plurality of columns CL, a plurality of plugs CP3, a plurality of plugs CP4, a plurality of conductive films BL, a wiring MA2, an electrode PD4, an electrode PD5, and the insulating film DL3. In the stacked body SST2, a plurality of conductive layers 3 are stacked in the Z direction with insulating layers 4 interposed therebetween. The plurality of conductive layers 3 function as a select gate line SGD, a word line WL3, a word line WL2, a word line WL1, a word line WL0, and a select gate line SGS in order from the −Z side to the +Z side.

Each conductive layer 3 extends in a plate shape in the XY direction. Each column CL extends in the Z direction through the plurality of conductive layers 3. Each column CL may pass through the stacked body SST2 in the Z direction. Each column CL extends in a columnar shape in the Z direction. Each column CL includes a semiconductor film CH (see FIG. 5A) that functions as a channel region. The semiconductor film CH extends in a columnar shape (for example, in a columnar shape or a cylindrical shape) having an axis along the Z direction. A plurality of memory cells MC are formed at a plurality of intersection positions where the plurality of conductive layers 3 and the plurality of columns CL intersect, that is, at a plurality of intersection positions where the plurality of conductive layers 3 and the plurality of semiconductor films CH intersect.

Each column CL includes, as shown in FIGS. 5A and 5B, an insulating film CR, a semiconductor film CH, an insulating film TNL, a charge storage film CT, an insulating film BLK1, and an insulating film BLK2. The insulating film CR extends in the Z direction, and forms a columnar shape having an axis along the Z direction. The insulating film CR may be made of an insulating material such as silicon oxide. The semiconductor film CH extends in the Z direction so as to cover the insulating film CR from the outside in the XY direction, and has a cylindrical shape having an axis along the Z direction. The semiconductor film CH may be formed of a semiconductor such as polysilicon. The insulating film TNL extends in the Z direction so as to cover the semiconductor film CH from the outside in the XY direction, and has a cylindrical shape having an axis along the Z direction. The insulating film TNL may be made of an insulating material such as silicon oxide. The charge storage film CT extends in the Z direction so as to cover the insulating film TNL from the outside in the XY direction, and has a cylindrical shape having an axis along the Z direction. The charge storage film CT may be made of an insulating material such as silicon nitride. The insulating film BLK1 extends in the Z direction so as to cover the charge storage film CT from the outside in the XY direction, and has a cylindrical shape having an axis along the Z direction. The insulating film BLK1 may be made of an insulating material such as silicon oxide. The insulating film BLK2 extends in the Z direction so as to cover the insulating film BLK1 from the outside in the XY direction, and has a cylindrical shape having an axis along the Z direction. The insulating film BLK2 may be made of an insulating material such as aluminum oxide. The portions surrounded by dotted lines in FIGS. 5A and 5B function as memory cells MT.

As shown in FIG. 4, the semiconductor film CH in the column CL is connected to the conductive layer 5 at the +Z-side end, and is connected to the conductive film BL at the −Z-side end via a plug. The conductive film BL functions as a bit line BL (see FIG. 2). The conductive layer 5 may be formed of a semiconductor (for example, polysilicon) having conductivity. The conductive layer 5 functions as a cell source portion CSL in the source line SL (see FIG. 2). The semiconductor film CH functions as a channel region in the memory string MS (see FIG. 2).

Each of the conductive layers 5 may have the same width in the Y direction. The widths in the X direction of the plurality of conductive layers 5 increase stepwise from the −Z side to the +Z side. The plurality of conductive layers 5 are configured such that the ends in the X direction are positioned gradually more outward from the −Z side to the +Z side. Thus, a staircase structure in which the select gate line SGD, a plurality of word lines WL, and the select gate line SGS are drawn in a stair-like manner from the −Z side to the +Z side in order is formed at the plug connection portion in a memory cell array 11_2.

The plurality of plugs CP3 correspond to the plurality of conductive layers 3. Each plug CP3 is disposed between the electrode PD4 and the corresponding conductive layer 3 in the Z direction, the −Z-side end is electrically connected to the electrode PD4, the plug CP3 extends in the Z direction, and the +Z-side end is electrically connected to the corresponding conductive layer 3. Thus, the plug CP3 electrically connects the electrode PD4 and the corresponding conductive layer 3.

The plurality of plugs CP4 correspond to the plurality of electrodes PD4 and the plurality of electrodes PD5. Each plug CP4 is disposed between the corresponding electrode PD4 and the corresponding electrode PD5 in the Z direction, the −Z-side end is electrically connected to the electrode PD4, the plug CP4 extends in the Z direction, and the +Z-side end is electrically connected to the corresponding electrode PD5. Thus, the plug CP4 electrically connects the corresponding electrode PD4 and the corresponding electrode PD5.

A plurality of conductive films BL are disposed on the −Z side of the stacked body SST2. The plurality of conductive films BL are located in the X direction with each other. Each conductive film BL extends in the Y direction. The plurality of conductive films BL correspond to the plurality of columns CL. Each conductive film BL is electrically connected to the −Z-side end of the corresponding column CL and functions as a bit line BL. The conductive film BL is electrically connected to the electrode PD4. Thus, the bit line BL can be connected to the transistor Tr of the chip 10 via a plug, the electrode PD4, the electrode PD3, a plug, the electrode PD2, the electrode PD1, and the wiring structure WS.

A plurality of wirings MA2 are disposed on the +Z side of the stacked body SST2. The plurality of wirings MA2 are located in the X direction. Each wiring MA2 extends in the Y direction. Each wiring MA2 extends in the Y direction across the stacked body SST2 when viewed from the Z direction. Each wiring MA2 functions as power lines 22 and 23, and the width and thickness thereof may be set according to the amount of power to be transmitted and the required length. A detailed configuration of the wiring MA2 will be described later.

The electrode PD4 is disposed such that its surface is exposed to the bonding surface BF1 of the chips 10 and 20_2. The electrode PD5 is disposed such that its surface is exposed to the +Z-side surface of the chip 20_2.

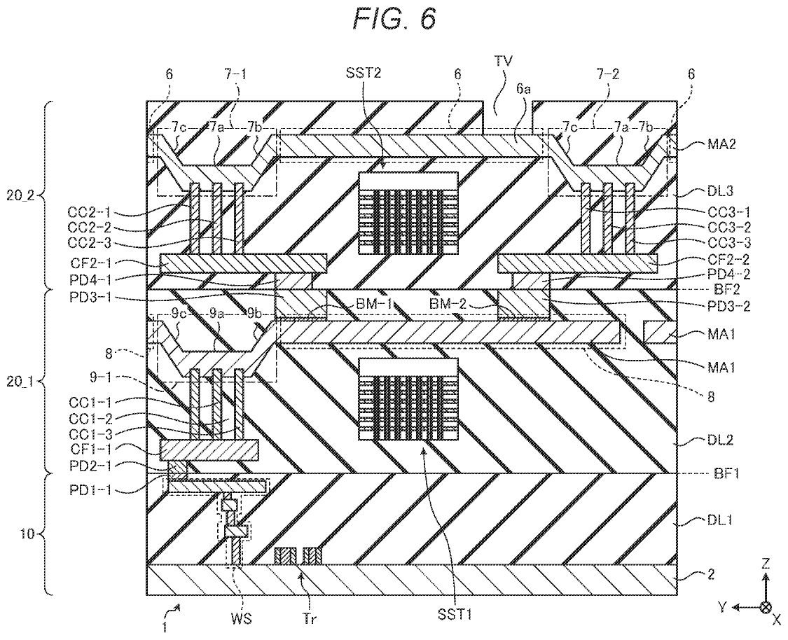

Next, a detailed configuration of the wirings MA1 and MA2 will be described with reference to FIG. 6. FIG. 6 is a YZ cross-sectional view showing the configuration of the semiconductor storage device 1, and illustrates the YZ cross-section taken along line B-B of FIG. 3.

The chip 10 has a transistor Tr, a wiring structure WS, and an electrode PD1-1. The electrode PD1-1 is disposed on the bonding surface BF1 of the chip 10 and the chip 20_1. The +Z-side surface of the electrode PD1-1 is exposed to the bonding surface BF1. The electrode PD1-1 has the −Z-side end connected to the transistor Tr via the wiring structure WS.

The chip 20_1 includes a stacked body SST1, a conductive film MA1, a conductive film CF1-1, a plurality of plugs CC1-1 to CC1-3, an electrode PD2-1, an electrode PD3-1, an electrode PD3-2, a barrier film BM-1, a barrier film BM-2, and an insulating film DL2.

The conductive film MA1 is disposed on the +Z side of the stacked body SST1. The conductive film MA1 functions as the wiring MA1 (see FIG. 3). The conductive film MA1 has a linear pattern in the XY plane view. The conductive film MA1 extends substantially in the Y direction across the stacked body SST1 when viewed from the Z direction. The conductive film MA1 may be made of a material containing a first metal as a main (primary) component. The first metal can be or comprise aluminum or the like. The conductive film MA1 has a routing portion 8 and a plug connection portion 9-1.

The plug connection portion 9-1 is disposed apart from the stacked body SST1 in the XY direction. The plug connection portion 9-1 is disposed at a position shifted in the Y direction from the stacked body SST1.

The routing portions 8 are disposed on both sides of the plug connection portion 9-1 in the Y direction, for example, at positions corresponding to the stacked body SST1. The routing portion 8 is substantially flat and extends in the Y direction while maintaining substantially the same Z height.

The plug connection portion 9-1 is connected adjacent to the routing portion 8 on the +Y side or the −Y side, and has a step of which Z height is lower than the routing portion 8. The plug connection portion 9-1 has a flat portion 9a, an inclined portion 9b, and an inclined portion 9c.

In the plug connection portion 9-1, the flat portion 9a is substantially flat and extends in the Y direction while maintaining substantially the same Z height. The Z height of the flat portion 9a is lower than the Z height of the routing portion 8. The +Z-side ends of the plugs CC1-1 to CC1-3 are connected to the flat portion 9a.

The inclined portion 9b is disposed on the −Y side of the flat portion 9a. The inclined portion 9b is connected to the routing portion 8 at the −Y-side end and connected to the flat portion 9a at the +Y-side end. The inclined portion 9b extends with an inclination such that the Z height decreases from the −Y side toward the +Y side. Thus, a step extending from the Z height of the routing portion 8 to the Z height of the flat portion 9a is formed.

The inclined portion 9c is disposed on the +Y side of the flat portion 9a. The inclined portion 9c has a +Y-side end connected to the routing portion 8 and a −Y-side end connected to the flat portion 9a. The inclined portion 9c extends with an inclination such that the Z height decreases from the +Y side toward the −Y side. Thus, a step extending from the Z height of the routing portion 8 to the Z height of the flat portion 9a is formed.

The conductive film CF1-1 is disposed apart from the stacked body SST1 in the XY direction. The conductive film CF1-1 is disposed at a position shifted in the Y direction from the stacked body SST1. The conductive film CF1-1 is disposed at the XY position corresponding to the plug connection portion 9-1. The conductive film CF1-1 is disposed at a position on the −Z side (deeper position) than the conductive film MA1. The conductive film CF1-1 may be made of a material containing a second metal as a main (primary) component. The second metal has a lower resistivity than the first metal. When the first metal can be aluminum, the second metal may be copper or the like.

A plurality of plugs CC1-1 to CC1-3 are disposed between the conductive film MA1 and the conductive film CF1-1 in the Z direction. The plurality of plugs CC1-1 to CC1-3 are disposed on the −Z side of the plug connection portion 9-1 and on the +Z side of the conductive film CF1-1. Each of the plugs CC1-1 to CC1-3 extends in the Z direction and connects the conductive film MA1 and the conductive film CF1-1. Each of the plugs CC1-1 to CC1-3 has a +Z-side end electrically connected to the plug connection portion 9-1 and a −Z-side end electrically connected to the conductive film CF1-1. Each plug CC1 may be made of a material containing a third metal as a main (primary) component. The third metal has a higher resistivity than the first metal. When the first metal contains aluminum or the like, the third metal contains tungsten or the like.

The electrode PD2-1 is disposed on the bonding surface BF1 of the chip 10 and the chip 20_1. The electrode PD2-1 is electrically connected to the conductive film CF1-1 and the electrode PD1-1. The electrode PD2-1 has a +Z-side surface in contact with the conductive film CF1-1 and a −Z-side surface exposed to the bonding surface BF1. The −Z-side surface of the electrode PD2-1 is in contact with the electrode PD1-1. The electrode PD2-1 may be made of a material containing the second metal as a main component.

The electrode PD3-1 is disposed on the bonding surface BF2 of the chip 20_1 and the chip 20_2. The electrode PD3-1 is disposed at the XY position corresponding to the routing portion 8 in the conductive film MA1. The electrode PD3-1 may be disposed at a position shifted in the +Y direction from the stacked body SST1.

The electrode PD3-1 is electrically connected to the conductive film MA1 through the barrier film BM-1 and electrically connected to the electrode PD4-1. The electrode PD3-1 has a −Z-side surface in contact with the barrier film BM-1 and a +Z-side surface exposed to the bonding surface BF2. The +Z-side surface of the electrode PD3-1 is in contact with the electrode PD4-1. The electrode PD3-1 may be made of a material containing the second metal as a main component.

The electrode PD3-2 is disposed on the bonding surface BF2 of the chip 20_1 and the chip 20_2. The electrode PD3-2 is disposed at the XY position corresponding to the routing portion 8 in the conductive film MA1. The electrode PD3-1 may be disposed at a position shifted in the −Y direction from the stacked body SST1.

The electrode PD3-2 is electrically connected to the conductive film MA1 through the barrier film BM-2 and electrically connected to the electrode PD4-2. The electrode PD3-2 has a −Z-side surface in contact with the barrier film BM-2 and a +Z-side surface exposed to the bonding surface BF2. The +Z-side surface of the electrode PD3-2 is in contact with the electrode PD4-2. The electrode PD3-2 may be made of a material containing the second metal as a main component.

The barrier film BM-1 is disposed between the electrode PD3-1 and the conductive film MA1 in the Z direction. The barrier film BM-1 has a +Z-side surface in contact with the electrode PD3-1 and a −Z-side surface in contact with the conductive film MA1. The barrier film BM-1 may be made of a material containing a fourth metal as a main (primary) component. The fourth metal serves as a barrier to diffusion of the first metal and the second metal. The fourth metal can be, for example, titanium nitride. Thus, the second metal element contained in the electrode PD3-1 can be prevented from diffusing toward the conductive film MA1 side, and the first metal element contained in the conductive film MA1 can be prevented from diffusing toward the electrode PD3-1 side.

The barrier film BM-2 is disposed between the electrode PD3-2 and the conductive film MA1 in the Z direction. The barrier film BM-2 has a +Z-side surface in contact with the electrode PD3-2 and a −Z-side surface in contact with the conductive film MA1. The barrier film BM-2 may be made of a material containing the fourth metal as a main component. The fourth metal has barrier properties for preventing (limiting) diffusion of the first metal and the second metal. The fourth metal can be, for example, titanium nitride. Thus, the second metal element contained in the electrode PD3-2 can be prevented from diffusing toward the conductive film MA1 side, and the first metal element contained in the conductive film MA1 can be prevented from diffusing toward the electrode PD3-2 side.

The chip 20_2 includes the stacked body SST2, a conductive film MA2, a conductive film CF2-1, a plurality of plugs CC2-1 to CC2-3, a conductive film CF2-2, a plurality of plugs CC3-1 to CC3-3, an electrode PD4-1, an electrode PD4-2, and the insulating film DL3.

The conductive film MA2 is disposed on the +Z side of the stacked body SST2. The conductive film MA2 functions as the wiring MA2 (see FIG. 3). The conductive film MA2 has a linear pattern in the XY plane view. The conductive film MA2 extends substantially in the Y direction across the stacked body SST2 when viewed from the Z direction. The conductive film MA2 may be made of a material containing the first metal as a main component. The first metal contains aluminum or the like. The conductive film MA2 has a routing portion 6 and plug connection portions 7-1 and 7-2.

The plug connection portions 7-1 and 7-2 each are disposed apart from the stacked body SST2 in the XY direction. The plug connection portion 7-1 is disposed at a position shifted in the +Y direction from the stacked body SST2. The plug connection portion 7-2 is disposed at a position shifted in the −Y direction from the stacked body SST2.

The routing portions 6 are disposed on the both sides of the plug connection portion 7-1 in the Y direction and on the both sides of the plug connection portion 7-2 in the Y direction, for example, at positions corresponding to the stacked body SST2. The routing portion 6 is substantially flat and extends in the Y direction while maintaining substantially the same Z height.

The plug connection portion 7-1 is connected adjacent to the routing portion 6 on both sides in the Y direction, and has a step of which Z height is lower than the routing portion 6. The plug connection portion 7-1 has a flat portion 7a, an inclined portion 7b, and an inclined portion 7c.

In the plug connection portion 7-1, the flat portion 7a is substantially flat and extends in the Y direction while maintaining substantially the same Z height. The Z height of the flat portion 7a is lower than the Z height of the routing portion 6. The +Z-side ends of the plugs CC2-1 to CC2-3 are connected to the flat portion 7a.

The inclined portion 7b is disposed on the −Y side of the flat portion 7a. The inclined portion 7b has a −Y-side end connected to the routing portion 6 and a +Y-side end connected to the flat portion 7a. The inclined portion 7b extends with an inclination such that the Z height decreases from the −Y side toward the +Y side. Thus, a step extending from the Z height of the routing portion 6 to the Z height of the flat portion 7a is formed on the −Y side of the flat portion 7a.

The inclined portion 7c is disposed on the +Y side of the flat portion 7a. The inclined portion 7c has a +Y-side end connected to the routing portion 6 and a −Y-side end connected to the flat portion 7a. The inclined portion 7c extends with an inclination such that the Z height decreases from the +Y side toward the −Y side. Thus, a step extending from the Z height of the routing portion 6 to the Z height of the flat portion 7a is formed on the +Y side of the flat portion 7a.

The plug connection portion 7-2 is connected adjacent to the routing portion 6 on both sides in the Y direction, and has a step of which Z height is lower than the routing portion 6. The plug connection portion 7-2 has a flat portion 7a, an inclined portion 7b, and an inclined portion 7c.

In the plug connection portion 7-2, the flat portion 7a is substantially flat and extends in the Y direction while maintaining substantially the same Z height. The Z height of the flat portion 7a is lower than the Z height of the routing portion 6. The +Z-side ends of the plugs CC3-1 to CC3-3 are connected to the flat portion 7a.

The inclined portion 7b is disposed on the −Y side of the flat portion 7a. The inclined portion 7b has a −Y-side end connected to the routing portion 6 and a +Y-side end connected to the flat portion 7a. The inclined portion 7b extends with an inclination such that the Z height decreases from the −Y side toward the +Y side. Thus, a step extending from the Z height of the routing portion 6 to the Z height of the flat portion 7a is formed on the −Y side of the flat portion 7a.

The inclined portion 7c is disposed on the +Y side of the flat portion 7a. The inclined portion 7c has a +Y-side end connected to the routing portion 6 and a −Y-side end connected to the flat portion 7a. The inclined portion 7c extends with an inclination such that the Z height decreases from the +Y side toward the −Y side. Thus, a step extending from the Z height of the routing portion 6 to the Z height of the flat portion 7a is formed on the +Y side of the flat portion 7a.

A portion 6a at the XY positions adjacent to the inclined portion 7c of the plug connection portion 7-2 in the routing portion 6 has a +Z-side surface exposed through the opening TV, and functions as an electrode portion. A wire for wire bonding mounting may be bonded to the +Z-side surface of an electrode portion 6a through the opening TV.

The conductive film CF2-1 is disposed apart from the stacked body SST2 in the XY direction. The conductive film CF2-1 is disposed at a position shifted in the +Y direction from the stacked body SST2. The conductive film CF2-1 is disposed at the XY position corresponding to the plug connection portion 7-1. The conductive film CF2-1 is disposed at a position on the −Z side (deeper position) than the conductive film MA2. The conductive film CF2-1 may be made of a material containing the second metal as a main component.

A plurality of plugs CC2-1 to CC2-3 are disposed between the conductive film MA2 and the conductive film CF2-1 in the Z direction. The plurality of plugs CC2-1 to CC2-3 are disposed on the −Z side of the plug connection portion 7-1 and on the +Z side of the conductive film CF2-1. Each of the plugs CC2-1 to CC2-3 extends in the Z direction and connects the conductive film MA2 and the conductive film CF2-1. Each of the plugs CC2-1 to CC2-3 has a +Z-side end electrically connected to the plug connection portion 7-1 and a −Z-side end electrically connected to the conductive film CF2-1. Each plug CC2 may be made of a material containing the third metal as a main component.

The conductive film CF2-2 is disposed apart from the stacked body SST2 in the XY direction. The conductive film CF2-2 is disposed at a position shifted in the −Y direction from the stacked body SST2. The conductive film CF2-2 is disposed at the XY position corresponding to the plug connection portion 7-2. The conductive film CF2-2 is disposed at a position on the −Z side (deeper position) than the conductive film MA2. The conductive film CF2-2 may be made of a material containing the second metal as a main component.

A plurality of plugs CC3-1 to CC3-3 are disposed between the conductive film MA2 and the conductive film CF2-2 in the Z direction. The plurality of plugs CC3-1 to CC3-3 are disposed on the −Z side of the plug connection portion 7-2 and on the +Z side of the conductive film CF2-2. Each of the plugs CC3-1 to CC3-3 extends in the Z direction and connects the conductive film MA2 and the conductive film CF2-2. Each of the plugs CC3-1 to CC3-3 has a +Z-side end electrically connected to the plug connection portion 7-2 and a −Z-side end electrically connected to the conductive film CF2-2. Each plug CC3 may be made of a material containing the third metal as a main component.

The electrode PD4-1 is disposed on the bonding surface BF2 of the chip 20_1 and the chip 20_2. The electrode PD4-1 is disposed at the XY position corresponding to the conductive film CF2-1. The electrode PD4-1 is disposed at a position shifted in the +Y direction from the stacked body SST2.

The electrode PD4-1 is electrically connected to the conductive film CF2-1 and the electrode PD3-1. The electrode PD4-1 has a +Z-side surface in contact with the conductive film CF2-1 and a −Z-side surface exposed to the bonding surface BF2. The −Z-side surface of the electrode PD4-1 is in contact with the electrode PD3-1. The electrode PD4-1 may be made of a material containing the second metal as a main component.

The electrode PD4-2 is disposed on the bonding surface BF2 of the chip 20_1 and the chip 20_2. The electrode PD4-2 is disposed at the XY position corresponding to the conductive film CF2-2. The electrode PD4-2 is disposed at a position shifted in the −Y direction from the stacked body SST2.

The electrode PD4-2 is electrically connected to the conductive film CF2-2 and the electrode PD3-2. The electrode PD4-2 has a +Z-side surface in contact with the conductive film CF2-2 and a −Z-side surface exposed to the bonding surface BF2. The −Z-side surface of the electrode PD4-2 is in contact with the electrode PD3-2. The electrode PD4-2 may be made of a material containing the second metal as a main component.

In the connection configuration from the opening TV (electrode portion 6a) to the transistor Tr shown in FIG. 6, the conductive film MA2 of the chip 20_2 and the conductive film MA1 of the chip 20_1 are connected in parallel. A common connection path is connected between the electrode portion 6a and the transistor Tr. A first connection path and a second connection path are connected in parallel between the electrode portion 6a and the common connection path.

The first connection path includes the electrode portion 6a→the routing portion 6→the plug connection portion 7-1→the plugs CC2-1 to CC2-3→the conductive film CF2-1→the electrode PD4-1→the electrode PD3-1→the barrier film BM-1→the routing portion 8. The second connection path includes the electrode portion 6a→the plug connection portion 7-2→the plugs CC3-1 to CC3-3→the conductive film CF2-2→the electrode PD4-2→the electrode PD3-2→the barrier film BM-2→the routing portion 8. The common connection path includes the plug connection portion 9-1→the plugs CC1-1 to CC1-3→the conductive film CF1-1→the electrode PD2-1→the electrode PD1-1→the wiring structure WS. The first connection path and the second connection path join at the plug connection portion 9-1 and are connected to the transistor Tr of the chip 10 via the common connection path. Thus, the conductive films MA1 and MA2 are connected in parallel between the electrode portion 6a and the common connection path.

The conductive film MA1 functions as the wiring MA1, and the conductive film MA2 functions as the wiring MA2. As described above, the wiring MA1 and the wiring MA2 function as power lines 22 and 23, respectively, and the width and thickness thereof may be set according to the amount of power to be transmitted and the required wiring length. Since the first connection path and the second connection path are parallel, the resistance of the connection configuration from the opening TV (electrode portion 6a) to the transistor Tr can be easily reduced. Thus, the wiring MA1 and the wiring MA2 can be reduced in the thickness by about half while maintaining the same length. That is, the wiring MA1 and the wiring MA2 can be thinned while still satisfying the required characteristics.

Alternatively, since the first connection path and the second connection path are parallel, the resistance of the connection configuration from the opening TV (electrode portion 6a) to the transistor Tr can be easily reduced. Thus, the wiring MA1 and the wiring MA2 can be approximately doubled in length while maintaining the same thickness (which is set according to the amount of power to be transmitted). That is, the wiring MA1 and the wiring MA2 can be elongated while still satisfying the required characteristics.

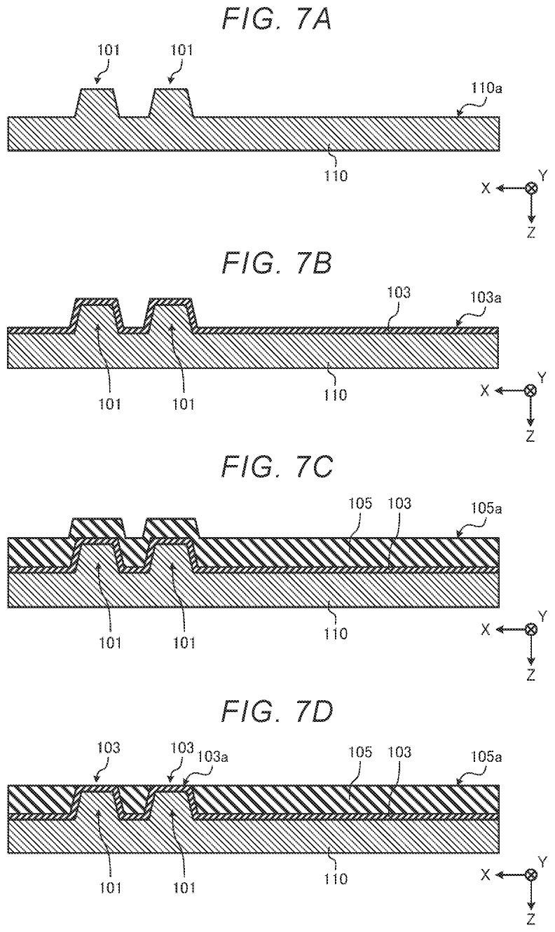

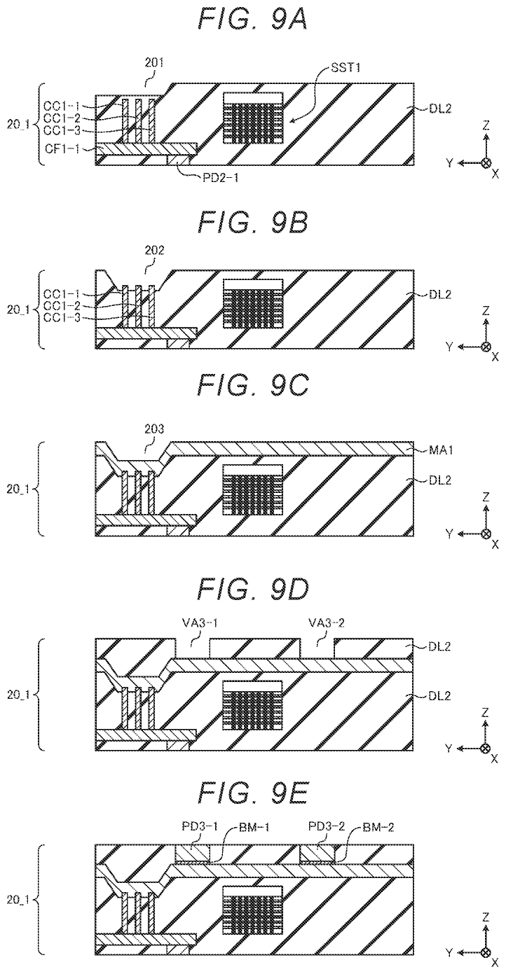

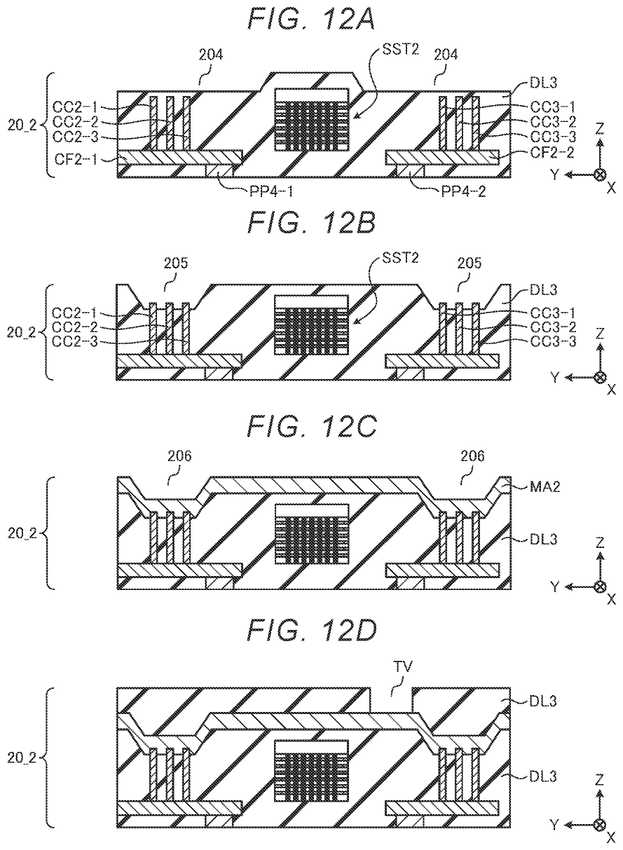

Next, a manufacturing method of the semiconductor storage device 1 will be described with reference to FIGS. 7 to 13. FIGS. 7A to 7D, 8A to 8C, 9A to 9E, 10A and 10B, 11A and 11B, 12A to 12D, and 13 are cross-sectional views showing the manufacturing method of the semiconductor storage device 1. FIGS. 7A to 7D, 8A to 8C, 10A and 10B, 11A and 11B, and 13 show XZ cross sections corresponding to FIG. 4. FIGS. 9A to 9E and 12A to 12D show YZ cross sections corresponding to FIG. 6. FIGS. 9A to 9E selectively show a portion of the chip 20_1 for simplification. FIGS. 12A to 12D selectively show a portion of the chip 20_2 for simplification.

In the step of FIG. 7A, a substrate 110 is prepared. The substrate 110 may be made of a semiconductor material (for example, silicon) as a main component. The substrate 110 has a main surface 110a on the −Z side. A resist pattern RP1 selectively covers a region in which the convex portion 101 is to be formed on the main surface 110a of the substrate 110. Etching is performed using the resist pattern RP1 as a mask. Thus, the convex portion 101 is formed on the main surface 110a of the substrate 110.

In the step of FIG. 7B, an insulating film 103 is deposited on the main surface 110a of the substrate 110 by Low Pressure Chemical Vapor Deposition (LPCVD) method or the like. The insulating film 103 may be made of an insulating material such as silicon nitride. The insulating film 103 has a main surface 103a on the −Z side.

In the step of FIG. 7C, an insulating film 105 is deposited on the main surface 103a of the insulating film 103 by a Chemical Vapor Deposition (CVD) method or the like. The insulating film 105 may be made of an insulating material such as silicon nitride. The insulating film 105 has a main surface 105a on the −Z side.

In the step of FIG. 7D, the main surface 105a of the insulating film 105 is planarized by the Chemical Mechanical Polishing (CMP) method or the like. The planarization is performed until the main surface 103a of the insulating film 103 is exposed.

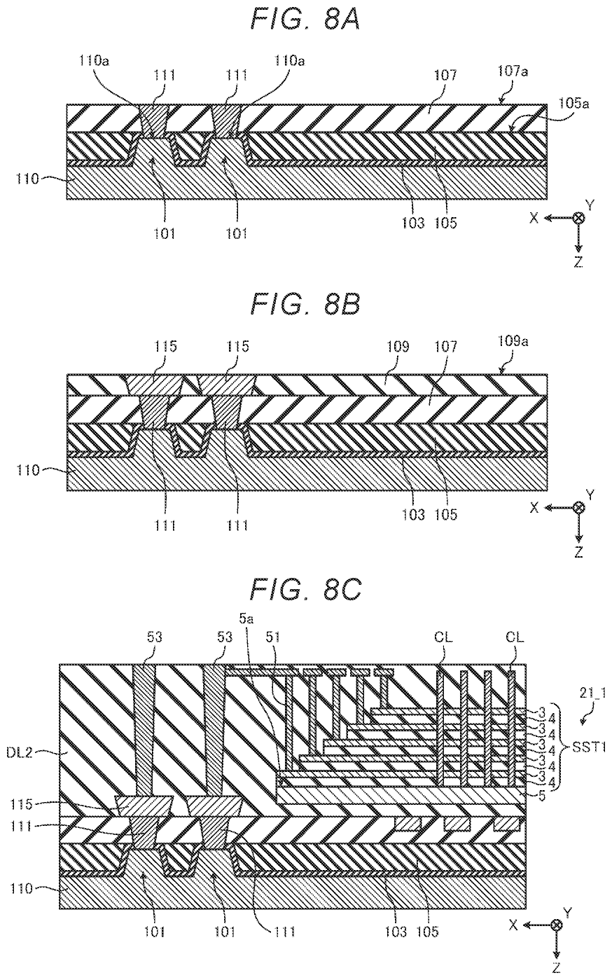

In the step of FIG. 8A, an insulating film 107 is deposited on the exposed main surface 103a of the insulating film 103 and the main surface 105a of the insulating film 105 by the CVD method or the like. The insulating film 107 may be made of an insulating material such as silicon nitride. The insulating film 107 has a main surface 107a on the −Z side. Subsequently, a resist pattern RP2 having openings in a region corresponding to the convex portion 101 on the main surface 107a of the insulating film 107 is formed. Etching is performed using the resist pattern RP2 as a mask until the main surface 110a of the convex portion 101 is exposed. Thus, an opening in the insulating film 107 is formed. This opening is filled with a conductive material (for example, a material containing a metal such as tungsten as a main component). Thus, a plug 111 extending from the main surface 107a of the insulating film 107 to the main surface 110a of the convex portion 101 is formed.

In the step of FIG. 8B, an insulating film 109 is deposited on the main surface 107a of the insulating film 107. The insulating film 109 may be made of an insulating material such as silicon nitride. The insulating film 109 has a main surface 109a on the −Z side. Subsequently, a resist pattern RP3 having an opening in a region corresponding to the plugs 111 on the main surface 109a of the insulating film 109 is formed. Etching is performed using the resist pattern RP3 as a mask until the plug 111 is exposed. Thus, an opening in the insulating film 109 is formed. This opening is filled with a conductive material (for example, a material containing a metal such as tungsten as a main component). Thus, a conductive film 115 in contact with the main surface of plug 111 is formed.

In the step of FIG. 8C, the structure of the memory cell array 21_1 is formed on the main surface 109a of the insulating film 109. In the memory cell array 21_1, the conductive layer 5 is stacked on the main surface 109a, and the stacked body SST1 is stacked on the conductive layer 5. In the stacked body SST1, the insulating layer 4 and the conductive layer 3 are alternately stacked plurality of times in the Z direction. The stacked body SST1 is penetrated by a plurality of columns CL each extending in the Z direction and located in the XY direction. A memory hole penetrating the stacked body SST1 is formed, and the insulating film BLK2, the insulating film BLK1, the charge storage film CT, the insulating film TNL, the semiconductor film CH, and the insulating film CR shown in FIG. 5A are embedded in the memory hole to form the column CL. As shown in FIG. 8C, an insulating film DL2 is deposited around the memory cell array 21_1. A hole is formed in the insulating film DL2 and filled with a conductive material (for example, a material containing a metal such as copper as a main component). Thus, a plug 51 extending in the Z direction and reaching the conductive layer 3 and a plug 53 extending in the Z direction and reaching the conductive film 115 are formed.

At this time, as shown in FIG. 9A, a hole is formed in the insulating film DL2 at a position shifted in the Y direction from the stacked body SST1, and is filled with a material containing a third metal (for example, tungsten or the like) as a main component. Thus, a plurality of plugs CC1-1 to CC1-3 extending in the Z direction are formed. Then, a conductive film is deposited on the −Z side of the insulating film DL2 using a material containing a second metal (for example, copper or the like) as a main component. A region overlapping the plurality of plugs CC1-1 to CC1-3 is patterned to form a conductive film CF1-1.

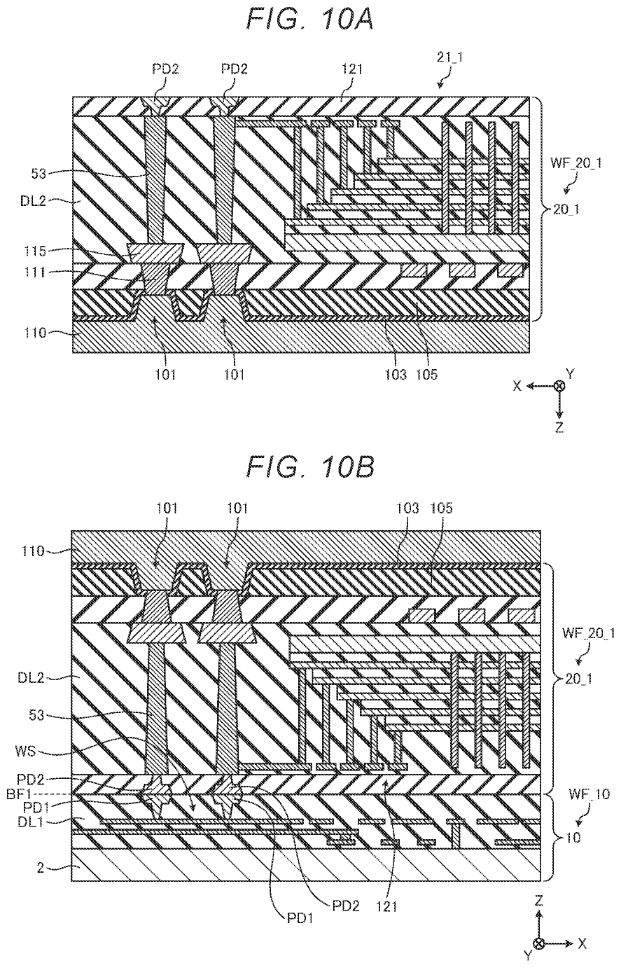

In the step of FIG. 10A, an insulating film 121 is deposited on the −Z side of the memory cell array 21_1. The insulating film 121 may be made of an insulating material such as silicon oxide. Subsequently, a resist pattern RP4 having an opening in a region corresponding to the plug 53 is formed on the −Z side of the insulating film 121. Etching is performed using the resist pattern RP4 as a mask until the plug 53 is exposed. Thus, an opening in the insulating film 121 is formed. This opening is filled with a conductive material (for example, a material containing a metal such as copper as a main component). Thus, an electrode PD2 electrically connected to the plug 53 is formed. Thus, a substrate WF_20_1 including a plurality of chips 20_1 is formed.

At this time, an opening is formed in the insulating film DL2 in a region corresponding to the conductive film CF1-1 shown in FIG. 9A, and is filled with a material containing a second metal (for example, copper or the like) as a main component. Thus, an electrode PD2-1 electrically connected to the conductive film CF1-1 is formed.

In the step of FIG. 10B, a substrate WF_10 including a plurality of chips 10 is formed. In each chip 10 on the substrate WF_10, the gate electrode of the transistor Tr is formed on the surface 2a of the substrate 2, the source and drain electrodes are formed as semiconductor regions near the surface 2a of the substrate 2, the insulating film DL1 is deposited, and a wiring structure WS is formed. A resist pattern RP5 having an opening in a region corresponding to the wiring structure WS is formed on the −Z side of the insulating film DL1. Etching is performed using the resist pattern RP5 as a mask until the wiring structure WS is exposed. Thus, an opening in the insulating film DL1 is formed. This opening is filled with a conductive material (for example, a material containing a metal such as copper as a main component). Thus, an electrode PD1 electrically connected to the wiring structure WS is formed. Thus, a substrate WF_10 including the plurality of chips 10 is formed.

After that, the −Z-side surface of the substrate WF_20_1 and the +Z-side surface of the substrate WF_10 may be activated through plasma treatment. The −Z-side surface of the substrate WF_20_1 faces the +Z-side surface of the substrate WF_10. At this time, the substrate WF_20_1 and the substrate WF_10 face each other such that the XY position of the electrode PD2 and the XY position of the electrode PD1 match. The substrate WF_20_1 and the substrate WF_10 are brought close to each other in the Z direction, and the substrate WF_20_1 and the substrate WF_10 are bonded. At this time, the substrate WF_20_1 and the substrate WF_10 may be heated and pressurized.

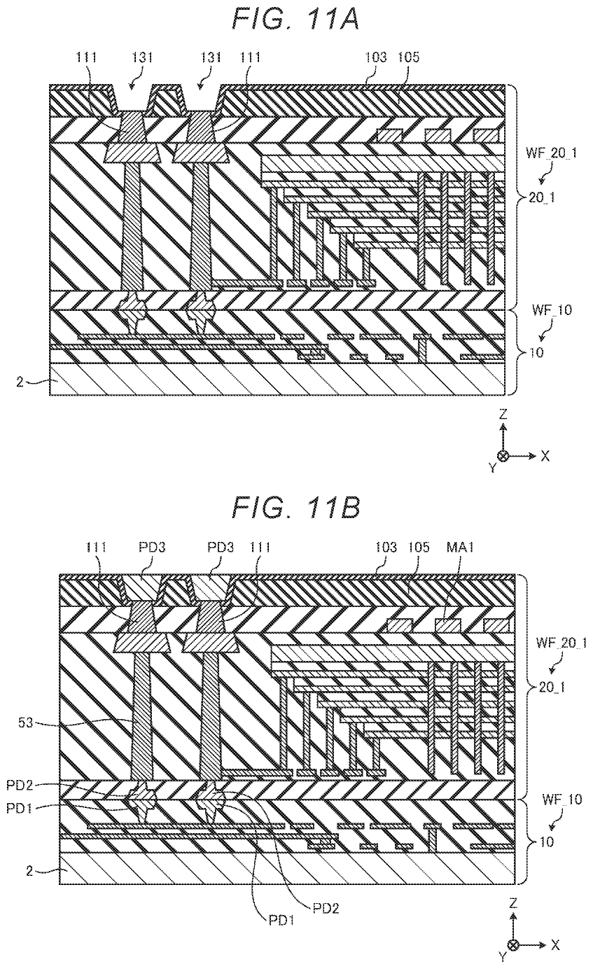

In the step of FIG. 11A, the substrate 110 is removed. The substrate 110 may be removed by polishing the substrate 110 from the +Z side followed by wet etching. Thus, the insulating film 103 is exposed, and a recess portion 131 is formed after the convex portion 101 is removed. The +Z-side surface of the plug 111 is exposed on the bottom surface of the recess portion 131.

At this time, as shown in FIG. 9A, a recess portion 201 is formed at a position shifted in the Y direction from the stacked body SST1, on the +Z-side surface of the insulating film DL2.

In the step of FIG. 11B, the recess portion 131 is filled with a conductive material (for example, a material containing a metal such as copper as a main component). Thus, an electrode PD3 electrically connected to the plug 111 is formed.

At this time, as shown in FIG. 9B, at a position shifted from the stacked body SST1 in the Y direction, the insulating film DL2 is embedded in the recess portion 201 and planarized, and then a region for a plurality of plugs CC1-1 to CC1-3 is selectively etched until the edges on the +Z side are exposed to form a recess portion 202.

Then, as shown in FIG. 9C, a conductive film MA1 functioning as a wiring MA1 is formed by a material containing a first metal (for example, aluminum) as a main component being deposited, and being patterned into a line extending in the Y direction. On the +Z side of the wiring MA1, a recess portion 203 is formed in the region corresponding to the plurality of plugs CC1-1 to CC1-3.

Thereafter, as shown in FIG. 9D, an insulating film DL2 is deposited to fill the recess portion 203 and cover the conductive film MA1. Openings VA3-1 and VA3-2 that expose the conductive film MA1 are formed at positions corresponding to both sides of the stacked body SST1 in the Y direction in the insulating film DL2.

As shown in FIG. 9E, barrier films BM-1 and BM-2 are deposited on the bottoms of the openings VA3-1 and VA3-2. The barrier films BM-1 and BM-2 may be made of a material containing the fourth metal as a main component. The fourth metal has barrier properties preventing (limiting) diffusion of the first metal and the second metal. The fourth metal can be, for example, titanium nitride. Further, the openings VA3-1 and VA3-2 are filled with a material containing a second metal (for example, copper) as a main component. Thus, electrodes PD3-1 and PD3-2 electrically connected to the conductive film MA1 are formed.

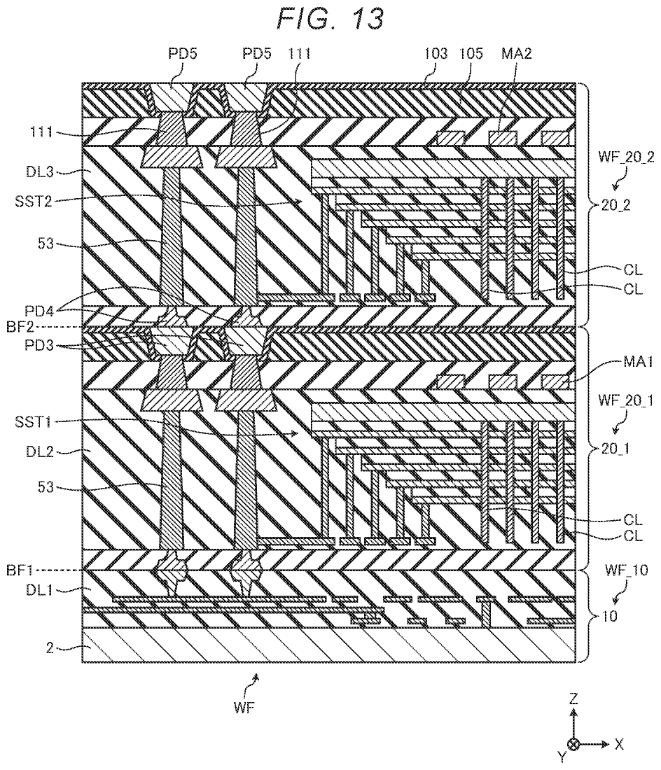

Thereafter, in the same manner as the steps of FIGS. 7A to 7D, 8A to 8C, and 10A, a structure of the memory cell array 11_2 in which the stacked body SST2, in which the insulating layers 4 and the conductive layers 3 are alternately stacked a plurality of times in the Z direction, is penetrated in the Z direction by the plurality of columns CL, and the peripheral structure thereof are formed. An electrode PD5 (see FIG. 13) is formed on the +Z-side surface. Thus, a substrate WF_20_2 including a plurality of chips 20_2 is formed.

At this time, as shown in FIG. 12A, holes are formed in the insulating film DL3 at positions shifted to both sides in the Y direction from the stacked body SST2, and are filled with a material containing a third metal (for example, tungsten or the like) as a main component. Thus, a plurality of plugs CC2-1 to CC2-3 and a plurality of plugs CC3-1 to CC3-3 extending in the Z direction are formed on both sides of the stacked body SST2 in the Y direction, respectively. Then, a conductive film is deposited on the −Z side of the insulating film DL3 using a material containing a second metal (for example, copper or the like) as a main component. A region overlapping the plurality of plugs CC2-1 to CC2-3 and a region overlapping the plurality of plugs CC3-1 to CC3-3 are patterned, respectively. Thus, a conductive film CF2-1 and a conductive film CF2-2 are formed.

Openings are formed in the insulating film DL3 in a region corresponding to the conductive film CF2-1 and a region corresponding to the conductive film CF2-2, and are filled with a material containing a second metal (for example, copper or the like) as a main component. Thus, an electrode PD2-1 electrically connected to the conductive film CF2-1 and an electrode PD2-2 electrically connected to the conductive film CF2-2 are formed.

After that, on the +Z-side surface of the insulating film DL3, recess portions 204 are formed at positions shifted to both sides in the Y direction from the stacked body SST2.

As shown in FIG. 12B, at positions shifted to both sides in the Y direction from the stacked body SST2, the insulating film DL3 is embedded in the recess portions 204 and planarized. Thereafter, a region for the plurality of plugs CC2-1 to CC2-3 is selectively etched until the edges on the +Z side are exposed, and a region for the plurality of plugs CC3-1 to CC3-3 is selectively etched until the edges on the +Z side are exposed. Thus, recess portions 205 are formed on both sides in the Y direction of the stacked body SST2.

Then, as shown in FIG. 12C, a conductive film MA2 functioning as a wiring MA2 is formed by a material containing a first metal (for example, aluminum or the like) as a main component being deposited, and being patterned into a line extending in the Y direction. On the +Z side of the wiring MA2, recess portions 206 are formed in the region corresponding to the plurality of plugs CC2-1 to CC2-3 and the region corresponding to the plurality of plugs CC3-1 to CC3-3, respectively.

After that, as shown in FIG. 12D, the insulating film DL3 is deposited to fill the recess portions 206 on both sides of the stacked body SST2 in the Y direction and cover the conductive film MA2. An opening TV that exposes the conductive film MA2 is formed at a position corresponding to the −Y side of the stacked body SST2 in the insulating film DL3.

In the step of FIG. 13, the −Z-side surface of the substrate WF_20_2 and the +Z-side surface of the substrate WF_20_1 may be activated through plasma treatment. The −Z-side surface of the substrate WF_20_2 faces the +Z-side surface of the substrate WF_20_1. At this time, the substrate WF_20_2 and the substrate WF_20_1 face each other such that the XY position of the electrode PD4 and the XY position of the electrode PD3 match. The substrate WF_20_2 and the substrate WF_20_1 are brought close to each other in the Z direction, and the substrate WF_20_2 and the substrate WF_20_1 are bonded. At this time, the substrate WF_20_2 and the substrate WF_20_1 may be heated and pressurized.

Thus, a stacked substrate WF is obtained in which the substrate WF_10, the substrate WF_20_1, and the substrate WF_20_2 are stacked in order in the Z direction. The stacked substrate WF includes a plurality of chip regions. Each chip region has a structure in which the chips 10, 20_1, and 20_2 are stacked. By dicing the stacked substrate WF at the boundaries of the plurality of chip regions, the plurality of chip regions are separated into pieces. Thus, the semiconductor storage device 1 including the chip region is obtained.

As described above, in the first embodiment, in the connection configuration from the opening TV (electrode portion 6a) to the transistor Tr in the semiconductor storage device 1, the conductive film MA2 of the chip 20_2 and the conductive film MA1 of the chip 20_1 are connected in parallel. The conductive film MA1 functions as the wiring MA1, and the conductive film MA2 functions as the wiring MA2. Therefore, the resistance of the connection configuration using the wiring MA1 and the wiring MA2 can be easily reduced. Thus, the wiring MA1 and the wiring MA2 can be reduced in the thickness by about half while maintaining the same length. That is, the wiring MA1 and the wiring MA2 can be thinned while satisfying the required characteristics.

In the first embodiment, the resistance of the connection configuration using the wiring MA1 and the wiring MA2 can be easily reduced. Thus, the wiring MA1 and the wiring MA2 can be approximately doubled in length while maintaining the same thickness according to the amount of power to be transmitted. That is, the wiring MA1 and the wiring MA2 can be elongated without increasing the film thickness while still satisfying the required resistance characteristics or the like.

For example, the wiring MA1 and the wiring MA2 may be elongated in accordance with a required change in a planar configuration.

In a case where the wiring MA1 (conductive film MA1) and the wiring MA2 (conductive film MA2) are thickened in order to reduce the resistance as the length is increased, when the stacked substrate WF is diced, the stress that the conductive film MA1 and the conductive film MA2 receive from the dicing blade tends to increase. Thus, the conductive films MA1 and MA2 may peel off in the vicinity of the edges of the chips 20_1 and 20_2, which may reduce the reliability of mounting the chips 20_1 and 20_2.

In the first embodiment, the wiring MA1 and the wiring MA2 can be thinned while still satisfying the required characteristics, so that the peeling of the conductive films MA1 and MA2 can be reduced during dicing, which can improve reliability of mounting.

When the wiring MA2 is thickened in order to reduce the resistance while the length is increased, voids tend to be formed when the wire is bonded to the electrode portion 6a of the wiring MA2 through the opening TV. This may cause bonding failure.

In the first embodiment, the wiring MA2 can be thinned while still satisfying the required characteristics, so that the occurrence of voids in the electrode portion 6a during bonding can be reduced, and bonding failure can be reduced.

When the wiring MA2 is thickened in order to reduce the resistance while the length is increased, the step on the upper surface of the insulating film DL3 tends to increase. Thus, an increase in the amount of the protective film deposited on the upper surface of the insulating film DL3 later may increase the processing cost of the protective film.

In the first embodiment, the wiring MA2 can be made thinner while still satisfying the required characteristics, so that the deposition amount for the protective film can be reduced, thereby reducing processing costs of the protective film.

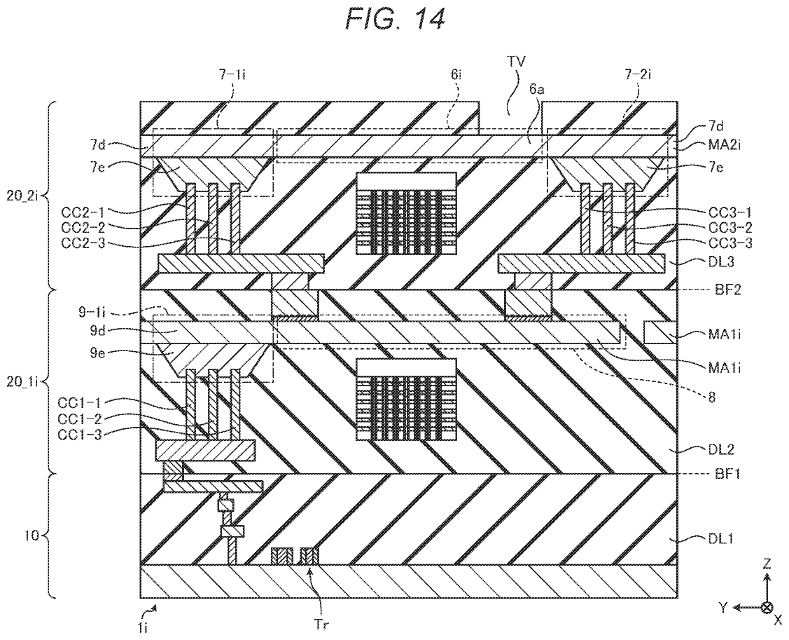

It is noted that as a first modification of the first embodiment, as shown in FIG. 14, a semiconductor storage device 1i may be implemented such that the surfaces on the +Z side of wirings MA1i and MA2i are flat. FIG. 14 is a YZ cross-sectional view showing the configuration of the semiconductor storage device 1i according to the first modification of the first embodiment, and corresponds to the YZ cross-section taken along line B-B of FIG. 3.

The semiconductor storage device 1i has chips 20_1i and 20_2i instead of the chips 20_1 and 20_2 (see FIG. 6).

The chip 20_1i has a conductive film MA1i instead of the conductive film MA1 (see FIG. 6). The conductive film MA1i functions as the wiring MA1i. The conductive film MA1i has a plug connection portion 9-1i instead of the plug connection portion 9-1 (see FIG. 6).

The plug connection portion 9-1i has a flat portion 9d and a convex portion 9e.

In the plug connection portion 9-1i, the flat portion 9d is substantially flat and extends in the Y direction while maintaining substantially the same Z height. The Z height of the flat portion 9d is equal to the Z height of the routing portion 8. The flat portion 9d is continuous with the routing portion 8 at the Y-direction end. Thus, the +Z-side surface of the conductive film MA1i can be formed substantially flat.

The convex portion 9e is disposed on the −Z side of the flat portion 9d, and has a convex shape from the flat portion 9d to the −Z side. The convex portion 9e has a substantially isosceles trapezoidal shape in a YZ cross-sectional view. A substantially isosceles trapezoidal shape has an upper base that is longer than a lower base. The convex portion 9e has side surfaces that are inclined on both sides in the Y direction. Thus, a step extending from the Z height of the routing portion 8 to the Z height of the base of the convex portion 9e is formed.

The flat portion 9d may be made of a material containing the first metal as a main component. The convex portion 9e may be made of a material containing the second metal or the third metal as a main component. The second metal has a lower resistivity than the resistivity of the first metal. The third metal has a higher resistivity than the resistivity of the first metal. When the first metal contains aluminum or the like, the second metal contains copper or the like, and the third metal contains tungsten or the like.

The chip 20_2i has a conductive film MA2i instead of the conductive film MA2 (see FIG. 6). The conductive film MA2i functions as the wiring MA2i. The conductive film MA2i has plug connection portions 7-1i and 7-2i instead of the plug connection portions 7-1 and 7-2 (see FIG. 6).

The plug connection portion 7-1i has a flat portion 7d and a convex portion 7e.

In the plug connection portion 7-1i, the flat portion 7d is substantially flat and extends in the Y direction while maintaining substantially the same Z height. The Z height of the flat portion 7d is equal to the Z height of the routing portion 6. The flat portion 7d is continuous with the routing portion 6 at the Y-direction end. Thus, the +Z-side surface of the conductive film MA2i can be formed substantially flat.

The convex portion 7e is disposed on the −Z side of the flat portion 7d and has a convex shape from the flat portion 7d to the −Z side. The convex portion 7e has a substantially isosceles trapezoidal shape in a YZ cross-sectional view. A substantially isosceles trapezoidal shape has an upper base that is longer than a lower base. The convex portion 7e has side surfaces that are inclined on both sides in the Y direction. Thus, a step extending from the Z height of the routing portion 8 to the Z height of the base of the convex portion 7e is formed. The +Z-side ends of the plugs CC2-1 to CC2-3 are connected to the convex portion 7e.

The flat portion 7d may be made of a material containing the first metal as a main component. The convex portion 7e may be made of a material containing the second metal as a main component. The second metal has a lower resistivity than the resistivity of the first metal. When the first metal contains aluminum or the like, the second metal contains copper or the like.

The plug connection portion 7-2i has a flat portion 7d and a convex portion 7e.

In the plug connection portion 7-2i, the flat portion 7d is substantially flat and extends in the Y direction while maintaining substantially the same Z height. The Z height of the flat portion 7d is equal to the Z height of the routing portion 6. The flat portion 7d is continuous with the routing portion 6 at the Y-direction end. Thus, the +Z-side surface of the conductive film MA2i can be formed substantially flat.

The convex portion 7e is disposed on the −Z side of the flat portion 7d and has a convex shape from the flat portion 7d to the −Z side. The convex portion 7e has a substantially isosceles trapezoidal shape in a YZ cross-sectional view. A substantially isosceles trapezoidal shape has an upper base that is longer than a lower base. The convex portion 7e has side surfaces that are inclined on both sides in the Y direction. Thus, a step extending from the Z height of the routing portion 8 to the Z height of the base of the convex portion 7e is formed. The +Z-side ends of the plugs CC3-1 to CC3-3 are connected to the convex portion 7e.

The flat portion 7d may be made of a material containing the first metal as a main component. The convex portion 7e may be made of a material containing the second metal or the third metal as a main component. The second metal has a lower resistivity than the resistivity of the first metal. The third metal has a higher resistivity than the resistivity of the first metal. When the first metal contains aluminum or the like, the second metal contains copper or the like, and the third metal contains tungsten or the like.

In such a semiconductor storage device 1i as well, the resistance of the connection configuration from the opening TV (electrode portion 6a) to the transistor Tr can be easily reduced by parallel connection of the conductive film MA2i (wiring MA2i) and the conductive film MA1i (wiring MA1i). Thus, the wiring MA1i and the wiring MA2i can be reduced in the thickness, which is determined according to the amount of power to be transmitted, to, for example, about half while maintaining the same length. That is, the wiring MA1i and the wiring MA2i can be thinned while meeting the required characteristics.

In addition, in the semiconductor storage device 1i, the resistance of the connection configuration can be easily reduced, so that the wiring MA1i and the wiring MA2i can be approximately doubled in length while maintaining the same thickness (as set according to the amount of power to be transmitted). That is, the wiring MA1i and the wiring MA2i can be elongated without increasing the film thickness while meeting the required characteristics.

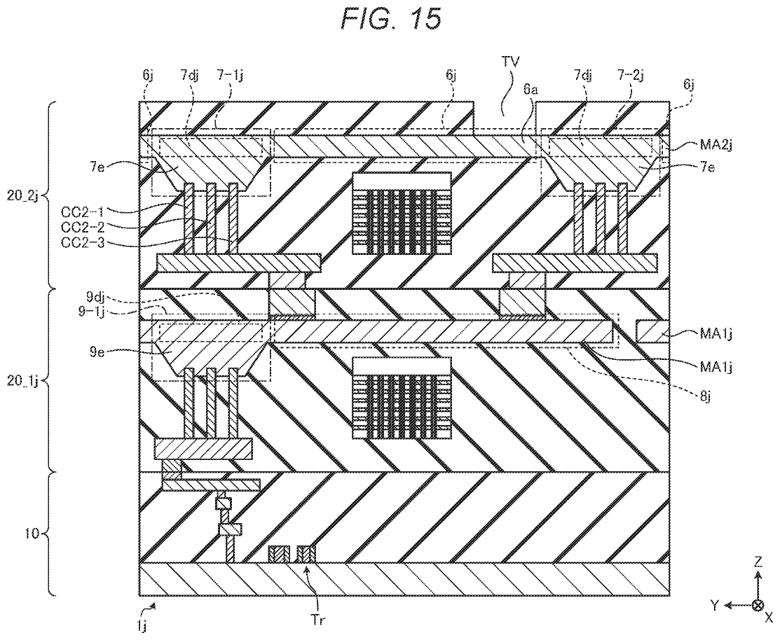

As a second modification of the first embodiment, a semiconductor storage device 1j may have wirings MA1i and MA2i made of a material having a lower resistivity, as shown in FIG. 15. FIG. 15 is a YZ cross-sectional view showing the configuration of the semiconductor storage device 1j according to the second modification of the first embodiment, and corresponds to the YZ cross-section taken along line B-B of FIG. 3.

The semiconductor storage device 1j has chips 20_1j and 20_2j instead of the chips 20_1i and 20_2i (see FIG. 14).

The chip 20_1j has a conductive film MA1j instead of the conductive film MA1i (see FIG. 14). The conductive film MA1j functions as the wiring MA1j. The conductive film MA1j has a routing portion 8j and a plug connection portion 9-1j instead of the routing portion 8 and the plug connection portion 9-1 (see FIG. 14).

The routing portion 8j may be made of a material containing the second metal as a main component, instead of the material containing the first metal as a main component. The second metal has a lower resistivity than the resistivity of the first metal. When the first metal contains aluminum or the like, the second metal contains copper or the like.

The plug connection portion 9-1j has a flat portion 9dj instead of the flat portion 9d (see FIG. 14). The flat portion 9dj may be made of a material containing the second metal as a main component, instead of the material containing the first metal as a main component.

The chip 20_2j has a conductive film MA2j instead of the conductive film MA2i (see FIG. 14). The conductive film MA2j functions as a wiring MA2j. The conductive film MA2j has a routing portion 6j and plug connection portions 7-1j and 7-2j instead of the routing portion 6 and plug connection portions 7-1 and 7-2 (see FIG. 14).

The routing portion 6j may be made of a material containing the second metal as a main component, instead of the material containing the first metal as a main component.

The plug connection portion 7-1j has a flat portion 7dj instead of the flat portion 7d (see FIG. 14). The flat portion 7dj may be made of a material containing the second metal as a main component, instead of the material containing the first metal as a main component.

The plug connection portion 7-2j has a flat portion 7dj instead of the flat portion 7d (see FIG. 14). The flat portion 7dj may be made of a material containing the second metal as a main component, instead of the material containing the first metal as a main component.

In such a semiconductor storage device 1j as well, the resistance of the connection configuration from the opening TV (electrode portion 6a) to the transistor Tr can be easily reduced by parallel connection of the conductive film MA2j (wiring MA2j) and the conductive film MA1j (wiring MA1j). Thus, the wiring MA1j and the wiring MA2j can be reduced in the thickness by, about half while maintaining the same length. That is, the wiring MA1j and the wiring MA2j can be thinned while still satisfying the required characteristics.

In addition, in the semiconductor storage device 1j, the resistance of the connection configuration can be easily reduced, so that the wiring MA1j and the wiring MA2j can be approximately doubled in length while maintaining the same thickness. That is, the wiring MA1j and the wiring MA2j can be elongated without increasing the film thickness while still satisfying the required characteristics.

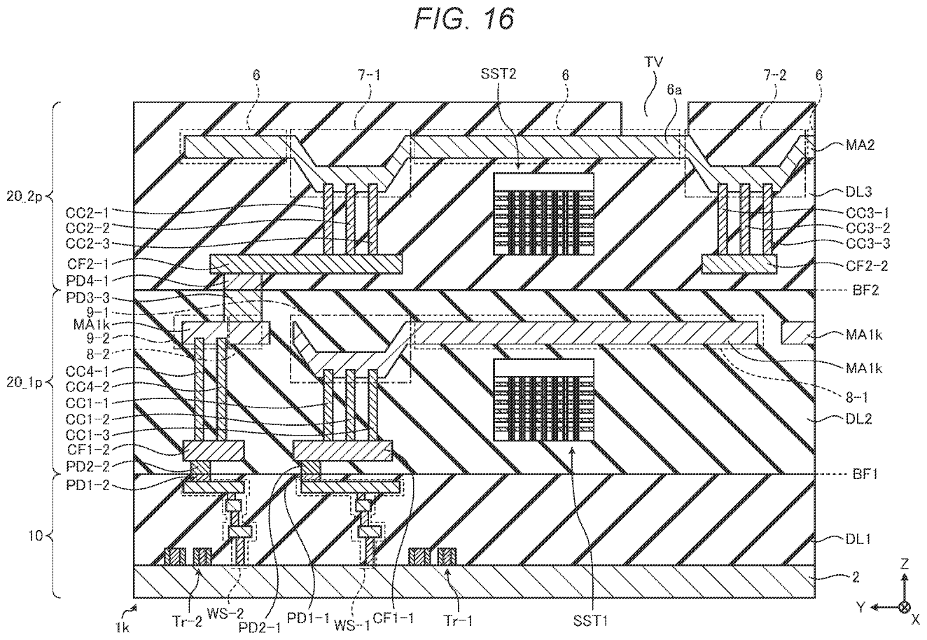

As a third modification of the first embodiment, a semiconductor storage device 1k may have a wiring MA1k and a wiring MA2 independently connected to a chip 10k, as shown in FIG. 16. FIG. 16 is a cross-sectional view showing the configuration of a semiconductor storage device 1k according to the third modification of the first embodiment.

The chip 10k has transistors Tr-1 and Tr-2, wiring structures WS-1 and WS-2, and electrodes PD1-1 and PD1-2. The electrodes PD1-1 and PD1-2 are disposed on the bonding surface BF1 of the chip 10k and a chip 20_1k, respectively. The electrodes PD1-1 and PD1-2 each have the +Z-side surface exposed to the bonding surface BF1. The −Z-side end of the electrode PD1-1 is connected to the transistor Tr-1 via the wiring structure WS-1. The electrode PD1-2 has the −Z-side end connected to the transistor Tr-2 via the wiring structure WS-2.

The chip 20_1k does not have the electrode PD3-1, the electrode PD3-2, the barrier film BM-1, and the barrier film BM-2 (see FIG. 6). The chip 20_1k has a conductive film MA1k instead of the conductive film MA1 (see FIG. 6). The chip 20_1k further has a conductive film CF1-2, a plurality of plugs CC4-1 to CC4-2, an electrode PD2-2, and an electrode PD3-3.

The conductive film MA1k functions as the wiring MA1k. The conductive film MA1k may be made of a material containing the first metal as a main component. The first metal contains aluminum or the like. The conductive film MA1k has routing portions 8-1 and 8-2 and plug connection portions 9-1 and 9-2.

The routing portion 8-1 is disposed on the −Y side of the plug connection portion 9-1, and has the +Y-side end connected to the plug connection portion 9-1. The routing portion 8-1 is substantially flat and extends in the Y direction while maintaining substantially the same Z height. The plug connection portion 9-1 is the same as in the first embodiment.

The routing portion 8-2 is disposed on the −Y side of the plug connection portion 9-2, and has the +Y-side end connected to the plug connection portion 9-2. The routing portion 8-2 is disposed on the +Y side of the plug connection portion 9-1, and has the −Y-side end separated from the plug connection portion 9-2 via the insulating film DL2. The routing portion 8-2 is substantially flat and extends in the Y direction while maintaining substantially the same Z height.

The plug connection portion 9-2 is connected adjacent to the routing portion 8-2 on the +Y side. The plug connection portion 9-2 is substantially flat and extends in the Y direction while maintaining substantially the same Z height. The +Z-side ends of the plugs CC4-1 to CC4-2 are connected to the plug connection portion 9-2.

The conductive film CF1-2 is disposed apart from the stacked body SST1 and the conductive film CF1-1 in the XY direction. The conductive film CF1-2 is disposed at a position shifted from the conductive film CF1-1 to the side opposite to the stacked body SST1 in the Y direction. The conductive film CF1-2 is disposed at the XY position corresponding to the plug connection portion 9-2. The conductive film CF1-2 is disposed at a position on the −Z side (deeper position) than the conductive film MA1k. The conductive film CF1-2 may be made of a material containing the second metal as a main component. The second metal has a lower resistivity than the resistivity of the first metal. When the first metal contains aluminum or the like, the second metal contains copper or the like.

A plurality of plugs CC4-1 and CC4-2 are disposed between the conductive film MA1k and the conductive film CF1-2 in the Z direction. The plurality of plugs CC4-1 to CC4-2 are disposed on the −Z side of the plug connection portion 9-2 and on the +Z side of the conductive film CF1-2. Each of the plugs CC4-1 to CC4-2 extends in the Z direction and connects the conductive film MA1k and the conductive film CF1-2. Each of the plugs CC4-1 to CC4-2 has a +Z-side end electrically connected to the plug connection portion 9-2 and a −Z-side end electrically connected to the conductive film CF1-2. Each plug CC4 may be made of a material containing the third metal as a main component. The third metal has a higher resistivity than the resistivity of the first metal. When the first metal contains aluminum or the like, the third metal contains tungsten or the like.

The electrode PD2-2 is disposed on the bonding surface BF1 of the chip 10k and the chip 20_1k. The electrode PD2-2 is electrically connected to the conductive film CF1-2 and the electrode PD1-2. The electrode PD2-2 has a +Z-side surface in contact with the conductive film CF1-2 and a −Z-side surface exposed to the bonding surface BF1. The −Z-side surface of the electrode PD2-2 is in contact with the electrode PD1-2. The electrode PD2-2 may be made of a material containing the second metal as a main component.

The electrode PD3-3 is disposed on the bonding surface BF2 of the chip 20_1k and the chip 20_2k. The electrode PD3-3 is disposed at the XY position corresponding to the routing portion 8-2 in the conductive film MA1k. The electrode PD3-3 may be disposed at a position shifted in the +Y direction from the stacked body SST1.

The electrode PD3-3 is electrically connected to the routing portion 8-2 of the conductive film MA1k, and is electrically connected to the electrode PD4-1. The electrode PD3-3 has a −Z-side surface in contact with the routing portion 8-2 and a +Z-side surface exposed to the bonding surface BF2. The +Z-side surface of the electrode PD3-3 is in contact with the electrode PD4-1. The electrode PD3-3 may be made of a material containing the second metal as a main component.

The chip 20_2k does not have the electrode PD4-2 (see FIG. 6). The electrode PD4-1 is connected to the electrode PD3-3 instead of the electrode PD3-1 (see FIG. 6).

In the connection configuration leading to the transistors Tr-1 and Tr-2 shown in FIG. 16, the conductive film MA2 of the chip 20_2 and the conductive film MA1 of the chip 20_1 are connected independently of each other. A third connection path is connected between the electrode portion 6a and the transistor Tr-1, and a fourth connection path is connected between another electrode portion (located outside the depicted area) and the transistor Tr-2. The third connection path and the fourth connection path are insulated from each other.

The third connection path includes the electrode portion 6a→the routing portion 6→the plug connection portion 7-1→the plugs CC2-1 to CC2-3→the conductive film CF2-1→the electrode PD4-1→the electrode PD3-3→the routing portion 8-2 the plug connection portion 9-2→the plugs CC4-1 to CC4-2→the conductive film CF1-2→the electrode PD2-2→the electrode PD1-2→the wiring structure WS-2. The fourth connection path includes another electrode portion→the plug connection portion 9-1→the plugs CC1-1 to CC1-3→the conductive film CF1-1→the electrode PD2-1→the electrode PD1-1→the wiring structure WS-1. Thus, the conductive film MA1k and the conductive film MA2 are independently connected to the chip 10k.

Here, the conductive film MA1k functions as the wiring MA1k, and the conductive film MA2 functions as the wiring MA2. When the wiring MA1 and the wiring MA2 are independently connected to the chip 10k, different levels of powers can be transmitted through the wiring MA1 and the wiring MA2. For example, the wiring MA1k can function as the power line 22, and the power Vss can be transmitted through the wiring MA1k. The wiring MA2 can be made to function as the power line 23, and the power Vcc can be transmitted through the wiring MA2. Alternatively, the wiring MA1k can function as the power line 23, and the power Vcc can be transmitted through the wiring MA1k. The wiring MA2 can be made to function as the power line 22, and the power Vss can be transmitted through the wiring MA2.

Thus, in the semiconductor storage device 1k, the wiring MA1k and the wiring MA2 are independently connected to the chip 10. Different powers can be transmitted to the chip 10 in parallel between the chips 20_1k and 20_2k stacked in the Z direction through the wiring MA1k and the wiring MA2. Thus, the power of the power source can be efficiently transmitted to the chip 10.

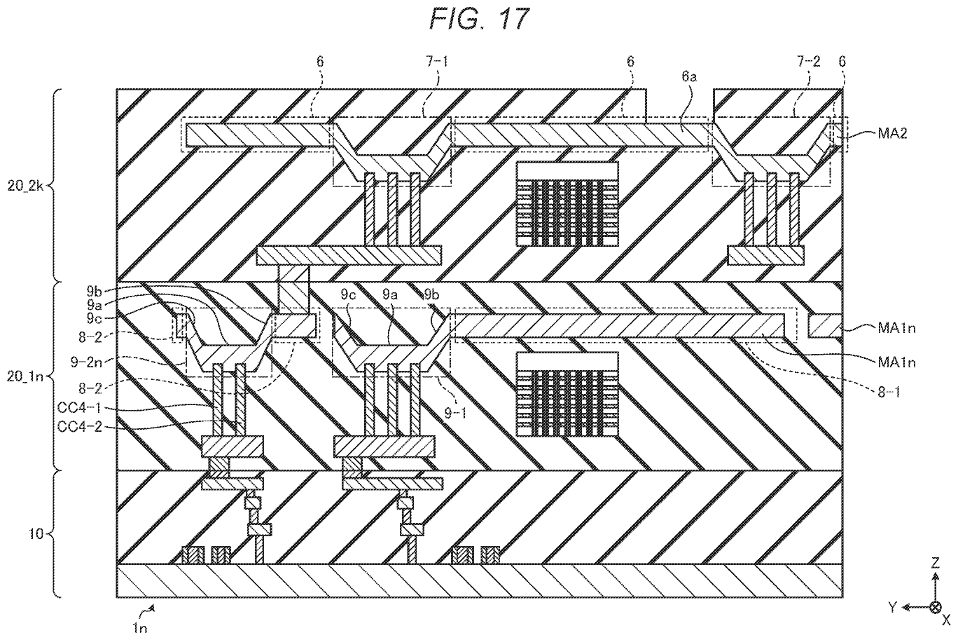

As a fourth modification of the first embodiment, a semiconductor storage device in may have plug connection portions 9-1 and 9-2n of a wiring MA1n having the same configuration, as shown in FIG. 17. FIG. 17 is a cross-sectional view showing the configuration of a semiconductor storage device in according to the fourth modification of the first embodiment.

The chip 20_1n has a conductive film MA1n instead of the conductive film MA1k (see FIG. 16). The conductive film MA1n has a plug connection portion 9-2n instead of the plug connection portion 9-2 (see FIG. 16).

The routing portions 8-2 are disposed on both sides of the plug connection portion 9-2n in the Y direction. The routing portion 8-2 is substantially flat and extends in the Y direction while maintaining substantially the same Z height.

The plug connection portion 9-2n is connected adjacent to the routing portion 8-2 on the +Y side or the −Y side, and has a step of which Z height is lower than the routing portion 8-2. The plug connection portion 9-2n has a flat portion 9a, an inclined portion 9b, and an inclined portion 9c.

In the plug connection portion 9-2n, the flat portion 9a is substantially flat and extends in the Y direction while maintaining substantially the same Z height. The Z height of the flat portion 9a is lower than the Z height of the routing portion 8-2. The +Z-side ends of the plugs CC4-1 to CC4-2 are connected to the flat portion 9a.

The inclined portion 9b is disposed on the −Y side of the flat portion 9a. The inclined portion 9b has a −Y-side end connected to the routing portion 8-2 and a +Y-side end connected to the flat portion 9a. The inclined portion 9b extends with an inclination such that the Z height decreases from the −Y side toward the +Y side. Thus, a step extending from the Z height of the routing portion 8-2 to the Z height of the flat portion 9a is formed.

The inclined portion 9c is disposed on the +Y side of the flat portion 9a. The inclined portion 9c has a +Y-side end connected to the routing portion 8-2 and a −Y-side end connected to the flat portion 9a. The inclined portion 9c extends with an inclination such that the Z height decreases from the +Y side toward the −Y side. Thus, a step extending from the Z height of the routing portion 8-2 to the Z height of the flat portion 9a is formed.

Even in such a semiconductor storage device 1n, the wiring MA1n and the wiring MA2 are independently connected to the chip 10. Different powers can be transmitted to the chip 10 in parallel between the chips 20_1n and 20_2k stacked in the Z direction through the wiring MA1n and the wiring MA2. Thus, the power of the power source can be efficiently transmitted to the chip 10.

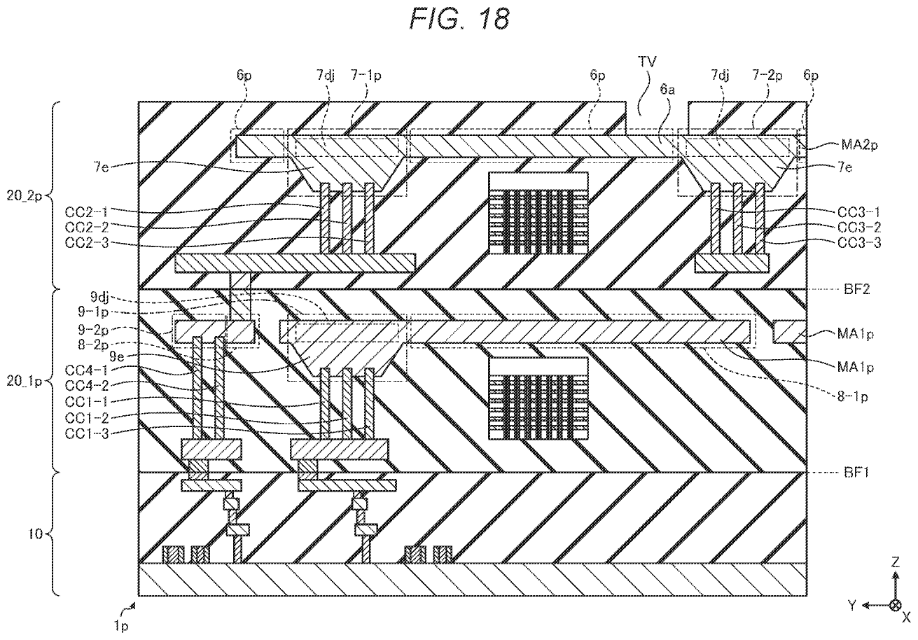

As a fifth modification of the first embodiment, a semiconductor storage device 1p may have wirings MA1p and MA2p made of a material having a lower resistivity, as shown in FIG. 18. FIG. 18 is a YZ cross-sectional view showing the configuration of the semiconductor storage device 1p according to the fifth modification of the embodiment, and corresponds to the YZ cross-section taken along line B-B of FIG. 3.

The semiconductor storage device 1p has chips 20_1p and 20_2p instead of the chips 20_1k and 20_2k (see FIG. 16).

The chip 20_1p has a conductive film MA1p instead of the conductive film MA1k (see FIG. 16). The conductive film MA1p functions as the wiring MA1p. The conductive film MA1p has the routing portions 8-1p and 8-2p and the plug connection portions 9-1p and 9-2p instead of the routing portions 8-1 and 8-2 and the plug connection portions 9-1 and 9-2 (see FIG. 16).

The routing portion 8-1p may be made of a material containing the second metal as a main component, instead of the material containing the first metal as a main component. The second metal has a lower resistivity than the resistivity of the first metal.

The plug connection portion 9-1p has a flat portion 9dj and a convex portion 9e.

In the plug connection portion 9-1p, the flat portion 9dj is substantially flat and extends in the Y direction while maintaining substantially the same Z height. The Z height of the flat portion 9dj is equal to the Z height of the routing portion 8-1p. The flat portion 9dj is continuous with the routing portion 8-1p at the Y-direction end. Thus, the +Z-side surface of the conductive film MA1p can be formed substantially flat.

The convex portion 9e is disposed on the −Z side of the flat portion 9dj and has a convex shape from the flat portion 9dj to the −Z side. The convex portion 9e has a substantially isosceles trapezoidal shape in a YZ cross-sectional view. A substantially isosceles trapezoidal shape has an upper base that is longer than a lower base. The convex portion 9e has side surfaces that are inclined on both sides in the Y direction. Thus, a step extending from the Z height of the routing portion 8-1p to the Z height of the base of the convex portion 9e is formed.

The flat portion 9dj may be made of a material containing the second metal as a main component, instead of the material containing the first metal as a main component. The convex portion 9e may be made of a material containing the second metal as a main component.

The routing portion 8-2p may be made of a material containing the second metal as a main component, instead of the material containing the first metal as a main component.

The plug connection portion 9-2p may be made of a material containing the second metal as a main component, instead of the material containing the first metal as a main component.

The chip 20_2p has a conductive film MA2p instead of the conductive film MA2k (see FIG. 16). The conductive film MA2p functions as the wiring MA2p. The conductive film MA2p has a routing portion 6p and plug connection portions 7-1p and 7-2p instead of the routing portion 6 and plug connection portions 7-1 and 7-2 (see FIG. 16).

The routing portion 6p may be made of a material containing the second metal as a main component, instead of the material containing the first metal as a main component.

The plug connection portion 7-1p has a flat portion 7dj and a convex portion 7e.

In the plug connection portion 7-1i, the flat portion 7dj is substantially flat and extends in the Y direction while maintaining substantially the same Z height. The Z height of the flat portion 7dj is equal to the Z height of the routing portion 6p. The flat portion 7dj is continuous with the routing portion 6p at the Y-direction end. Thus, the +Z-side surface of the conductive film MA1p can be formed substantially flat.

The convex portion 7e is disposed on the −Z side of the flat portion 7dj and has a convex shape from the flat portion 7dj to the −Z side. The convex portion 7e has a substantially isosceles trapezoidal shape in a YZ cross-sectional view. A substantially isosceles trapezoidal shape has an upper base that is longer than a lower base. The convex portion 7e has side surfaces that are inclined on both sides in the Y direction. Thus, a step extending from the Z height of the routing portion 6p to the Z height of the base of the convex portion 7e is formed.

The flat portion 7dj may be made of a material containing the second metal as a main component, instead of the material containing the first metal as a main component. The convex portion 7e may be made of a material containing the second metal as a main component.

The plug connection portion 7-2p has a flat portion 7dj and a convex portion 7e.

In the plug connection portion 7-2p, the flat portion 7dj is substantially flat and extends in the Y direction while maintaining substantially the same Z height. The Z height of the flat portion 7dj is equal to the Z height of the routing portion 6p. The flat portion 7dj is continuous with the routing portion 6p at the Y-direction end. Thus, the +Z-side surface of the conductive film MA1p can be formed substantially flat.

The convex portion 7e is disposed on the −Z side of the flat portion 7dj and has a convex shape from the flat portion 7dj to the −Z side. The convex portion 7e has a substantially isosceles trapezoidal shape in a YZ cross-sectional view. A substantially isosceles trapezoidal shape has an upper base that is longer than a lower base. The convex portion 7e has side surfaces that are inclined on both sides in the Y direction. Thus, a step extending from the Z height of the routing portion 6p to the Z height of the base of the convex portion 7e is formed.

The flat portion 7dj may be made of a material containing the second metal as a main component, instead of the material containing the first metal as a main component. The convex portion 7e may be made of a material containing the second metal as a main component.

Even in such a semiconductor storage device 1p, the wiring MA1p and the wiring MA2p are independently connected to the chip 10. Different powers can be transmitted to the chip 10 in parallel between the chips 20_1p and 20_2p stacked in the Z direction through the wiring MA1p and the wiring MA2p. Thus, the power of the power source can be efficiently transmitted to the chip 10.

### Second Embodiment

Next, a semiconductor storage device 1m according to a second embodiment will be described. In the following description, a difference from the first embodiment will be mainly described.

In the first embodiment, the configuration of wirings MA1 and MA2 that may be applied to power lines are illustrated, while in the second embodiment, the configuration of wirings MA101 and MA102 that may be applied to source lines are illustrated.

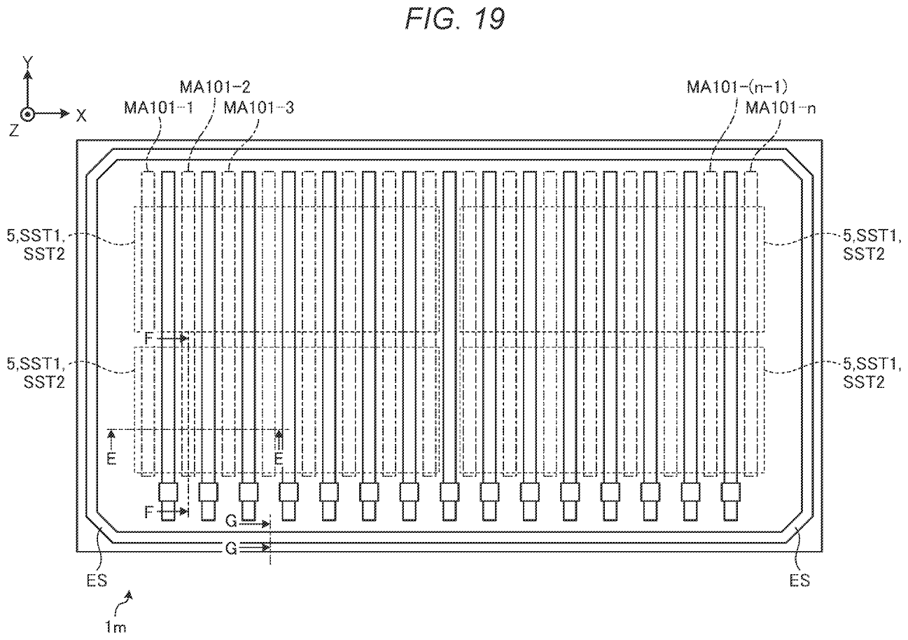

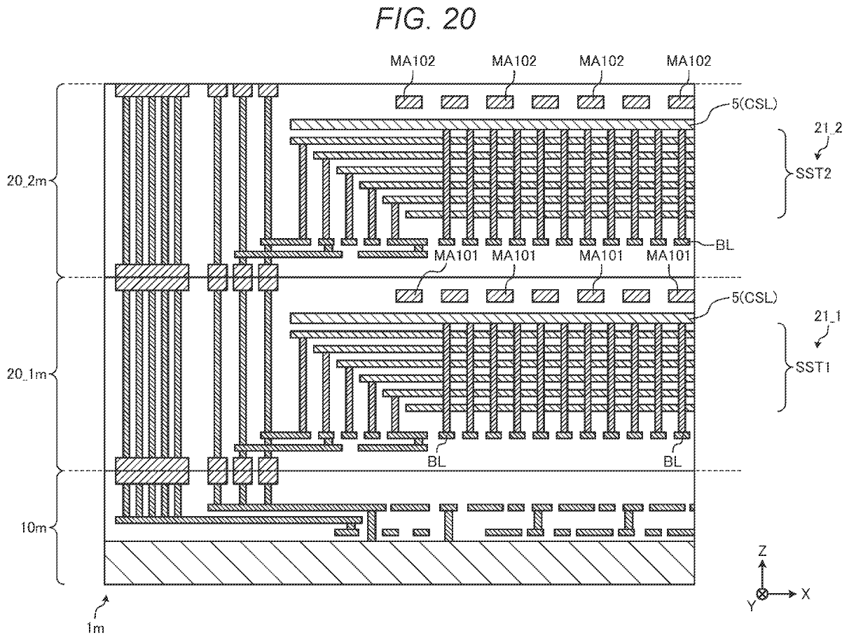

The source line SL shown in FIG. 1 may be implemented by wirings MA101 and MA102 as shown in FIGS. 19 and 20, for example. FIG. 19 is an XY plan view showing the configuration of the semiconductor storage device 1m. FIG. 20 is an XZ cross-sectional view showing the configuration of the semiconductor storage device 1m. FIG. 20 illustrates a cross section taken along line E-E of FIG. 19.

As shown in FIGS. 19 and 20, in the chip 20_1m, the plurality of wirings MA101 are disposed on the +Z side of the stacked body SST1. The wiring MA101 is indicated by a dashed line in FIG. 19. The plurality of wirings MA101 are located in the X direction. A wiring MA1 (see FIG. 3) may be disposed between the plurality of wirings MA101. Each wiring MA101 extends in the Y direction. Each wiring MA101 extends in the Y direction across the stacked body SST1 when viewed from the Z direction. The conductive layer 5 is disposed between each wiring MA101 and the stacked body SST1 in the Z direction. The conductive layer 5 extends in a plate shape in the XY direction so as to overlap with the stacked body SST1 when viewed from the Z direction. The +Z-side end (tip) of the semiconductor film CH in the column CL reaches the −Z-side surface of the conductive layer 5. The conductive layer 5 functions as a cell source portion CSL. The wiring MA101 can be electrically connected to the conductive layer 5. Each wiring MA101 functions as a source line SL, and its width and thickness may be determined according to required voltage characteristics (for example, voltage stabilization of the cell source portion CSL of the memory cell array 21_1).

Similarly, in the chip 20_2m, the plurality of wirings MA102 are disposed on the +Z side of the stacked body SST2. The wiring MA102 is indicated by a dashed line in FIG. 19. The plurality of wirings MA102 are located in the X direction. A wiring MA2 (see FIG. 3) may be disposed between the plurality of wirings MA102. Each wiring MA102 extends in the Y direction. Each wiring MA102 extends in the Y direction across the stacked body SST2 when viewed from the Z direction. The conductive layer 5 is disposed between each wiring MA102 and the stacked body SST2 in the Z direction. The conductive layer 5 extends in a plate shape in the XY direction so as to overlap with the stacked body SST1 when viewed from the Z direction. The +Z-side end (tip) of the semiconductor film CH in the column CL reaches the −Z-side surface of the conductive layer 5. The conductive layer 5 functions as the cell source portion CSL. The wiring MA102 can be electrically connected to the conductive layer 5. Each wiring MA102 functions as a source line SL, and its width and thickness may be determined according to required voltage characteristics (for example, voltage stabilization of the cell source portion CSL of the memory cell array 21_1).

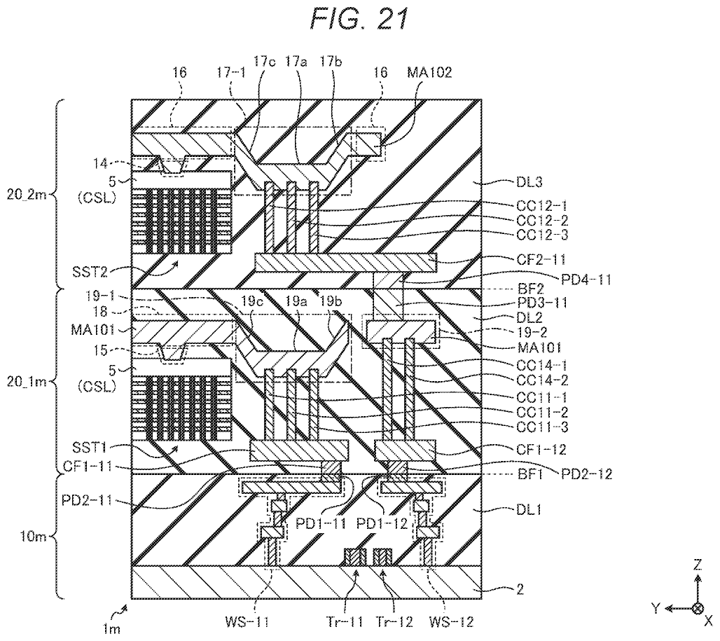

Next, a detailed configuration of the wirings MA101 and MA102 will be described with reference to FIG. 21. FIG. 21 is a YZ cross-sectional view showing the configuration of the semiconductor storage device 1m, and illustrates the YZ cross-section taken along line F-F of FIG. 19.

A chip 10m has transistors Tr-11 and Tr-12, wiring structures WS-11 and WS-12, and electrodes PD1-11 and PD1-12. The electrodes PD1-11 and PD1-12 are disposed on the bonding surface BF1 of the chip 10m and the chip 20_1m, respectively. The electrodes PD1-11 and PD1-12 each have the +Z-side surface exposed to the bonding surface BF1. The electrode PD1-11 has the −Z-side end connected to the transistor Tr-11 via the wiring structure WS-11. The electrode PD1-12 has the −Z-side end connected to the transistor Tr-12 via the wiring structure WS-12.

The chip 20_1m includes a stacked body SST1, a conductive film MA101, a conductive film CF1-11, a plurality of plugs CC11-1 to CC11-3, an electrode PD2-11, an electrode PD2-12, and an electrode PD3-11.

The conductive film MA101 is disposed on the +Z side of the stacked body SST1. The conductive film MA101 functions as a wiring MA101 (see FIG. 19). The conductive film MA101 has a linear pattern in the XY plane view. The conductive film MA101 extends substantially in the Y direction across the stacked body SST1 when viewed from the Z direction. The conductive layer 5 is disposed between the conductive film MA101 and the stacked body SST1 in the Z direction. The conductive layer 5 functions as the cell source portion CSL. The conductive film MA101 is connected to the conductive layer 5 from the +Z side. The conductive film MA101 may be made of a material containing the first metal as a main component. The first metal contains aluminum or the like. The conductive film MA101 has a routing portion 18, a pad portion 15, and plug connection portions 19-1 and 19-2.

The plug connection portion 19-1 is disposed apart from the stacked body SST1 in the XY direction. The plug connection portion 19-1 is disposed at a position shifted in the Y direction from the stacked body SST1.

The routing portion 18 is disposed on the +Y side of the plug connection portion 19-1, and is disposed at a position corresponding to the stacked body SST1, for example. The routing portion 18 is substantially flat and extends in the Y direction while maintaining substantially the same Z height.

The pad portion 15 is disposed between the routing portion 18 and the conductive layer 5 in the Z direction. The pad portion 15 extends in the Z direction and connects the routing portion 18 and the conductive layer 5. The pad portion 15 has a substantially columnar shape with the Z direction as an axis, and may be substantially a truncated cone shape, for example, in which the area of the +Z-side end is larger than the area of the −Z-side end. The pad portion 15 has a +Z side end electrically connected to the routing portion 18 and a −Z side end electrically connected to the conductive layer 5. The pad portion 15 functions as a pad connected to the surface of the conductive layer 5 opposite to the stacked body SST1, and is also called a backing pad portion.

The plug connection portion 19-1 is connected adjacent to the routing portion 18 on the −Y side and has a step of which Z height is lower than the routing portion 18. The plug connection portion 19-1 has a flat portion 19a, an inclined portion 19b, and an inclined portion 19c.

In the plug connection portion 19-1, the flat portion 19a is substantially flat and extends in the Y direction while maintaining substantially the same Z height. The Z height of the flat portion 19a is lower than the Z height of the routing portion 18. The +Z-side ends of the plugs CC11-1 to CC11-3 are connected to the flat portion 19a.

The inclined portion 19b is disposed on the −Y side of the flat portion 19a. The inclined portion 19b has a −Y-side end connected to the routing portion 18 and a +Y-side end connected to the flat portion 19a. The inclined portion 19b extends with an inclination such that the Z height decreases from the −Y side toward the +Y side. Thus, a step extending from the Z height of the routing portion 18 to the Z height of the flat portion 19a is formed.

The inclined portion 19c is disposed on the +Y side of the flat portion 19a. The inclined portion 19c has a +Y-side end connected to the routing portion 18 and a −Y-side end connected to the flat portion 19a. The inclined portion 19c extends with an inclination such that the Z height decreases from the +Y side toward the −Y side. Thus, a step extending from the Z height of the routing portion 18 to the Z height of the flat portion 19a is formed.

The conductive film CF1-11 is disposed apart from the stacked body SST1 in the XY direction. The conductive film CF1-11 is disposed at a position shifted in the Y direction from the stacked body SST1. The conductive film CF1-11 is disposed at the XY position corresponding to the plug connection portion 19-1. The conductive film CF1-11 is disposed at a position on the −Z side (deeper position) than the conductive film MA101. The conductive film CF1-11 may be made of a material containing the second metal as a main component. The second metal has a lower resistivity than the resistivity of the first metal. When the first metal contains aluminum or the like, the second metal contains copper or the like.

The plug connection portion 19-2 is substantially flat and extends in the Y direction while maintaining substantially the same Z height. The plug connection portion 19-2 has the +Z-side surface connected to the electrode PD3-11, and the −Z-side surface connected to the +Z-side ends of the plugs CC14-1 to CC14-2.

The conductive film CF1-12 is disposed apart from the stacked body SST1 and the conductive film CF1-11 in the XY direction. The conductive film CF1-12 is disposed at a position shifted from the conductive film CF1-11 to the side opposite to the stacked body SST1 in the Y direction. The conductive film CF1-12 is disposed at the XY position corresponding to the plug connection portion 19-2. The conductive film CF1-12 is disposed at a position on the −Z side (deeper position) than the conductive film MA101. The conductive film CF1-12 may be made of a material containing the second metal as a main component.

A plurality of plugs CC11-1 to CC11-3 are disposed between the conductive film MA101 and the conductive film CF1-11 in the Z direction. The plurality of plugs CC11-1 to CC11-3 are disposed on the −Z side of the plug connection portion 19-1 and on the +Z side of the conductive film CF1-11. Each of the plugs CC11-1 to CC11-3 extends in the Z direction and connects the conductive film MA101 and the conductive film CF1-11. Each of the plugs CC11-1 to CC11-3 has a +Z-side end electrically connected to the plug connection portion 19-1 and a −Z-side end electrically connected to the conductive film CF1-11. Each plug CC11 may be made of a material containing the third metal as a main component. The third metal has a higher resistivity than the resistivity of the first metal. When the first metal contains aluminum or the like, the third metal contains tungsten or the like.

A plurality of plugs CC14-1 and CC14-2 are disposed between the conductive film MA101 and the conductive film CF1-12 in the Z direction. The plurality of plugs CC14-1 to CC14-2 are disposed on the −Z side of the plug connection portion 19-2 and on the +Z side of the conductive film CF1-12. Each of the plugs CC14-1 to CC14-2 extends in the Z direction and connects the conductive film MA101 and the conductive film CF1-12. Each of the plugs CC14-1 to CC14-2 has a +Z-side end electrically connected to the plug connection portion 19-2 and a −Z-side end electrically connected to the conductive film CF1-12. Each plug CC14 may be made of a material containing the third metal as a main component.

The electrode PD2-11 is disposed on the bonding surface BF1 of the chip 10m and the chip 20_1m. The electrode PD2-11 is electrically connected to the conductive film CF1-11 and the electrode PD1-11. The electrode PD2-11 has a +Z-side surface in contact with the conductive film CF1-11 and a −Z-side surface exposed to the bonding surface BF1. The −Z-side surface of the electrode PD2-11 is in contact with the electrode PD1-11. The electrode PD2-11 may be made of a material containing the second metal as a main component.

The electrode PD2-12 is disposed on the bonding surface BF1 of the chip 10m and the chip 20_1m. The electrode PD2-12 is electrically connected to the conductive film CF1-12 and the electrode PD1-12. The electrode PD2-12 has a +Z-side surface in contact with the conductive film CF1-12 and a −Z-side surface exposed to the bonding surface BF1. The −Z-side surface of the electrode PD2-12 is in contact with the electrode PD1-12. The electrode PD2-12 may be made of a material containing the second metal as a main component.

The electrode PD3-11 is disposed on the bonding surface BF2 of the chip 20_1m and the chip 20_2m. The electrode PD3-11 is disposed at the XY position corresponding to the plug connection portion 19-2 in the conductive film MA101. The electrode PD3-11 may be disposed at a position shifted in the −Y direction from the stacked body SST1.

The electrode PD3-11 is electrically connected to the conductive film MA101, and electrically connected to the electrode PD4-11. The electrode PD3-11 has a −Z-side surface in contact with the plug connection portion 19-2 and a +Z-side surface exposed to the bonding surface BF2. The +Z-side surface of the electrode PD3-11 is in contact with the electrode PD4-2. The electrode PD3-11 may be made of a material containing the second metal as a main component.

The chip 20_2m has the stacked body SST2, a conductive film MA102, a conductive film CF2-11, a plurality of plugs CC12-1 to CC12-3, and an electrode PD4-11.

The conductive film MA102 is disposed on the +Z side of the stacked body SST2. The conductive film MA102 functions as the wiring MA102 (see FIG. 19). The conductive film MA102 has a linear pattern in the XY plane view. The conductive film MA102 extends substantially in the Y direction across the stacked body SST2 when viewed from the Z direction. The conductive layer 5 is disposed between the conductive film MA102 and the stacked body SST2 in the Z direction. The conductive layer 5 functions as the cell source portion CSL. The conductive film MA102 is connected to the conductive layer 5 from the +Z side. The conductive film MA102 may be made of a material containing the first metal as a main component. The conductive film MA102 has a routing portion 16, a pad portion 14, and a plug connection portion 17-1.

The plug connection portion 17-1 is disposed apart from the stacked body SST2 in the XY direction. The plug connection portion 17-1 is disposed at a position shifted in the Y direction from the stacked body SST2.

The routing portions 16 are disposed on both sides of the plug connection portion 17-1 in the Y direction, for example, at positions corresponding to the stacked body SST2. The routing portion 16 is substantially flat and extends in the Y direction while maintaining substantially the same Z height.

The pad portion 14 is disposed between the routing portion 16 and the conductive layer 5 in the Z direction. The pad portion 14 extends in the Z direction and connects the routing portion 16 and the conductive layer 5. The pad portion 14 has a substantially columnar shape with the Z direction as an axis, and may be substantially a truncated cone shape, for example, in which the area of the +Z-side end is larger than the area of the −Z-side end. The pad portion 14 has a +Z side end electrically connected to the routing portion 16 and a −Z side end electrically connected to the conductive layer 5. The pad portion 14 functions as a pad connected to the surface of the conductive layer 5 opposite to the stacked body SST2, and is also called a backing pad portion.

The plug connection portion 17-1 is connected adjacent to the routing portion 16 on the −Y side or the +Y side, and has a step of which Z height is lower than the routing portion 16. The plug connection portion 17-1 has a flat portion 17a, an inclined portion 17b, and an inclined portion 17c.

In the plug connection portion 17-1, the flat portion 17a is substantially flat and extends in the Y direction while maintaining substantially the same Z height. The Z height of the flat portion 17a is lower than the Z height of the routing portion 16. The +Z-side ends of the plugs CC12-1 to CC12-3 are connected to the flat portion 17a.

The inclined portion 17b is disposed on the −Y side of the flat portion 17a. The inclined portion 17b has a −Y-side end connected to the routing portion 16 and a +Y-side end connected to the flat portion 17a. The inclined portion 17b extends with an inclination such that the Z height decreases from the −Y side toward the +Y side. Thus, a step extending from the Z height of the routing portion 16 to the Z height of the flat portion 17a is formed.

The inclined portion 17c is disposed on the +Y side of the flat portion 17a. The inclined portion 17c has a +Y-side end connected to the routing portion 16 and a −Y-side end connected to the flat portion 17a. The inclined portion 17c extends with an inclination such that the Z height decreases from the +Y side toward the −Y side. Thus, a step extending from the Z height of the routing portion 16 to the Z height of the flat portion 17a is formed.

The conductive film CF2-11 is disposed apart from the stacked body SST2 in the XY direction. The conductive film CF2-11 is disposed at a position shifted in the Y direction from the stacked body SST2. The conductive film CF2-11 is disposed at the XY position corresponding to the plug connection portion 17-1. The conductive film CF2-11 is disposed at a position on the −Z side (deeper position) than the conductive film MA102. The conductive film CF2-11 may be made of a material containing the second metal as a main component.

The conductive film CF2-11 is disposed apart from the stacked body SST2 in the XY direction. The conductive film CF2-11 is disposed at a position shifted in the Y direction from the stacked body SST2. The conductive film CF2-11 is disposed at the XY position corresponding to the plug connection portion 17-1. The conductive film CF2-11 is disposed at a position on the −Z side (deeper position) than the conductive film MA102. The conductive film CF2-11 may be made of a material containing the second metal as a main component.

A plurality of plugs CC12-1 to CC12-3 are disposed between the conductive film MA102 and the conductive film CF2-11 in the Z direction. The plurality of plugs CC12-1 to CC12-3 are disposed on the −Z side of the plug connection portion 17-1 and on the +Z side of the conductive film CF2-11. Each of the plugs CC12-1 to CC12-3 extends in the Z direction and connects the conductive film MA102 and the conductive film CF2-11. Each of the plugs CC12-1 to CC12-3 has a +Z-side end electrically connected to the plug connection portion 17-1 and a −Z-side end electrically connected to the conductive film CF2-11. Each plug CC12 may be made of a material containing the third metal as a main component.

The electrode PD4-11 is disposed on the bonding surface BF1 of the chip 10m and the chip 20_2m. The electrode PD4-11 is electrically connected to the conductive film CF2-11 and the electrode PD1-11. The electrode PD4-11 has a +Z-side surface in contact with the conductive film CF2-11 and a −Z-side surface exposed to the bonding surface BF1. The −Z-side surface of the electrode PD4-11 is in contact with the electrode PD1-11. The electrode PD4-11 may be made of a material containing the second metal as a main component.

In the connection configuration from the conductive layer 5 of each chip (array chip) 20 to the transistors Tr-11 and Tr-12 shown in FIG. 21, the conductive film MA102 of the chip 20_2m and the conductive film MA101 of the chip 20_1m are connected independently of each other. A fifth connection path is connected between the conductive layer 5 of the chip 20_1m and the transistor Tr-11, and a sixth connection path is connected between the conductive layer 5 of the chip 20_2m and the transistor Tr-12. The fifth connection path and the sixth connection path are insulated from each other.

The fifth connection path includes the conductive layer 5 (the cell source portion CSL)→the pad portion 15→the routing portion 18→the plug connection portion 19-1→the plugs CC11-1 to CC11-3→the conductive film CF1-11→the electrode PD2-11→the electrode PD1-11→the wiring structure WS-11. The sixth connection path includes the conductive layer 5 (the cell source portion CSL)→the pad portion 14→the routing portion 16→the plug connection portion 17-1→the plugs CC12-1 to CC12-3→the conductive film CF2-11→the electrode PD4-11→the electrode PD3-11→the plug connection portion 19-2→the plugs CC14-1 to CC14-2→the conductive film CF1-12→the electrode PD2-12→the electrode PD1-12→the wiring structure WS-12. Thus, the conductive film MA101 and the conductive film MA102 are independently connected to the chip 10m.

Here, the conductive film MA101 functions as the wiring MA101, and the conductive film MA102 functions as the wiring MA102. When the wiring MA101 and the wiring MA102 are independently connected to the chip 10m, the voltage of the cell source portion CSL of each chip (array chip) 20 can be stabilized through the wiring MA101 and the wiring MA102. For example, the wiring MA101 can function as the source line SL for the chip 20_1m, and the source line voltage (for example, ground voltage) can be stably supplied to the cell source portion CSL of the chip 20_1m through the wiring MA101. For example, the wiring MA102 can function as the source line SL for the chip 20_2m, and the source line voltage (for example, ground voltage) can be stably supplied to the cell source portion CSL of the chip 20_2m through the wiring MA102.

As described above, in the second embodiment, in the semiconductor storage device 1m, the wiring MA101 and the wiring MA102 are independently connected to the chip 10m. A source line voltage (for example, a ground voltage) can be supplied in parallel from the chip 10m to the chips 20_1m and 20_2m stacked in the Z direction through the wiring MA101 and the wiring MA102. Thus, the voltage of the cell source portion CSL of each chip (array chip) 20 can be efficiently stabilized.

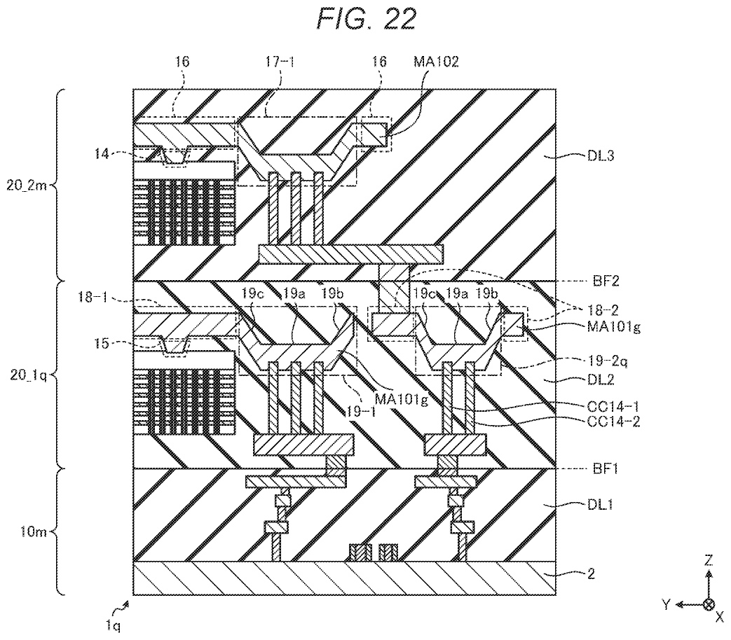

It is noted that as a first modification of the second embodiment, in a semiconductor storage device 1q, as shown in FIG. 22, plug connection portions 19-1 and 19-2n of the wiring MA101q may have the same configuration. FIG. 22 is a cross-sectional view showing the configuration of a semiconductor storage device 1q according to the first modification of the second embodiment.

The chip 20_1q has a conductive film MA101q instead of the conductive film MA101 (see FIG. 21). The conductive film MA101q has a plug connection portion 19-2q instead of the plug connection portion 19-2 (see FIG. 21), and further has a routing portion 18-2.

The routing portion 18-2 is disposed on both sides of the plug connection portion 19-2q in the Y direction. The routing portion 18-2 is substantially flat and extends in the Y direction while maintaining substantially the same Z height.

The plug connection portion 19-2q is connected adjacent to the routing portion 18-2 on the +Y side or the −Y side, and has a step of which Z height is lower than the routing portion 18-2. The plug connection portion 19-2q has a flat portion 19a, an inclined portion 19b, and an inclined portion 19c.

In the plug connection portion 19-2q, the flat portion 19a is substantially flat and extends in the Y direction while maintaining substantially the same Z height. The Z height of the flat portion 19a is lower than the Z height of the routing portion 18-2. The +Z-side ends of the plugs CC14-1 to CC14-2 are connected to the flat portion 19a.

The inclined portion 19b is disposed on the −Y side of the flat portion 19a. The inclined portion 19b has a −Y-side end connected to the routing portion 18-2 and a +Y-side end connected to the flat portion 19a. The inclined portion 19b extends with an inclination such that the Z height decreases from the −Y side toward the +Y side. Thus, a step extending from the Z height of the routing portion 18-2 to the Z height of the flat portion 19a is formed.

The inclined portion 19c is disposed on the +Y side of the flat portion 19a. The inclined portion 19c has a +Y-side end connected to the routing portion 18-2 and a −Y-side end connected to the flat portion 19a. The inclined portion 19c extends with an inclination such that the Z height decreases from the +Y side toward the −Y side. Thus, a step extending from the Z height of the routing portion 18-2 to the Z height of the flat portion 19a is formed.

Even in such a semiconductor storage device 1q, the wiring MA101q and the wiring MA102 are independently connected to the chip 10m. A source line voltage (for example, a ground voltage) can be supplied in parallel from the chip 10m to the chips 20_1m and 20_2m stacked in the Z direction through the wiring MA101q and the wiring MA102. Thus, the voltage of the cell source portion CSL of each chip (array chip) 20 can be efficiently stabilized.

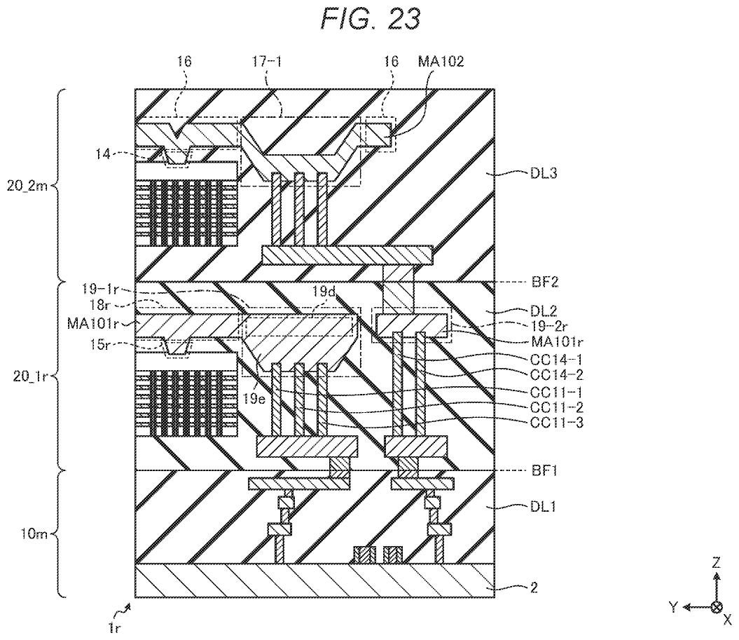

As a second modification of the second embodiment, a semiconductor storage device 1r may have a wiring MA101r made of a material having a lower resistivity, as shown in FIG. 23. FIG. 23 is a YZ cross-sectional view showing the configuration of the semiconductor storage device 1r according to the second modification of the second embodiment, and corresponds to the YZ cross-section taken along line F-F of FIG. 19.

The semiconductor storage device 1r has a chip 20_1r instead of the chip 20_1m (see FIG. 21).

The chip 20_1r has a conductive film MA101r instead of the conductive film MA101 (see FIG. 21). The conductive film MA101r functions as the wiring MA101r. The conductive film MA101r has a routing portion 18r, a pad portion 15r, and plug connection portions 19-1r and 19-2r instead of the routing portion 18, the pad portion 15, and the plug connection portions 19-1 and 19-2 (see FIG. 16).

The routing portion 18r may be made of a material containing the second metal as a main component, instead of the material containing the first metal as a main component. The second metal has a lower resistivity than the resistivity of the first metal.

The plug connection portion 19-1p has a flat portion 19d and a convex portion 19e.

In the plug connection portion 19-1p, the flat portion 19d is substantially flat and extends in the Y direction while maintaining substantially the same Z height. The Z height of the flat portion 19d is equal to the Z height of the routing portion 18r. The flat portion 19d is continuous with the routing portion 18r at the Y-direction end. Thus, the +Z-side surface of the conductive film MA101r can be formed substantially flat.

The convex portion 19e is disposed on the −Z side of the flat portion 19d and has a convex shape from the flat portion 19d to the −Z side. The convex portion 19e has a substantially isosceles trapezoidal shape in a YZ cross-sectional view. A substantially isosceles trapezoidal shape has an upper base that is longer than a lower base. The convex portion 19e has side surfaces that are inclined on both sides in the Y direction. Thus, a step extending from the Z height of the routing portion 18r to the Z height of the base of the convex portion 19e is formed.

The flat portion 19d may be made of a material containing the second metal as a main component, instead of the material containing the first metal as a main component. The convex portion 19e may be made of a material containing the second metal as a main component.

The routing portion 18r may be made of a material containing the second metal as a main component, instead of the material containing the first metal as a main component.

The plug connection portion 19-2r may be made of a material containing the second metal as a main component, instead of the material containing the first metal as a main component.

Even in such a semiconductor storage device 1r, the wiring MA101r and the wiring MA102 are independently connected to the chip 10m. A source line voltage (for example, a ground voltage) can be supplied in parallel from the chip 10m to the chips 20_1m and 20_2m stacked in the Z direction through the wiring MA101r and the wiring MA102. Thus, the voltage of the cell source portion CSL of each chip (array chip) 20 can be efficiently stabilized.

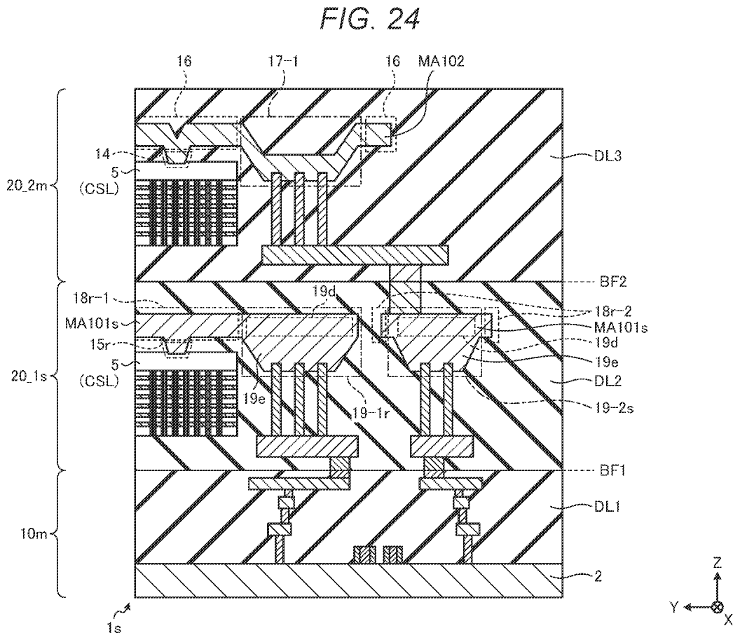

As a third modification of the second embodiment, in a semiconductor storage device is, as shown in FIG. 24, plug connection portions 19-1r and 19-2s of the wiring MA101s may have the same configuration. FIG. 24 is a cross-sectional view showing the configuration of a semiconductor storage device is according to the third modification of the second embodiment.

The chip 20_1s has a conductive film MA101s instead of the conductive film MA101r (see FIG. 23). The conductive film MA101s has a plug connection portion 19-2s instead of the plug connection portion 19-2r (see FIG. 23), and further has a routing portion 18r-2.

The routing portion 18r-2 is disposed on both sides of the plug connection portion 19-2s in the Y direction. The routing portion 18r-2 is substantially flat and extends in the Y direction while maintaining substantially the same Z height.

The plug connection portion 19-2s is connected adjacent to the routing portion 18r-2 on the +Y side or the −Y side, and has a step of which Z height is lower than the routing portion 18r-2. The plug connection portion 19-1s has a flat portion 19d and a convex portion 19e.

In the plug connection portion 19-1s, the flat portion 19d is substantially flat and extends in the Y direction while maintaining substantially the same Z height. The Z height of the flat portion 19d is equal to the Z height of the routing portion 18r-2. The flat portion 19d is continuous with the routing portion 18r-2 at the Y-direction end. Thus, the +Z-side surface of the conductive film MA101s can be formed substantially flat.

The convex portion 19e is disposed on the −Z side of the flat portion 19d and has a convex shape from the flat portion 19d to the −Z side. The convex portion 19e has a substantially isosceles trapezoidal shape in a YZ cross-sectional view. A substantially isosceles trapezoidal shape has an upper base that is longer than a lower base. The convex portion 19e has side surfaces that are inclined on both sides in the Y direction. Thus, a step extending from the Z height of the routing portion 18r to the Z height of the base of the convex portion 19e is formed.

The flat portion 19d may be made of a material containing the second metal as a main component. The convex portion 19e may be made of a material containing the second metal as a main component.

Even in such a semiconductor storage device is, the wiring MA101s and the wiring MA102 are independently connected to the chip 10m. A source line voltage (for example, a ground voltage) can be supplied in parallel from the chip 10m to the chips 20_1m and 20_2m stacked in the Z direction through the wiring MA101s and the wiring MA102. Thus, the voltage of the cell source portion CSL of each chip (array chip) 20 can be efficiently stabilized.

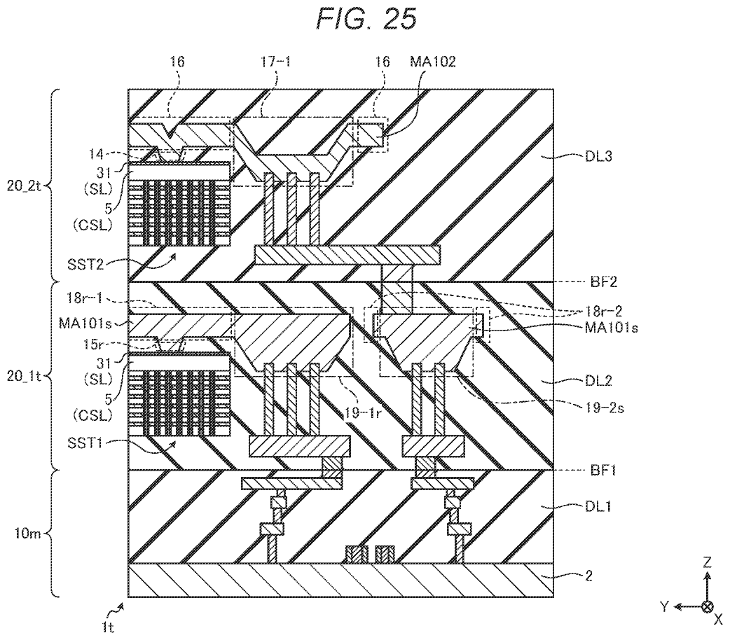

As a fourth modification of the second embodiment, a semiconductor storage device it may be implemented to further stabilize the voltage of a cell source portion CSL, as shown in FIG. 25. FIG. 25 is a cross-sectional view showing the configuration of a semiconductor storage device it according to the fourth modification of the second embodiment.

The chip 20_1t further has a conductive layer 31 in the chip 20_1s (see FIG. 24). The conductive layer 31 is disposed between the pad portion 15r and the conductive layer 5 in the Z direction. The conductive layer 31 extends in a plate shape in the XY direction so as to overlap the conductive layer 5 when viewed from the Z direction. The conductive layer 31 covers the +Z-side surface (rear surface) of the conductive layer 5. The conductive layer 31 functions as the source part SL. The resistivity of the conductive layer 31 is lower than the resistivity of the conductive layer 5. The conductive layer 31 may be made of a material containing a fourth metal (for example, titanium nitride, or the like) as a main component.

Here, when the resistivity of the conductive layer 31 is lower than the resistivity of the conductive layer 5, the conductive layer 31 covers the conductive layer 5 (cell source portion CSL) planarly in the XY direction, so that the voltage of the conductive layer 5 (cell source portion CSL) can be further stabilized.

The chip 20_2t further has a conductive layer 31 in the chip 20_2m (see FIG. 24). The conductive layer 31 is disposed between the pad portion 14 and the conductive layer 5 in the Z direction. The conductive layer 31 extends in a plate shape in the XY direction so as to overlap the conductive layer 5 when viewed from the Z direction. The conductive layer 31 covers the +Z-side surface (rear surface) of the conductive layer 5. The conductive layer 31 functions as the source part SL. The resistivity of the conductive layer 31 is lower than the resistivity of the conductive layer 5. The conductive layer 31 may be made of a material containing a fourth metal (for example, titanium nitride, or the like) as a main component.

Here, when the resistivity of the conductive layer 31 is lower than the resistivity of the conductive layer 5, the conductive layer 31 covers the conductive layer 5 (cell source portion CSL) planarly in the XY direction, so that the voltage of the conductive layer 5 (cell source portion CSL) can be further stabilized.

Even in such a semiconductor storage device 1t, the wiring MA101s and the wiring MA102 are independently connected to the chip 10m. A source line voltage (for example, a ground voltage) can be supplied in parallel from the chip 10m to the chips 20_1t and 20_2t stacked in the Z direction through the wiring MA101s and the wiring MA102. The conductive layer 31 disposed between the wirings MA101s and MA102 and the conductive layer 5 (cell source portion CSL) planarly covers the conductive layer 5 in the XY direction. Thus, the voltage of the cell source portion CSL of each chip (array chip) 20 can be efficiently stabilized.

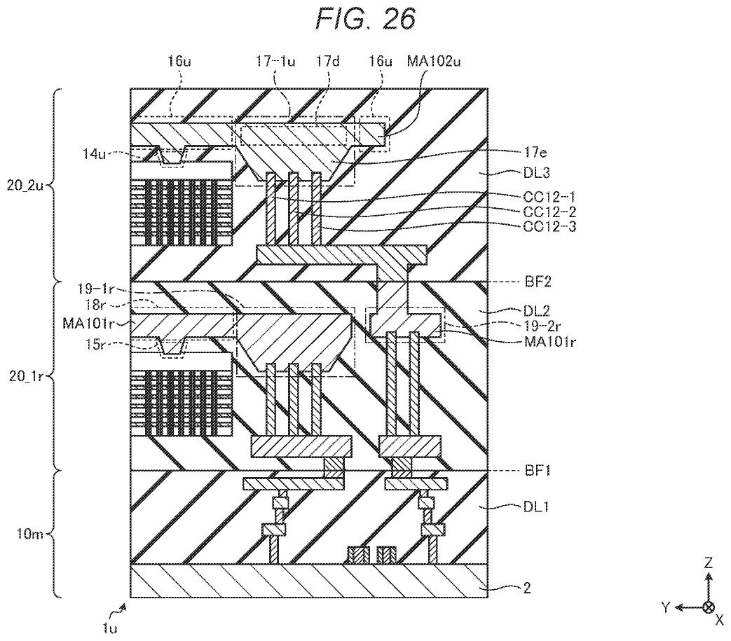

As a fifth modification of the second embodiment, in a semiconductor storage device 1u, as shown in FIG. 26, a wiring MA102u may be formed of a material having a lower resistivity in addition to the wiring MA101r. FIG. 26 is a YZ cross-sectional view showing the configuration of the semiconductor storage device 1u according to the fifth modification of the second embodiment, and corresponds to the YZ cross-section taken along line F-F of FIG. 19.

The semiconductor storage device 1u has a chip 20_2u instead of the chip 20_2m (see FIG. 23).

The chip 20_2u has a conductive film MA102u instead of the conductive film MA102 (see FIG. 23). The conductive film MA102u functions as the wiring MA102u. The conductive film MA102u has a routing portion 16u, a pad portion 15u, and a plug connection portion 17-1u instead of the routing portion 16, the pad portion 15, and the plug connection portion 17-1 (see FIG. 23).

The routing portion 16u may be made of a material containing the second metal as a main component, instead of the material containing the first metal as a main component. The second metal has a lower resistivity than the resistivity of the first metal.

The plug connection portion 17-1u has a flat portion 17d and a convex portion 17e.

In the plug connection portion 17-1u, the flat portion 17d is substantially flat and extends in the Y direction while maintaining substantially the same Z height. The Z height of the flat portion 17d is equal to the Z height of the routing portion 16u. The flat portion 17d is continuous with the routing portion 16u at the Y-direction end. Thus, the +Z-side surface of the conductive film MA101r can be formed substantially flat.

The convex portion 17e is disposed on the −Z side of the flat portion 17d and has a convex shape from the flat portion 17d to the −Z side. The convex portion 17e has a substantially isosceles trapezoidal shape in a YZ cross-sectional view. A substantially isosceles trapezoidal shape has an upper base that is longer than a lower base. The convex portion 17e has side surfaces that are inclined on both sides in the Y direction. Thus, a step extending from the Z height of the routing portion 16u to the Z height of the base of the convex portion 17e is formed.

The flat portion 17d may be made of a material containing the second metal as a main component, instead of the material containing the first metal as a main component. The convex portion 17e may be made of a material containing the second metal as a main component.

The routing portion 16u may be made of a material containing the second metal as a main component, instead of the material containing the first metal as a main component.

Even in such a semiconductor storage device 1u, the wiring MA101r and the wiring MA102u are independently connected to the chip 10m. A source line voltage (for example, a ground voltage) can be supplied in parallel from the chip 10m to the chips 20_1r and 20_2u stacked in the Z direction through the wiring MA101r and the wiring MA102u. Thus, the voltage of the cell source portion CSL of each chip (array chip) 20 can be efficiently stabilized.

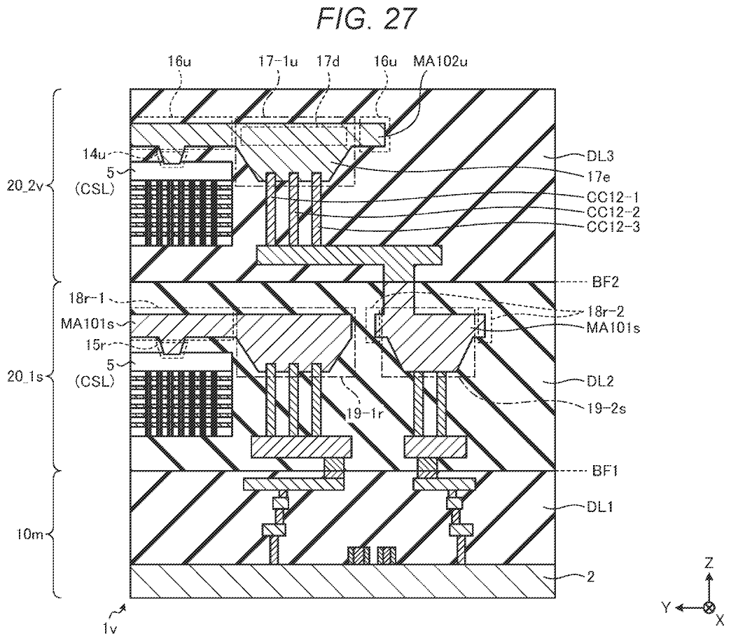

As a sixth modification of the second embodiment, in a semiconductor storage device 1v, as shown in FIG. 27, the wiring MA102u may be formed of a material having a lower resistivity in addition to the wiring MA101s. FIG. 27 is a YZ cross-sectional view showing the configuration of the semiconductor storage device 1v according to the sixth modification of the second embodiment, and corresponds to the YZ cross-section taken along line F-F of FIG. 19.

The semiconductor storage device 1v has a chip 20_2v instead of the chip 20_2m (see FIG. 24).

The chip 20_2v has the conductive film MA102u instead of the conductive film MA102 (see FIG. 23). The conductive film MA102u functions as the wiring MA102u. The conductive film MA102u has a routing portion 16u, a pad portion 15u, and a plug connection portion 17-1u instead of the routing portion 16, the pad portion 15, and the plug connection portion 17-1 (see FIG. 24).

The routing portion 16u may be made of a material containing the second metal as a main component, instead of the material containing the first metal as a main component. The second metal has a lower resistivity than the resistivity of the first metal.

The plug connection portion 17-1u has a flat portion 17d and a convex portion 17e.

In the plug connection portion 17-1u, the flat portion 17d is substantially flat and extends in the Y direction while maintaining substantially the same Z height. The Z height of the flat portion 17d is equal to the Z height of the routing portion 16u. The flat portion 17d is continuous with the routing portion 16u at the Y-direction end. Thus, the +Z-side surface of the conductive film MA101r can be formed substantially flat.

The convex portion 17e is disposed on the −Z side of the flat portion 17d and has a convex shape from the flat portion 17d to the −Z side. The convex portion 17e has a substantially isosceles trapezoidal shape in a YZ cross-sectional view. A substantially isosceles trapezoidal shape has an upper base that is longer than a lower base. The convex portion 17e has side surfaces that are inclined on both sides in the Y direction. Thus, a step extending from the Z height of the routing portion 16u to the Z height of the base of the convex portion 17e is formed.

The flat portion 17d may be made of a material containing the second metal as a main component, instead of the material containing the first metal as a main component. The convex portion 17e may be made of a material containing the second metal as a main component.

The routing portion 16u may be made of a material containing the second metal as a main component, instead of the material containing the first metal as a main component.

Even in such a semiconductor storage device 1v, the wiring MA101s and the wiring MA102u are independently connected to the chip 10m. A source line voltage (for example, a ground voltage) can be supplied in parallel from the chip 10m to the chips 20_1s and 20_2v stacked in the Z direction through the wiring MA101s and the wiring MA102u. Thus, the voltage of the cell source portion CSL of each chip (array chip) 20 can be efficiently stabilized.

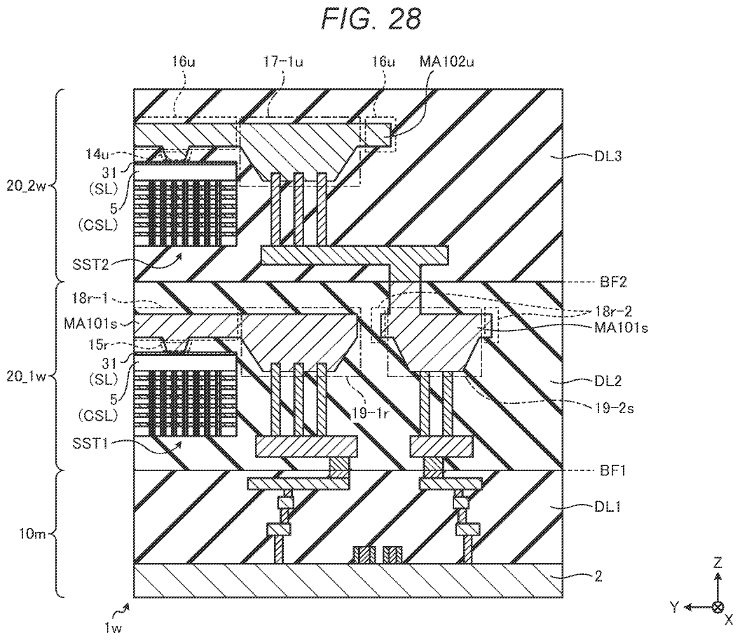

As a seventh modification of the second embodiment, the semiconductor storage device 1w may be implemented to further stabilize the voltage of the cell source portion CSL, as shown in FIG. 28. FIG. 28 is a cross-sectional view showing the configuration of a semiconductor storage device 1w according to the seventh modification of the second embodiment.

The chip 20_1w further has a conductive layer 31 in the chip 20_1s (see FIG. 27). The conductive layer 31 is disposed between the pad portion 15r and the conductive layer 5 in the Z direction. The conductive layer 31 extends in a plate shape in the XY direction so as to overlap the conductive layer 5 when viewed from the Z direction. The conductive layer 31 covers the +Z-side surface (rear surface) of the conductive layer 5. The conductive layer 31 functions as the source part SL. The resistivity of the conductive layer 31 is lower than the resistivity of the conductive layer 5. The conductive layer 31 may be made of a material containing a fourth metal (for example, titanium nitride, or the like) as a main component.

Here, when the resistivity of the conductive layer 31 is lower than the resistivity of the conductive layer 5, the conductive layer 31 covers the conductive layer 5 (cell source portion CSL) planarly in the XY direction, so that the voltage of the conductive layer 5 (cell source portion CSL) can be further stabilized.

The chip 20_2w further has a conductive layer 31 in the chip 20_2v (see FIG. 27). The conductive layer 31 is disposed between the pad portion 14u and the conductive layer 5 in the Z direction. The conductive layer 31 extends in a plate shape in the XY direction so as to overlap the conductive layer 5 when viewed from the Z direction. The conductive layer 31 covers the +Z-side surface (rear surface) of the conductive layer 5. The conductive layer 31 functions as the source part SL. The resistivity of the conductive layer 31 is lower than the resistivity of the conductive layer 5. The conductive layer 31 may be made of a material containing a fourth metal (for example, titanium nitride, or the like) as a main component.

Here, when the resistivity of the conductive layer 31 is lower than the resistivity of the conductive layer 5, the conductive layer 31 covers the conductive layer 5 (cell source portion CSL) planarly in the XY direction, so that the voltage of the conductive layer 5 (cell source portion CSL) can be further stabilized.

Even in such a semiconductor storage device 1w, the wiring MA101s and the wiring MA102 are independently connected to the chip 10m. A source line voltage (for example, a ground voltage) can be supplied in parallel from the chip 10m to the chips 20_1t and 20_2t stacked in the Z direction through the wiring MA101s and the wiring MA102. The conductive layer 31 disposed between the wirings MA101s and MA102 and the conductive layer 5 (cell source portion CSL) planarly covers the conductive layer 5 in the XY direction. Thus, the voltage of the cell source portion CSL of each chip (array chip) 20 can be efficiently stabilized.

### Third Embodiment

Next, a semiconductor storage device 1x according to a third embodiment will be described. In the following description, a difference from the first embodiment and the second embodiment will be mainly described.

In the first embodiment, the configuration of wirings MA1 and MA2 that may be applied to power lines are illustrated, in the second embodiment, the configuration of wirings MA101 and MA102 that may be applied to source lines are illustrated, and in the third embodiment, the configuration of wirings MA201 and MA202 that may be applied to the edge seal is illustrated.

As shown in FIGS. 3 and 19, the edge seal ES surrounds the plurality of stacked bodies SST1 and SST2 from the outside in the XY direction when viewed from the Z direction. Thus, the edge seal ES protects the memory cell arrays 21_1 and 21_2 and the circuits for controlling the memory cell arrays 21_1 and 21_2 (the row decoder 1012, the sense amplifier 1013, the sequencer 1014, the voltage generation circuit 1015, the power circuit 1016, or the like) from external electrostatic noise and the like.

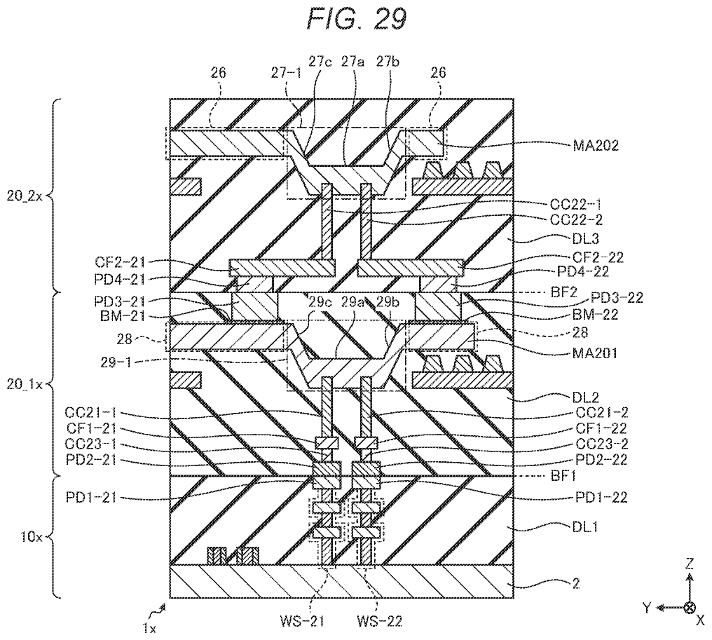

The edge seal ES shown in FIGS. 3 and 19 may be implemented by wirings MA201 and MA202 as shown in FIG. 29. FIG. 29 is a YZ cross-sectional view showing the configuration of the semiconductor storage device 1x, and corresponds to the YZ cross-section taken along line G-G of FIG. 19.

The chip 10x has wiring structures WS-21, WS-22, electrodes PD1-21, PD1-22, and an insulating film DL1. The electrodes PD1-21 and PD1-22 are disposed on the bonding surface BF1 of the chips 10x and 20_1x, respectively. The electrodes PD1-21 and PD1-22 each have the +Z-side surface exposed to the bonding surface BF1. The −Z-side end of the electrode PD1-21 is connected to the substrate 2 via the wiring structure WS-21. The −Z-side end of the electrode PD1-22 is connected to the substrate 2 via the wiring structure WS-22.

The chip 20_1x includes a stacked body SST1 (see FIGS. 3 and 19), a conductive film MA201, a conductive film CF1-21, a conductive film CF1-22, a plurality of plugs CC21-1 to CC21-3, a plurality of plugs CC23-1 to CC23-3, an electrode PD2-21, an electrode PD2-22, an electrode PD3-21, an electrode PD3-22, a barrier film BM-21, a barrier film BM-22, and an insulating film DL2.

The conductive film MA201 is disposed outside the stacked body SST1 in the XY direction. The conductive film MA201 functions as a wiring MA201 that is a part of the edge seal ES. The conductive film MA201 has a linear pattern in the XY plane view. The conductive film MA201 extends in the XY direction so as to approach the stacked body SST1 from the outside in the XY direction of the stacked body SST1 when viewed from the Z direction. The conductive film MA201 may be made of a material containing the first metal as a main component. The first metal contains aluminum or the like. The conductive film MA201 has a routing portion 28 and a plug connection portion 29-1.

The routing portion 28 is disposed on both sides of the plug connection portion 29-1 in the Y direction. The routing portion 28 is substantially flat and extends in the Y direction while maintaining substantially the same Z height.

The plug connection portion 29-1 is connected adjacent to the routing portion 28 on the +Y side or the −Y side, and has a step of which Z height is lower than the routing portion 28. The plug connection portion 29-1 has a flat portion 29a, an inclined portion 29b, and an inclined portion 29c.

In the plug connection portion 29-1, the flat portion 29a is substantially flat and extends in the Y direction while maintaining substantially the same Z height. The Z height of the flat portion 29a is lower than the Z height of the routing portion 28. The +Z-side ends of the plugs CC21-1 to CC21-2 are connected to the flat portion 29a.

The inclined portion 29b is disposed on the −Y side of the flat portion 29a. The inclined portion 29b has a −Y-side end connected to the routing portion 28 and a +Y-side end connected to the flat portion 29a. The inclined portion 29b extends with an inclination such that the Z height decreases from the −Y side toward the +Y side. Thus, a step extending from the Z height of the routing portion 28 to the Z height of the flat portion 29a is formed.

The inclined portion 29c is disposed on the +Y side of the flat portion 29a. The inclined portion 29c has a +Y-side end connected to the routing portion 28 and a −Y-side end connected to the flat portion 29a. The inclined portion 29c extends with an inclination such that the Z height decreases from the +Y side toward the −Y side. Thus, a step extending from the Z height of the routing portion 28 to the Z height of the flat portion 29a is formed.

The conductive film CF1-21 is disposed at a position shifted in the Y direction from the conductive film CF1-22. The conductive film CF1-21 is disposed at the XY position corresponding to the plug connection portion 29-1. The conductive film CF1-21 is disposed at the XY position corresponding to the plug CC21-1. The conductive film CF1-21 is disposed at a position on the −Z side (deeper position) than the conductive film MA201. The conductive film CF1-21 may be made of a material containing the second metal as a main component. The second metal has a lower resistivity than the resistivity of the first metal.

The conductive film CF1-22 is disposed at a position shifted in the Y direction from the conductive film CF1-21. The conductive film CF1-22 is disposed at the XY position corresponding to the plug connection portion 29-1. The conductive film CF1-21 is disposed at the XY position corresponding to the plug CC21-2. The conductive film CF1-22 is disposed at a position on the −Z side (deeper position) than the conductive film MA201. The conductive film CF1-22 may be made of a material containing the second metal as a main component. The second metal has a lower resistivity than the resistivity of the first metal.

The plug CC21-1 is disposed between the conductive film MA201 and the conductive film CF1-21 in the Z direction. The plug CC21-1 is disposed on the −Z side of the plug connection portion 29-1 and disposed on the +Z side of the conductive film CF1-21. The plug CC21-1 extends in the Z direction, and connects the conductive film MA201 and the conductive film CF1-21. The plug CC21-1 has a +Z-side end electrically connected to the plug connection portion 29-1 and a −Z-side end electrically connected to the conductive film CF1-21. Each plug CC21-1 may be made of a material containing the third metal as a main component. The third metal has a higher resistivity than the resistivity of the first metal.

The plug CC21-2 is disposed between the conductive film MA201 and the conductive film CF1-22 in the Z direction. The plug CC21-2 is disposed on the −Z side of the plug connection portion 29-1 and disposed on the +Z side of the conductive film CF1-22. The plug CC21-2 extends in the Z direction, and connects the conductive film MA201 and the conductive film CF1-22. The plug CC21-2 has a +Z-side end electrically connected to the plug connection portion 29-1 and a −Z-side end electrically connected to the conductive film CF1-22. Each plug CC21-2 may be made of a material containing the third metal as a main component.

The plug CC23-1 is disposed between the conductive film CF1-21 and the electrode PD2-21 in the Z direction. The plug CC23-1 is disposed on the −Z side of the conductive film CF1-21 and on the +Z side of the electrode PD2-21. The plug CC23-1 extends in the Z direction and connects the conductive film CF1-21 and the electrode PD2-21. The plug CC23-1 has a +Z-side end electrically connected to the conductive film CF1-21 and a −Z-side end electrically connected to the electrode PD2-21. Each plug CC23-1 may be made of a material containing the third metal as a main component.

The plug CC23-2 is disposed between the conductive film CF1-22 and the electrode PD2-22 in the Z direction. The plug CC23-2 is disposed on the −Z side of the conductive film CF1-22 and on the +Z side of the electrode PD2-22. The plug CC23-2 extends in the Z direction and connects the conductive film CF1-22 and the electrode PD2-22. The plug CC23-2 has a +Z-side end electrically connected to the conductive film CF1-22 and a −Z-side end electrically connected to the electrode PD2-22. Each plug CC23-2 may be made of a material containing the third metal as a main component.

The electrode PD2-21 is disposed on the bonding surface BF1 of the chip 10x and the chip 20_1x. The electrode PD2-21 is electrically connected to the plug CC23-1 and the electrode PD1-21. The electrode PD2-21 has a +Z-side surface in contact with the plug CC23-1 and a −Z-side surface exposed to the bonding surface BF1. The −Z-side surface of the electrode PD2-21 is in contact with the electrode PD1-21. The electrode PD2-21 may be made of a material containing the second metal as a main component.

The electrode PD2-22 is disposed on the bonding surface BF1 of the chip 10x and the chip 20_1x. The electrode PD2-22 is electrically connected to the plug CC23-2 and the electrode PD1-22. The electrode PD2-22 has a +Z-side surface in contact with the plug CC23-2 and a −Z-side surface exposed to the bonding surface BF1. The −Z-side surface of the electrode PD2-22 is in contact with the electrode PD1-22. The electrode PD2-22 may be made of a material containing the second metal as a main component.

The electrode PD3-21 is disposed on the bonding surface BF2 of the chip 20_1x and the chip 20_2x. The electrode PD3-21 is disposed at the XY position corresponding to the routing portion 28 in the conductive film MA201.

The electrode PD3-21 is electrically connected to the conductive film MA201 via the barrier film BM-21 and electrically connected to the electrode PD4-21. The electrode PD3-21 has a −Z-side surface in contact with the barrier film BM-21 and a +Z-side surface exposed to the bonding surface BF2. The +Z-side surface of the electrode PD3-21 is in contact with the electrode PD4-21. The electrode PD3-21 may be made of a material containing the second metal as a main component.

The electrode PD3-22 is disposed on the bonding surface BF2 of the chip 20_1x and the chip 20_2x. The electrode PD3-22 is disposed at the XY position corresponding to the routing portion 28 in the conductive film MA201. The electrode PD3-22 is disposed at the XY position on the side opposite to the electrode PD3-21 with the plug connection portion 29-1 therebetween.

The electrode PD3-22 is electrically connected to the conductive film MA201 via the barrier film BM-22, and is electrically connected to the electrode PD4-22. The electrode PD3-22 has a −Z-side surface in contact with the barrier film BM-22 and a +Z-side surface exposed to the bonding surface BF2. The +Z-side surface of the electrode PD3-22 is in contact with the electrode PD4-22. The electrode PD3-22 may be made of a material containing the second metal as a main component.

The barrier film BM-21 is disposed between the electrode PD3-21 and the conductive film MA201 in the Z direction. The barrier film BM-21 has a +Z-side surface in contact with the electrode PD3-21 and a −Z-side surface in contact with the conductive film MA201. The barrier film BM-21 is made of a conductive material having barrier properties preventing (limiting) diffusion of the first metal and the second metal. The barrier film BM-21 can be made of, for example, a material containing titanium nitride as a main component. Thus, the second metal element contained in the electrode PD3-21 can be prevented from diffusing toward the conductive film MA201 side, and the first metal element contained in the conductive film MA201 can be prevented from diffusing toward the electrode PD3-21 side.

The barrier film BM-22 is disposed between the electrode PD3-22 and the conductive film MA201 in the Z direction. The barrier film BM-22 has a +Z-side surface in contact with the electrode PD3-22 and a −Z-side surface in contact with the conductive film MA201. The barrier film BM-22 is made of a conductive material having barrier properties limiting (preventing) diffusion of the first metal and the second metal. The barrier film BM-22 may be made of, for example, a material containing titanium nitride as a main component. Thus, the second metal element contained in the electrode PD3-22 can be prevented from diffusing toward the conductive film MA201 side, and the first metal element contained in the conductive film MA201 can be prevented from diffusing toward the electrode PD3-22 side.

The chip 20_2x includes the stacked body SST2 (see FIGS. 3 and 19), a conductive film MA202, a conductive film CF2-21, a conductive film CF2-22, a plurality of plugs CC22-1 and CC22-2, an electrode PD4-21, an electrode PD4-22, and an insulating film DL3.

The conductive film MA202 is disposed outside the stacked body SST2 in the XY direction. The conductive film MA202 functions as a wiring MA202 that is a part of the edge seal ES. The conductive film MA202 has a linear pattern in the XY plane view. The conductive film MA202 extends in the XY direction so as to approach the stacked body SST2 from the outside in the XY direction of the stacked body SST2 when viewed from the Z direction. The conductive film MA202 may be made of a material containing the first metal as a main component. The first metal contains aluminum or the like. The conductive film MA202 has a routing portion 26 and a plug connection portion 27-1.

The routing portion 26 is disposed on both sides of the plug connection portion 27-1 in the Y direction. The routing portion 26 is substantially flat and extends in the Y direction while maintaining substantially the same Z height.

The plug connection portion 27-1 is connected adjacent to the routing portion 26 on the +Y side or the −Y side, and has a step of which Z height is lower than the routing portion 26. The plug connection portion 27-1 has a flat portion 27a, an inclined portion 27b, and an inclined portion 27c.

In the plug connection portion 27-1, the flat portion 27a is substantially flat and extends in the Y direction while maintaining substantially the same Z height. The Z height of the flat portion 27a is lower than the Z height of the routing portion 26. The +Z-side ends of the plugs CC22-1 to CC22-2 are connected to the flat portion 27a.

The inclined portion 27b is disposed on the −Y side of the flat portion 27a. The inclined portion 27b has a −Y-side end connected to the routing portion 26 and a +Y-side end connected to the flat portion 27a. The inclined portion 27b extends with an inclination such that the Z height decreases from the −Y side toward the +Y side. Thus, a step extending from the Z height of the routing portion 26 to the Z height of the flat portion 27a is formed.

The inclined portion 27c is disposed on the +Y side of the flat portion 27a. The inclined portion 27c has a +Y-side end connected to the routing portion 26 and a −Y-side end connected to the flat portion 27a. The inclined portion 27c extends with an inclination such that the Z height decreases from the +Y side toward the −Y side. Thus, a step extending from the Z height of the routing portion 26 to the Z height of the flat portion 27a is formed.

The conductive film CF2-21 is disposed at a position shifted in the Y direction from the conductive film CF2-22. The conductive film CF2-21 is disposed at the XY position corresponding to the plug connection portion 27-1. The conductive film CF2-21 is disposed at the XY position corresponding to the plug CC22-1. The conductive film CF2-21 is disposed at a position on the −Z side (deeper position) than the conductive film MA202. The conductive film CF2-21 may be made of a material containing the second metal as a main component. The second metal has a lower resistivity than the resistivity of the first metal.

The conductive film CF2-22 is disposed at a position shifted in the Y direction from the conductive film CF2-21. The conductive film CF2-22 is disposed at the XY position corresponding to the plug connection portion 27-1. The conductive film CF2-21 is disposed at the XY position corresponding to the plug CC22-2. The conductive film CF2-22 is disposed at a position on the −Z side (deeper position) than the conductive film MA202. The conductive film CF2-22 may be made of a material containing the second metal as a main component.

The plug CC22-1 is disposed between the conductive film MA202 and the conductive film CF2-21 in the Z direction. The plug CC22-1 is disposed on the −Z side of the plug connection portion 27-1 and on the +Z side of the conductive film CF2-21. The plug CC22-1 extends in the Z direction and connects the conductive film MA202 and the conductive film CF2-21. The plug CC22-1 has a +Z-side end electrically connected to the plug connection portion 27-1 and a −Z-side end electrically connected to the conductive film CF2-21. The plug CC22-1 may be made of a material containing the third metal as a main component.

The plug CC22-2 is disposed between the conductive film MA202 and the conductive film CF2-22 in the Z direction. The plug CC22-2 is disposed on the −Z side of the plug connection portion 27-1 and disposed on the +Z side of the conductive film CF2-22. The plug CC22-2 extends in the Z direction and connects the conductive film MA202 and the conductive film CF2-22. The plug CC22-2 has a +Z-side end electrically connected to the plug connection portion 27-1 and a −Z-side end electrically connected to the conductive film CF2-22. The plug CC22-2 may be made of a material containing the third metal as a main component.

The electrode PD4-21 is disposed on the bonding surface BF2 of the chip 20_1x and the chip 20_2x. The electrode PD4-21 is electrically connected to the conductive film CF2-21 and the electrode PD3-21. The electrode PD4-21 has a +Z-side surface in contact with the conductive film CF2-21 and a −Z-side surface exposed to the bonding surface BF2. The −Z-side surface of the electrode PD4-21 is in contact with the electrode PD3-21. The electrode PD4-21 may be made of a material containing the second metal as a main component.

The electrode PD4-22 is disposed on the bonding surface BF2 of the chip 20_1x and the chip 20_2x. The electrode PD4-22 is electrically connected to the conductive film CF2-22 and the electrode PD3-22. The electrode PD4-22 has a +Z-side surface in contact with the conductive film CF2-22 and a −Z-side surface exposed to the bonding surface BF2. The −Z-side surface of the electrode PD4-22 is in contact with the electrode PD3-22. The electrode PD4-22 may be made of a material containing the second metal as a main component.

In the connection configuration from the conductive film MA202 to the substrate 2 shown in FIG. 29, the conductive film MA202 of the chip 20_2x and the conductive film MA201 of the chip 20_1x are connected in parallel. A first common connection path and a second common connection path are connected between the routing portion 26 and the substrate 2, respectively. A seventh connection path and an eighth connection path are connected in parallel between the routing portion 26 and the first common connection path. The seventh connection path and the eighth connection path are connected in parallel between the routing portion 26 and the second common connection path.

The seventh connection path includes the routing portion 26→the plug connection portion 27-1→the plug CC22-1 the conductive film CF2-21→the electrode PD4-21→the electrode PD3-21→the barrier film BM-21→the routing portion 28. The eighth connection path includes the routing portion 26 the plug connection portion 27-1→the plug CC22-2→the conductive film CF2-22→the electrode PD4-22→the electrode PD3-22→the barrier film BM-22→the routing portion 28. The first common connection path includes the plug connection portion 29-1→the plug CC21-1→the conductive film CF1-21→the plug CC23-1→the electrode PD2-21→the electrode PD1-21→the wiring structure WS-21. The second common connection path includes the plug connection portion 29-1→the plug CC21-2→the conductive film CF1-22→the plug CC23-2→the electrode PD2-22→the electrode PD1-22→the wiring structure WS-22.

The seventh connection path and the eighth connection path join at the plug connection portion 29-1 and are connected to the substrate 2 of the chip 10x via the first common connection path. Thus, the conductive films MA201 and MA202 are connected in parallel between the routing portion 26 and the first common connection path. Thus, external electrostatic noise can be released from the routing portion 26 to the substrate 2.

The seventh connection path and the eighth connection path join at the plug connection portion 29-1 and are connected to the substrate 2 of the chip 10x via the second common connection path. Thus, the conductive films MA201 and MA202 are connected in parallel between the routing portion 26 and the second common connection path. Thus, external electrostatic noise can be released from the routing portion 26 to the substrate 2.

The conductive film MA201 can be formed in the same step as the step of forming the conductive film MA1 (see FIG. 6) and/or the conductive film MA101 (see FIG. 6) during the manufacture of the semiconductor storage device 1x. At this time, since the Z-direction thickness of the conductive film MA201 is made the same as the Z-direction thickness of the conductive film MA1 and/or the Z-direction thickness of the conductive film MA101, the +Z-side surface of the chip 20_1 can be substantially flattened from the inside to the outside in the XY direction. Thus, when the chip 20_1 and the chip 20_2 are bonded, the electrode PD3 and the electrode PD4 can be satisfactorily bonded from the inside to the outside in the XY direction on the +Z-side surface of the chip 20_1.

As described above, in the third embodiment, in the connection configuration from the routing portion 26 to the substrate 2 in the semiconductor storage device 1x, the conductive film MA202 of the chip 20_2x and the conductive film MA201 of the chip 20_1x are connected in parallel. Thus, the wiring MA201 and the wiring MA202 can be thinned while still meeting the required characteristics.

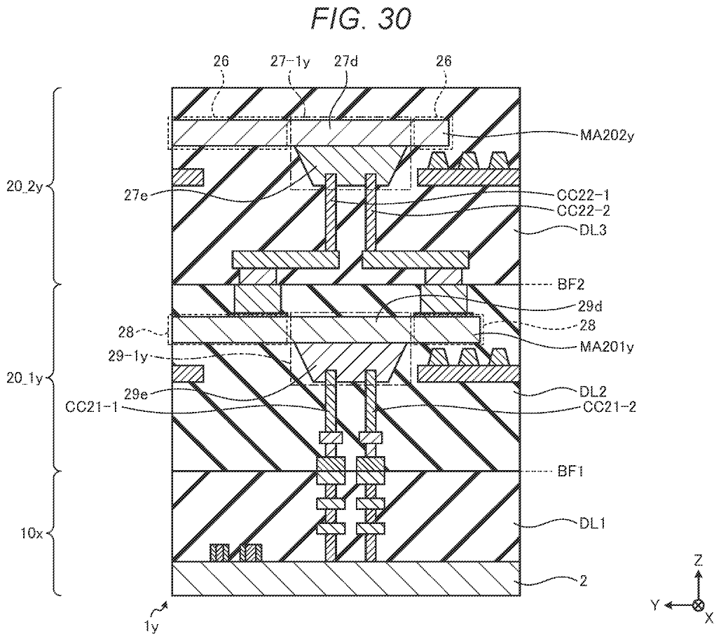

It is noted that as a first modification of the third embodiment, as shown in FIG. 30, a semiconductor storage device 1y may be implemented such that the surfaces on the +Z side of wirings MA201y and MA202y are flat. FIG. 30 is a YZ cross-sectional view showing the configuration of the semiconductor storage device 1y according to the first modification of the third embodiment, and corresponds to the YZ cross-section taken along line G-G of FIG. 19.

The semiconductor storage device 1y has chips 20_1y and 20_2y instead of the chips 20_1x and 20_2x (see FIG. 29).

The chip 20_1y has a conductive film MA201y instead of the conductive film MA201 (see FIG. 29). The conductive film MA201y functions as the wiring MA201y. The conductive film MA201y has a plug connection portion 29-1y instead of the plug connection portion 29-1 (see FIG. 6).

The plug connection portion 29-1y has a flat portion 29d and a convex portion 29e.

In the plug connection portion 29-1y, the flat portion 29d is substantially flat and extends in the Y direction while maintaining substantially the same Z height. The Z height of the flat portion 29d is equal to the Z height of the routing portion 28. The flat portion 29d is continuous with the routing portion 28 at the Y-direction end. Thus, the +Z-side surface of the conductive film MA201y can be formed substantially flat.

The convex portion 29e is disposed on the −Z side of the flat portion 29d and has a convex shape from the flat portion 29d to the −Z side. The convex portion 29e has a substantially isosceles trapezoidal shape in a YZ cross-sectional view. A substantially isosceles trapezoidal shape has an upper base that is longer than a lower base. The convex portion 29e has side surfaces that are inclined on both sides in the Y direction. Thus, a step extending from the Z height of the routing portion 28 to the Z height of the base of the convex portion 29e is formed.

The flat portion 29d may be made of a material containing the first metal as a main component. The convex portion 29e may be made of a material containing the second metal or the third metal as a main component. The second metal has a lower resistivity than the resistivity of the first metal. The third metal has a higher resistivity than the resistivity of the first metal. When the first metal contains aluminum or the like, the second metal contains copper or the like, and the third metal contains tungsten or the like.

The chip 20_2y has a conductive film MA202y instead of the conductive film MA202 (see FIG. 6). The conductive film MA202y functions as the wiring MA202y. The conductive film MA202y has plug connection portions 27-1y and 27-2i instead of the plug connection portions 27-1 and 27-2 (see FIG. 6).

The plug connection portion 27-1y has a flat portion 27d and a convex portion 27e.

In the plug connection portion 27-1y, the flat portion 27d is substantially flat and extends in the Y direction while maintaining substantially the same Z height. The Z height of the flat portion 27d is equal to the Z height of the routing portion 26. The flat portion 27d is continuous with the routing portion 26 at the Y-direction end. Thus, the +Z-side surface of the conductive film MA2 can be formed substantially flat.

The convex portion 27e is disposed on the −Z side of the flat portion 27d and has a convex shape from the flat portion 27d to the −Z side. The convex portion 27e has a substantially isosceles trapezoidal shape in a YZ cross-sectional view. A substantially isosceles trapezoidal shape has an upper base that is longer than a lower base. The convex portion 27e has side surfaces that are inclined on both sides in the Y direction. Thus, a step extending from the Z height of the routing portion 28 to the Z height of the base of the convex portion 27e is formed. The +Z-side ends of the plugs CC22-1 to CC22-2 are connected to the convex portion 27e.

The flat portion 27d may be made of a material containing the first metal as a main component. The convex portion 27e may be made of a material containing the second metal or the third metal as a main component. The second metal has a lower resistivity than the resistivity of the first metal. The third metal has a higher resistivity than the resistivity of the first metal.

Even in such a semiconductor storage device 1y, in the connection configuration from the routing portion 26 to the substrate 2, the conductive film MA202y of the chip 20_2y and the conductive film MA201y of the chip 20_1y are connected in parallel. Thus, the wiring MA201y and the wiring MA202y can be thinned while still satisfying the required characteristics.

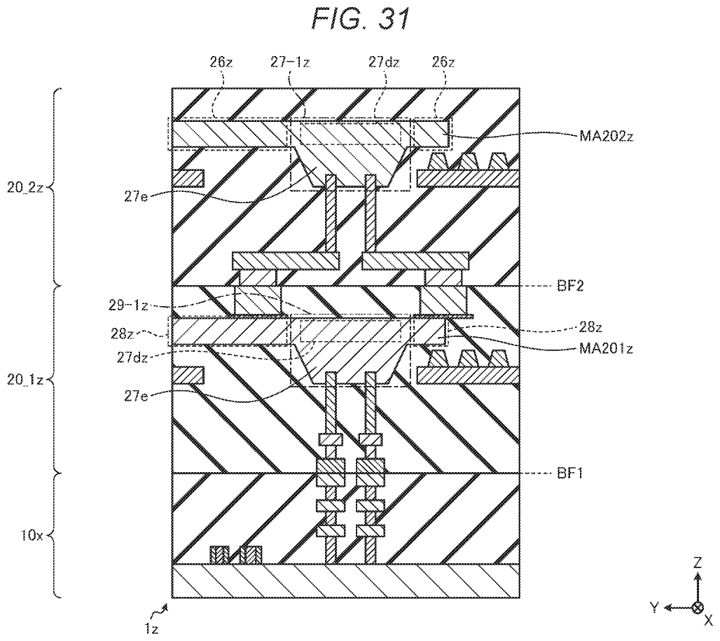

As a second modification of the third embodiment, as shown in FIG. 31, in a semiconductor storage device 1z, wirings MA201z and MA202z may be made of a material with lower resistivity. FIG. 31 is a YZ cross-sectional view showing the configuration of the semiconductor storage device 1z according to the second modification of the third embodiment, and corresponds to the YZ cross-section taken along line G-G of FIG. 19.

The semiconductor storage device 1z has chips 20_1z and 20_2z instead of the chips 20_1y and 20_2y (see FIG. 30).

The chip 20_1z has a conductive film MA201z instead of the conductive film MA201y (see FIG. 30). The conductive film MA201z functions as the wiring MA201z. The conductive film MA201z has a routing portion 28z and a plug connection portion 29-1z instead of the routing portion 28 and the plug connection portion 29-1y (see FIG. 30).

The routing portion 28z may be made of a material containing the second metal as a main component, instead of the material containing the first metal as a main component. The second metal has a lower resistivity than the resistivity of the first metal.

The plug connection portion 29-1z has a flat portion 29dz instead of the flat portion 29d (see FIG. 30). The flat portion 29dz may be made of a material containing the second metal as a main component, instead of the material containing the first metal as a main component.

The chip 20_2z has a conductive film MA202z instead of the conductive film MA202y (see FIG. 30). The conductive film MA202z functions as the wiring MA202z. The conductive film MA202z has a routing portion 26z and plug connection portions 27-1z and 27-2j instead of the routing portion 26 and the plug connection portion 27-1y (see FIG. 30).

The routing portion 26z may be made of a material containing the second metal as a main component, instead of the material containing the first metal as a main component.

The plug connection portion 27-1z has a flat portion 27dz instead of the flat portion 27d (see FIG. 30). The flat portion 27dz may be made of a material containing the second metal as a main component, instead of the material containing the first metal as a main component.

Even in such a semiconductor storage device 1z, in the connection configuration from the routing portion 26 to the substrate 2, the conductive film MA202z of the chip 20_2z and the conductive film MA201z of the chip 20_1z are connected in parallel. Thus, the wiring MA201z and the wiring MA202z can be made thinner while still satisfying the required characteristics.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device, comprising:
a first chip;
a second chip bonded to the first chip; and
a third chip bonded to the second chip on a side opposite the first chip, wherein
the third chip includes:
a first stacked body in which a plurality of first conductive layers are stacked via a first insulating layer one on the other in a stacking direction,
a plurality of first semiconductor films each extending in the stacking direction in the first stacked body,
a first conductive film above the first stacked body in the stacking direction and extending across the first stacked body when viewed from the stacking direction,
a second conductive film spaced from the first stacked body in a planar direction intersecting the stacking direction, the second conductive film being at a position along the stacking direction that is closer to the second chip than is the first conductive film,
a first plug between the first conductive film and the second conductive film in the stacking direction and connecting the first conductive film and the second conductive film, and
a first electrode at a bonding surface of the second chip and the third chip and connected to the second conductive film,
the second chip includes:
a second stacked body in which a plurality of second conductive layers are stacked via a second insulating layer one on the other in the stacking direction,
a plurality of second semiconductor films each extending in the stacking direction in the second stacked body,
a third conductive film above the second stacked body in the stacking direction,
a fourth conductive film spaced from the second stacked body in the planar direction, the fourth conductive film being at a position along the stacking direction that is closer to the first chip than is the third conductive film,
a second plug between the third conductive film and the fourth conductive film in the stacking direction and connecting the third conductive film and the fourth conductive film,
a second electrode at the bonding surface of the second chip and the third chip and connected to the first electrode and the third conductive film, and
a third electrode at a bonding surface of the first chip and the second chip and connected to the fourth conductive film, and
the first chip has a first wiring structure therein that is connected to the third electrode.

2. The semiconductor storage device according to claim 1, wherein
the third chip further includes:
a fifth conductive film spaced from the first stacked body in the planar direction to a side opposite the second conductive film, the fifth conductive film being at a position along the stacking direction that is closer to the second chip than is the first conductive film,
a third plug between the first conductive film and the fifth conductive film in the stacking direction and connecting the first conductive film and the fifth conductive film, and
a fourth electrode at the bonding surface of the second chip and the third chip and connected to the fifth conductive film,
the third conductive film extends across the second stacked body when viewed from the stacking direction, and
the second chip has a fifth electrode at the bonding surface of the second chip and the third chip that is connected to the fourth electrode and the third conductive film.

3. The semiconductor storage device according to claim 2, wherein
the third chip has a plurality of first plugs and a plurality of third plugs,
the plurality of first plugs electrically connect the first conductive film and the second conductive film in parallel,
the plurality of third plugs electrically connect the first conductive film and the fifth conductive film in parallel,
the second chip has a plurality of the second plugs each extending in the stacking direction, and
the plurality of second plugs electrically connect the third conductive film and the fourth conductive film in parallel.

4. The semiconductor storage device according to claim 1, wherein
the second chip further includes:
a sixth conductive film above the second stacked body in the stacking direction and extending across the second stacked body when viewed from the stacking direction,
a seventh conductive film spaced from the second stacked body in the planar direction and at a position along the stacking direction that is closer to the first chip than is the sixth conductive film,
a fourth plug between the sixth conductive film and the seventh conductive film in the stacking direction and connecting the sixth conductive film and the seventh conductive film, and
a sixth electrode at the bonding surface of the first chip and the second chip and connected to the seventh conductive film, and
the first chip includes a second wiring structure therein that is connected to the sixth electrode.

5. The semiconductor storage device according to claim 1, wherein
the third chip has an eighth conductive film connected to an end of the first semiconductor film,
a width of the first conductive film in a lateral direction is greater than a width of the eighth conductive film in the lateral direction,
the second chip has a ninth conductive film connected to an end of the second semiconductor film, and
a width of the second conductive film in the lateral direction is greater than a width of the ninth conductive film in the lateral direction.

6. The semiconductor storage device according to claim 1, wherein
the third chip has an eighth conductive film connected to an end of the first semiconductor film,
a thickness of the first conductive film is greater than a thickness of the eighth conductive film,
the second chip has a ninth conductive film connected to an end of the second semiconductor film, and
a thickness of the second conductive film is greater than a thickness of the ninth conductive film.

7. The semiconductor storage device according to claim 1, wherein
the third chip has a plurality of first plugs,
the plurality of first plugs connect the first conductive film and the second conductive film in parallel,
the second chip has a plurality of second plugs, and
the plurality of second plugs connect the third conductive film and the fourth conductive film in parallel.

8. A semiconductor storage device, comprising:
a first chip;
a second chip bonded to the first chip; and
a third chip bonded to the second chip on a side opposite the first chip in a stacking direction, wherein
the third chip includes:
a first conductive film,
a second conductive film at a position along the stacking direction that is closer to the second chip than is the first conductive film,
a first plug between the first conductive film and the second conductive film, the first plug extending in the stacking direction to connect the first conductive film and the second conductive film,
a first electrode at a bonding surface of the second chip and the third chip and connected to the second conductive film,
a fifth conductive film spaced from the second conductive film in a planar direction intersecting the stacking direction, the fifth conductive film being at a position along the stacking direction that is closer to second chip than is than the first conductive film,
a third plug between the first conductive film and the fifth conductive film, the third plug extending in the stacking direction to connect the first conductive film and the fifth conductive film, and
a fourth electrode at the bonding surface of the second chip and the third chip and connected to the fifth conductive film,
the second chip includes:
a third conductive film,
a fourth conductive film at a position along the stacking direction closer to the first chip than is the third conductive film,
a second plug between the third conductive film and the fourth conductive film, the second plug extending in the stacking direction to connect the third conductive film and the fourth conductive film,
a second electrode at the bonding surface of the second chip and the third chip and connected to the first electrode and the third conductive film,
a third electrode at a bonding surface of the first chip and the second chip and connected to the fourth conductive film, and
a fifth electrode at the bonding surface of the second chip and the third chip and connected to the fourth electrode and the third conductive film, and
the first chip has a first wiring structure therein that is connected to the third electrode.

9. The semiconductor storage device according to claim 8, wherein the second chip further includes:
a first stacked body comprising a plurality of conductive layers stacked one on the other with an insulating film therebetween, and
a plurality of memory pillars extending through the plurality of conductive layers of the first stacked body in the stacking direction.

10. The semiconductor storage device according to claim 9, wherein the first stacked body is between the third conductive film and the first chip in the stacking direction.

11. The semiconductor storage device according to claim 10, wherein the second plug is to one side of the first stacked body in a second direction intersecting the stacking direction.

12. The semiconductor storage device according to claim 11, wherein
the third conductive film includes a plug connection portion directly contacting the second plug, and
the plug connection portion extends into the second chip to a position closer to the first chip than the bonding surface of the second chip and the third chip.

13. The semiconductor storage device according to claim 11, wherein the third chip further includes:
a second stacked body comprising a plurality of conductive layers stacked one on the other with an insulating film therebetween, and
a plurality of memory pillars extending through the plurality of conductive layers of the second stacked body in the stacking direction.

14. The semiconductor storage device according to claim 13, wherein the second stacked body is between the first conductive film and the second chip in the stacking direction.

15. The semiconductor storage device according to claim 14, wherein the first plug is to one side of the second stacked body in the second direction.

16. The semiconductor storage device according to claim 15, wherein the first plug and the second plug are on the same side of the second and first stacked bodies, respectively.

17. The semiconductor storage device according to claim 14, wherein
the first conductive film includes a plug connection portion directly contacting the first plug, and
the plug connection portion of the first conductive film extends into the third chip to a position closer to the second chip than an uppermost surface of third chip.

18. The semiconductor storage device according to claim 8, wherein the first chip is a memory controller chip.

19. The semiconductor storage device according to claim 18, wherein the second chip is a memory cell array chip.

20. The semiconductor storage device according to claim 19, wherein the third chip is a memory cell array chip.
